(19) United States
(12) Patent Application Publication
(10) Pub. No.: US 2009/0278556 A1
(43) Pub. Date: Nov. 12, 2009

(54) Carbon Nanostructure Electrode Based Sensors: Devices, Processes and Uses Thereof

(75) Inventors: Piu Francis Man, Wilmington, DE (US); Ajeeta Pradip Patil, Newark, DE (US); Kah Fatt Tan, Newark, DE (US); Salvatore J. Pace, Newark, DE (US)

Correspondence Address: WOODCOCK WASHBURN LLP, CIRA CENTRE, 12TH FLOOR, 2929 ARCH STREET, PHILADELPHIA, PA, 19104-2891, US

(73) Assignee: Nanoselect, Inc., Wilmington, DE (US)

(21) Appl. No.: 12/423,989

(22) Filed: Apr. 15, 2009

Related U.S. Application Data
(63) Continuation-in-part of application No. 12/161,294.
(60) Provisional application No. 60/762,788, filed on Jan. 26, 2006.

(51) Int. Cl. G01R 27/22

(52) U.S. Cl. 324/693; 977/953; 977/742

(57) ABSTRACT

Disclosed herein are methods of preparing and using doped MWNT electrodes, sensors and field-effect transistors. Devices incorporating doped MWNT electrodes, sensors and field-effect transistors are also disclosed. Also disclosed are devices comprising nanostructured electrodes and methods for measuring free chlorine in an aqueous environment. Also disclosed are diamond coated electrodes for use in electrochemical applications.

### CROSS REFERENCE TO RELATED PATENT APPLICATIONS

This patent application is a continuation-in-part of U.S. patent application Ser. No. 12/161,294, filed Jul. 17, 2008, which is the U.S. National Stage of International Application No. PCT/US2007/002104, filed Jan. 26, 2007, which claims the benefit of U.S. Provisional Application No. 60/762,788, filed Jan. 26, 2006, the disclosure of which is incorporated herein by reference in its entirety.

### FIELD OF THE INVENTION

The present invention is in the field of chemical and biological sensors. The present invention is also in the field of processes for making chemical and biological sensors. The present invention is also in the field of using sensors for monitoring water quality.

### BACKGROUND OF THE INVENTION

Chemical and biological sensors that are used for continuous monitoring generally require a degree of inertness from the sample environment. Inertness is particularly important in utility type applications such as water monitoring. Continually operating sensors in the field need to be rugged, chemically stable and readily manufactured. There is a continuing need to prepare and design sensors that can effectively and efficiently measure a wide range of chemical and biological contaminants in drinking water in view of both public health and national safety perspectives.

The low salt content (high electrical impedance) of drinking water presents a unique challenge to electrochemical measurement because small variations in electrolyte content will introduce significant measurement error. Improvements in the ability to measure variable conductivity water samples from drinking water to sea water without analytical performance degradation are presently needed. Even gold or gold-coated electrodes are known to degrade in such environments. Accordingly, improvements in electrodes and sensors are required.

U.S. Pat. No. 6,905,655 to Gabriel et al. discloses sensors that operate on the principle that the electrical conductivity of a MWNT changes depending on the environment surrounding nanotube. The disclosed sensors, however, require one to carefully lay down MWNTs (“CNTs”) parallel to the surface of a substrate. Nanotubes oriented in such a fashion are required to make electrical contact with two or more electrodes on the substrate through the outer surface of its graphene sheet. Such sensors typically require that the nanotubes are bonded with some type of protective coating, such as a polymer, where the nanotubes contact the electrodes. In view of the difficulty of adhering nanotubes lying across electrodes in this fashion, there remains the need to provide CNT-based sensors that overcome these difficulties.

Li et al., Nano Letters, 2003, Vol. 3, No. 5, 597-602, discloses a carbon nanotube electrode array for ultrasensitive DNA detection. The nanoelectrode array is based on multiwalled carbon nanotubes embedded in SiO2, with only the open ends of the multiwalled carbon nanotubes being exposed to the environment to give rise to DNA detection. Accordingly, only a very low surface area is provided in the carbon nanotube electrode arrays provided by Li et al. Further improvements are needed to enhance the sensitivity of carbon nanotube electrodes and sensors.

### SUMMARY OF THE INVENTION

In certain aspects, the present invention provides sensors composed of one or more multiwall MWNT (“MWNT”) array electrodes that are rugged in use, chemically stable and readily manufactured. The MWNT array electrodes used in aspects of the invention can be used to measure drinking water compositions. Various sensor embodiments as described herein can be adapted to many other applications, for example, in medical testing of biological fluids, as well as in testing the safety of pharmaceuticals, beverages and food.

In one aspect, the present invention provides antennae assembly electrodes, comprising: an electrically conductive layer at least partially surmounting a substrate; and an assembly of doped antennae vertically oriented with respect to the electrically conductive layer, wherein each of the doped antennae comprises a doped MWNT comprising: a base end attached to the electrically conductive layer, a mid-section comprising an outer surface surrounding a lumen, wherein at least a portion of the outer surface of the mid-section is capable of being in fluidic contact with an environment in contact with the antennae; a top end disposed opposite to the base end, and a dopant attached to or contained within the lumen, a dopant attached to or contained within the outer surface, a dopant attached to or contained within the top end, or any combination thereof. Sensors and field-effect transistors comprising these antennae assembly electrodes are also provided.

The present invention also provides methods of making an antennae assembly electrode, comprising the steps of: surmounting a substrate with an electrically conductive layer; surmounting an assembly of antennae on the electrically conductive layer giving rise to the antennae being vertically oriented with respect to the electrically conductive layer, wherein each of the antennae comprises a MWNT comprising a base end being attached to the electrically conductive layer; a mid-section comprising an outer surface surrounding a lumen, wherein at least a portion of the outer surface of the mid-section is capable of being in fluidic contact with an environment in contact with the antennae; and a top end being disposed opposite to the base end; and doping at least a portion of the MWNT with a cladding, a covalent bond linkage, a functional dopant molecule, a fill material, or any combination thereof. Doped antennae assembly electrodes, sensors and field-effect transistors are also provided using these methods.

In other aspects, the present invention provides antennae assembly field-effect transistors, comprising: a substrate comprising a source and a drain; a gate oxide layer at least partially surmounting the substrate, source and drain; an electrically conductive layer at least partially surmounting the gate oxide layer; and an assembly of doped MWNT antennae vertically oriented with respect to the electrically conductive layer.

The present invention also provides sensors, comprising: at least two electrodes situated on a substrate, wherein at least one of the electrodes comprises an antennae assembly electrode, wherein the antennae assembly electrode comprises an electrically conductive layer at least partially surmounting a substrate; and an assembly of doped antennae vertically oriented with respect to the electrically conductive layer, wherein each of the doped antennae comprises a doped MWNT comprising: a base end attached to the electrically conductive layer, a mid-section comprising an outer surface surrounding a lumen, wherein at least a portion of the outer surface of the mid-section is capable of being in fluidic contact with an environment in contact with the antennae; a top end disposed opposite to the base end, and a dopant attached to or contained within the lumen, a dopant attached to or contained within the outer surface, a dopant attached to or contained with the top end, or any combination thereof.

In other aspects, the present invention provides antennae assembly electrodes, comprising: an electrically conductive layer at least partially surmounting a substrate; and an assembly of antennae vertically oriented with respect to the electrically conductive layer, wherein each of the antennae comprises a MWNT comprising: a base end attached to the electrically conductive layer, a mid-section comprising an outer surface surrounding a lumen, wherein at least a portion of the outer surface of the mid-section is capable of being in fluidic contact with an environment in contact with the antennae; and a top end disposed opposite to the base end. Sensors and field-effect transistors are also provided using these electrodes.

The present invention also provides methods of making an antennae assembly electrode, comprising the steps of: surmounting a substrate with an electrically conductive layer; and surmounting an assembly of antennae on the electrically conductive layer giving rise to the antennae being vertically oriented with respect to the electrically conductive layer, wherein each of the antennae comprises a MWNT comprising a base end being attached to the electrically conductive layer; a mid-section comprising an outer surface surrounding a lumen; and a top end being disposed opposite to the base end.

The present invention also provides methods of growing non-aligned MWNTs on a substrate, comprising: depositing a nickel metal catalyst on a substrate; and contacting the nickel metal catalyst with a gas mixture comprising a carrier gas and a carbon source gas at a temperature in the range of from about 650° C. to about 750° C., the carbon source gas comprising acetylene, wherein the substrate comprises silicon, silicon dioxide, silicon nitride, phosphorus doped poly silicon, or boron doped P-type silicon, to give rise to non-aligned MWNTs attached to the nickel metal catalyst.

The present invention also provides methods of growing aligned MWNTs on a substrate, comprising: contacting a substrate with a gas comprising a carrier gas and a carbon source gas at a temperature in the range of from about 800° C. to about 960° C., the carbon source gas comprising iron (II) phthalocyanine, wherein the substrate comprises silicon, silicon dioxide, silicon nitride, phosphorus doped poly silicon, or boron doped P-type silicon, to give rise to aligned MWNTs attached to the substrate.

The present invention also provides methods of growing aligned MWNTs on a substrate, comprising: depositing a nickel metal catalyst on the titanium barrier layer; and contacting the nickel metal catalyst with a gas mixture comprising a carrier gas and a carbon source gas at a temperature in the range of from about 650° C. to about 750° C., the carrier gas comprising argon, ammonia and hydrogen, the carbon source gas comprising acetylene, wherein the substrate comprises silicon, silicon dioxide, silicon nitride, phosphorus doped poly silicon, or boron doped P-type silicon, to give rise to aligned MWNTs attached to the nickel metal catalyst.

The present invention also provides methods of measuring the concentration of free chlorine in solution comprising: applying a voltage in the range from about +0.5 V to about −1.0V between a working electrode and a reference electrode and measuring the current on the working electrode corresponding to the concentration of free chlorine in solution, wherein the working electrode comprises electrically conductive diamond.

The present invention also provides methods of measuring free chlorine in solution comprising: applying a voltage between a working electrode and a reference electrode, and measuring the current on the working electrode corresponding to the concentration of free chlorine in solution, wherein the working electrode comprises carbon nanostructures.

The present invention also provides methods of measuring electrochemically-active species in solution comprising: applying a voltage between a working electrode and a reference electrode, and measuring the current on the working electrode corresponding to the concentration of electrochemically-active species in solution, wherein the working electrode comprises carbon nanostructures.

The present invention also provides electrochemical devices for measuring free chlorine concentration in an aqueous solution, comprising: a working electrode comprising carbon nanostructures, and a reference electrode, wherein each one of said electrodes is capable of contacting an aqueous solution comprising residual chlorine, said electrodes capable of being in ionic communication with the aqueous solution; and wherein the working and reference electrodes are operatively coupled to give rise to a measurable current at the working electrode upon application of a voltage between the working electrode and the reference electrode.

The present invention also provides electrochemical device, comprising: a working electrode comprising electrically conductive diamond; and a reference electrode; wherein the electrochemical device is capable of measuring a current on the working electrode, the current arising from the presence of an analyte in an aqueous solution upon the application of a voltage in the range of from about +0.5 V to about −1.0V between the working electrode and a the reference electrode, wherein said electrodes are capable of being in ionic communication with the aqueous solution.

The general description and the following detailed description are exemplary and explanatory only and are not restrictive of the invention, as defined in the appended claims. Other aspects of the present invention will be apparent to those skilled in the art in view of the detailed description of the invention as provided herein.

### BRIEF DESCRIPTION OF THE DRAWINGS

The summary, as well as the following detailed description, is further understood when read in conjunction with the appended drawings. For the purpose of illustrating the invention, there are shown in the drawings exemplary embodiments of the invention; however, the invention is not limited to the specific methods, compositions, and devices disclosed. In addition, the drawings are not necessarily drawn to scale. In the drawings:

FIG. 1A is a top-view perspective schematic illustration of an embodiment of a CNT array electrode of the present invention;

FIG. 1B is a side-view schematic illustration of the CNT array electrode of FIG. 1A;

FIG. 2A is a top-view perspective schematic illustration of an embodiment of a CNT array FET, which is suitable for ion sensing, of the present invention;

FIG. 2B is a side-view schematic illustration of the CNT array FET of FIG. 2A;

FIG. 3A is a top-view perspective schematic illustration of an embodiment of a CNT island array electrode of the present invention;

FIG. 3B is a side-view schematic illustration of the CNT island array electrode of FIG. 3A;

FIG. 4 is a schematic illustration of an embodiment of a multi-sensor CNT array chip of the present invention that includes integrated counter and reference electrode elements;

FIG. 5 is a schematic illustration of a cladded CNT peapod used in various embodiments of the present invention;

FIG. 6 provides illustrations of representative polymers that can be used as cladding and peapod materials for CNTs.

FIG. 7 provides illustrations of representative donor-acceptor polymer chemistries for CNT dopants;

FIG. 8A provides a schematic illustration of an embodiment of an element of a peapod CNT array FET of the present invention that can be used as a calcium ion selective sensor;

FIG. 8B provides a schematic illustration of an embodiment of an element of a cladded peapod CNT array FET of the present invention that can be used as an ammonia ion selective sensor;

FIG. 9 provides a schematic illustration of an embodiment of the method of the present invention for making a CNT array electrode;

FIGS. 10a-10r provides a schematic illustration of an embodiment of the method of the present invention for making a CNT array FET;

FIG. 11 provides a schematic illustration of an embodiment of the method of the present invention for making a CNT island array electrode;

FIG. 12 provides a schematic illustration of a suitable CVD furnace and auxiliary equipment for preparing CNT array electrodes of the present invention;

FIG. 13 provides a schematic illustration of equipment suitable for radio frequency sputtering and plasma polymerization of polymer cladding materials used in various embodiments of the present invention.

FIG. 14 shows a fabrication process of catalyst insulation and mechanical support.

FIG. 14I setup for thermal chemical vapor deposition

FIG. 14J shows aligned multiewalled carbon nanotubes (ACNTs) grown on Patterned Chip with growth conditions; Ar/H₂/Temp/FePc/Time:80/75/902/0.6/5 min.

FIG. 14K shows ACNTs grown on Patterned Chip with growth conditions; Ar/H₂/Temp/FePc/Time:20/20/902/0.4/20 min.

FIG. 14L shows ACNTs grown on Patterned Chip with growth conditions; Ar/H₂/Temp/FePc/Time:20/20/902/0.4/20 min. And post-clean up process carried out to remove the sacrificial Copper layer.

FIG. 14M shows ACNTs grown on Patterned Chip with growth conditions; Ar/H₂/Temp/FePc/Time:20/20/902/0.4/20 min. And post-clean up process carried out to remove the sacrificial Copper layer.

FIG. 15A shows Non-aligned multiwalled CNTs grown on 30 nm Ni on Poly-silicon with gas ratio of Ar/H₂/C₂H₂: 100/20/15 sccm at 745° C.

FIG. 15B shows Non-aligned multiwalled CNTs grown on 30 nm Ni on P-type silicon with gas ratio of Ar/H₂/C₂H₂; 100/20/15 sccm at 745° C.

FIG. 15C shows Non-aligned patterned CNTs grown on 60 nm Ni on cracked Poly-silicon with gas ratio of Ar/H₂/C₂H₂; 100/20/15 at 745° C.

FIG. 15D shows aligned multiwalled CNTs carpet (approximately 10 micron long) grown on Poly Si/Ti 50 nm/Ni 30 nm (sample was annealed at 400° C. for 15 hours) with gas ratio of Ar/H₂/C₂H₂; 100/20/15 sccm at 745° C.

FIG. 15E shows aligned multiwalled CNTs carpet (approximately 35 micron long) grown on Poly Si/Ti 50 nm/Ni 30 nm (sample was annealed at 400° C. for 15 hours) with gas ratio of Ar/H₂/C₂H₂; 80/75/15 sccm at 745° C.

FIG. 15F shows 35 micron long ACNTs bundle scratch off from the substrate. Growth conditions same as described in FIG. (d).

FIG. 15G shows aligned multiwalled CNTs carpet grown on Poly Si/Ti 50 nm/Ni 30 nm (substrate was annealed at 400° C. for 15 hours) with gas ratio of H₂/C₂H₂; 155/15 at 745° C.

FIG. 15H C shows aligned multiwalled CNTs carpet grown on Poly Si/Ti 50 nm/Ni 30 nm (sample was annealed at 400° C. for 15 hours) with gas ratio of Ar/NH₃/C₂H₂; 250/150/25 sccm at 745° C.

FIG. 15I shows aligned patterned CNTs grown on 30 nm Ni on 50 nm Ti on Poly-silicon (patterned sample was annealed at 400° C. for 15 hours) with gas ratio of Ar/H₂/C₂H₂; 30/125/20 sccm at 745° C.

FIG. 15J shows TEM image of multiwalled CNTs grown on 30 nm Ni on Poly-silicon with gas ratio of Ar/H₂/C₂H₂: 100/20/15 sccm at 745° C.

FIG. 15K shows TEM image of multiwalled CNTs grown on 30 nm Ni on P-type silicon with gas ratio of Ar/H₂/C₂H₂; 100/20/15 sccm at 745° C.

FIG. 15L shows TEM image of patterned CNTs grown on 60 nm Ni on cracked Poly-silicon with gas ratio of Ar/H₂/C₂H₂; 100/20/15 at 745° C.

FIG. 15M shows TEM image of multiwalled CNTs carpet grown on Poly Si/Ti 50 nm/Ni 30 nm (sample was annealed at 400° C. for 15 hours) with gas ratio of Ar/H₂/C₂H₂; 100/20/15 sccm at 745°.

FIG. 16A shows a setup for thermal chemical vapor deposition.

FIG. 16B shows ACNTs grown on P-type Si with growth conditions; Ar/H₂/Temp/FePc/Time:40/75/902/0.6/8 min.

FIG. 16C shows ACNTs grown on Quartz with growth conditions; Ar/H₂/Temp/FePc/Time:20/20/902/0.4/20 min.

FIG. 16D shows ACNTs grown on SiOx with growth conditions; Ar/H₂/Temp/FePc/Time:40/110/902/0.3/10 min.

FIG. 16E shows ACNTs grown on SiN with growth conditions; Ar/H₂/Temp/FePc/Time:40/120/902/0.3/10 min.

FIG. 16F shows ACNTs grown on P-type Si with growth conditions; Ar/H₂/Temp/FePc/Time:80/150/820/0.6/6 min.

FIG. 16G shows Chip # SP457 ACNTs grown on P-type Si with growth conditions; Ar/H₂/Temp/FePc/Time:80/75/960/0.6/1.5 min.

FIG. 16H shows ACNTs grown on P-type Si with growth conditions; Ar/H₂/Temp/FePc/Time:100/100/900/0.4/5 min.

FIG. 16I shows TEM image of multiwalled CNTs grown on SiOx with growth conditions; Ar/H₂/Temp/FePc/Time:15/20/900/0.5/10 min.

FIG. 16K shows a TEM image of multiwalled CNTs grown on P-type Si with growth conditions; Ar/H₂/Temp/FePc/Time:80/75/960/0.6/5 min.

FIG. 17 shows a fabrication process of catalyst insulation and mechanical support.

FIGS. 18A and 18B: (a) SEM of ACNT film before supercritical treatment; (b) TEM of ACNT before supercritical treatment.

FIG. 18C and FIG. 18D: (a) SEM of ACNT film after supercritical treatment; (b) TEM of ACNTs after supercritical treatment.

FIG. 18E Line scans EDX of ACNT after supercritical treatment.

FIG. 18F High resolution TEM of SWNT sample after supercritical treatment.

FIG. 18G Signature CV of 100 ppm 64BFA dissolved in methylene chloride solution in presence of 0.05 M tetra butyl ammonium hexafluoro phosphate supporting electrolyte.

FIG. 18H 0.05 M tetra butyl ammonium hexafluoro phosphate supporting electrolyte in methylene chloride solvent. Scan rate 20 mV/s. ACNT film electrochemical analyses after SFT treatment.

FIG. 18I SEM characterization of ACNT sample after supercritical treatment with conditions 2.

FIG. 18J 0.05 M tetra butyl ammonium hexafluoro phosphate supporting electrolyte in methylene chloride solvent, Scan rate 20 mV/s. ACNT film electrochemical analysis after condition 2 treatment.

FIG. 19A i-E curve for the electrolysis of 0.1 M ClO— in 0.1 M phosphate buffer.

FIG. 19B Typical amperometric reduction curves obtained for the reduction of hypochlorous acid in 18.2 MΩ-cm water. R²=0.9888 in this case.

FIG. 19C Effect of conductivity (mS/cm, plot on the left) and pH vs. the concentration of chlorine in its solutions.

FIG. 19D Plots of resulting reduction charge Vs. free chlorine concentration using CNT electrodes (with and without the addition of electrolyte). For comparison, a similar plot using a commercial doped diamond electrode is also presented.

FIG. 19E Free chlorine Reduction Reaction: Comparison of the response of CNTs, Diamond, Glassy Carbon and Gold. Reduction performed at constant potential of 0 V, applied for 5 s in 0.05 M phosphate buffer.

FIG. 19F Response Precision of Free Chlorine Reduction Reaction, n=10.

FIG. 20A Typical calibration curve for the solid contact Ca-ISE (Chip# SP-97). 10⁻¹-10⁻⁵ M CaCl₂ solutions were prepared in Tris Buffer (pH 7.4) and the EMF was measured against Ag/AgCl reference electrode.

FIG. 20B Doped and Undoped PANI response to Calcium. 10⁻¹-10⁻⁵ M CaCl₂ solutions were prepared in Tris Buffer (pH 7.4) and the EMF was measured against Ag/AgCl reference electrode.

FIG. 20C Calibration curve for the solid contact Ca-ISE (Chip # SP-158). 10⁻¹-10⁻⁴ M CaCl₂ solutions were prepared in Tap H₂O and the EMF was measured against Ag/AgCl reference electrode.

FIG. 20D SEM images of the prepolymerized CNT film (Chip # SP-169). a) Cross sectional view of the conducting polymer-CNT cladding. The side walls of the CNTs are visible and b) Top view of the structure.

FIG. 20E Selectivity studies for Ca²⁺ selective electrode (Chip # SP-97). (▪) Response for Ca²⁺ in DI H₂O and (♦) Response for 0.01 M CaCl₂ in 10⁻¹-10⁻⁴ M KCl.

FIG. 20F Experimental time traces for the EMF measurements of the pre-polymerized PANi (Chip # SP-171).

FIG. 21 illustrates an exemplary schematic of a residual chlorine measuring device.

FIG. 22 illustrates a linear sweep voltammogram from about −1V to about +1V for several residual chlorine concentrations.

FIG. 23 illustrates the amperometric response of a diamond electrode where the potential is stepped from a resting potential (about +0.6V versus Ag/AgCl) to the applied potential (about −0.1V versus Ag/AgCl) at which chlorine reduction occurs.

FIG. 24 illustrates a calibration curve of residual chlorine concentrations and current values in applied potential of about −0.1V versus Ag/AgCl.

FIG. 25 shows a scanning electron micrograph of a carbon nanotube array chip that may be used, for example, for detection of free chlorine in drinking water.

FIG. 26a shows linear sweep voltammetry for 0, 1, 2, 3 and 4 ppm of free chlorine.

FIG. 26b shows a chronoamperometry scan at −0.15V for 2 min for 0, 1, 2, 3 and 4 ppm of free chlorine.

FIG. 27 shows a sub-ppm chronoamperometry scan for free chlorine detection on a carbon nanotube array sensor.

FIG. 28 shows the current through a carbon nanotube array sensor as a function of chlorine concentration.

FIG. 29 shows a scanning electron micrograph of a carbon nanotube array chip that may be used, for example, for detection of free chlorine in drinking water.

FIG. 30a shows linear sweep voltammetry for 0, 1, 2, 3 and 4 ppm of free chlorine.

FIG. 30b shows a chronoamperometry scan at −0.15V for 2 min for 0, 1, 2, 3 and 4 ppm of free chlorine.

### DETAILED DESCRIPTION OF ILLUSTRATIVE EMBODIMENTS

The present invention may be understood more readily by reference to the following detailed description taken in connection with the accompanying figures and examples, which form a part of this disclosure. It is to be understood that this invention is not limited to the specific devices, methods, conditions or parameters described and/or shown herein, and that the terminology used herein is for the purpose of describing particular embodiments by way of example only and is not intended to be limiting of the claimed invention. Also, as used in the specification including the appended claims, the singular forms “a,” “an,” and “the” include the plural, and reference to a particular numerical value includes at least that particular value, unless the context clearly dictates otherwise. When a range of values is expressed, another embodiment includes from the one particular value and/or to the other particular value. Similarly, when values are expressed as approximations, by use of the antecedent “about,” it will be understood that the particular value forms another embodiment. All ranges are inclusive and combinable.

It is to be appreciated that certain features of the invention which are, for clarity, described herein in the context of separate embodiments, may also be provided in combination in a single embodiment. Conversely, various features of the invention that are, for brevity, described in the context of a single embodiment, may also be provided separately or in any subcombination. Further, reference to values stated in ranges include each and every value within that range.

Terms.

As used herein, “residual chlorine” refers to the amount of chlorine remaining in water after chlorine is reacted with or absorbed by substances, for example an organic compound, present in the water. For example, an organic compound in water may react with chlorine. The chlorine remaining in water after the completion of the reaction is the residual chlorine.

As used herein, “free chlorine” refers to the form of residual chlorine in water present as dissolved chlorine gas (Cl₂), hypochlorous acid (HOCl), and hyprochlorite ion (OCl—). The three forms of free chlorine exist together in equilibrium. Free chlorine does not bind with other molecules in water.

As used herein, “combined chlorine” refers to the form of residual chlorine existing in water in chemical combination with ammonia or organic amines.

As used herein, “total chlorine” refers to the sum of free chlorine and combined chlorine.

As used herein, “working electrode” refers to the electrode in an electrochemical system on which the reaction of interest is occurring. The working electrode is often, but not always, used in conjunction with a counter electrode, and a reference electrode in a three-electrode system.

As used herein, “reference electrode” refers to an electrode which has a stable and well-known electrode potential.

As used herein, “counter electrode” refers to an electrode used in an electrochemical cell in which an electrical current is expected to flow through.

As used herein, “diamond coated electrode” refers to an electrode coated with diamond thin film. A diamond thin film can be deposited onto an electrode substrate, for example, using microwave-assisted chemical vapor deposition.

As used herein, “hydrogen-terminated diamond coated electrode” refers to a diamond coated electrode whose surface carbon atoms are covalently bonded to hydrogen.

As used herein, “amorphous carbon” refers to an allotrope of carbon that does not have any crystalline structure.

As used herein, “2D-3D graphene structures” refers to a one-atom-thick planar sheet of sp²-bonded carbon atoms.

As used herein, “fullerites” refers to the solid-state manifestation of fullerenes and related compounds and materials. For example, polymerized Single Walled Carbon nanotubes are a class of fullerites and are comparable to diamond in terms of hardness, but do not necessarily possess similar crystal lattice structure as diamond.

As used herein, “fullerene molecules” refers to molecules that are similar in structure to graphite, which graphite is composed of stacked sheets of linked hexagonal rings, but may also contain pentagonal (or sometimes heptagonal) rings that would prevent a sheet from being planar.

As used herein, “buckyballs” refers to spherical fullerenes.

As used herein, “buckytubes” refers to cylindrical fullerene molecules, for example, carbon nanotubes

As used herein, “carbon nano wires” refers to electrically conducting or semi-conducting nanofibers composed of carbon.

As used herein, “carbon nano horns” refers to irregular carbon nanotubes-like nano-object having a nanocone apex.

As used herein, “carbon nano cones” refer to hollow cone-shaped nano-structures.

As used herein, “carbon nano fibers” refers to cylindric nanostructures having graphene layers arranged as stacked cones, cups or plates. For example, carbon nanofibers with graphene layers wrapped into perfect cylinders are called carbon nanotubes.

As used herein, “carbon/graphene nano ribbons” refers to nanofibers having one of its shorter dimensions much smaller than the other.

As used herein, “carbon nano spheres” refers to a single sheet of graphene formed into a sphere, constituting a carbon nanosphere, also known as buckyball.

As used herein, “carbon nano rods” referfs to a solid carbon nanofibre.

As used herein, “carbon nano onions” refers to carbon nanoparticles obtained from either arcing of graphite under water or thermal annealing of nanodiamonds are commonly called carbon nano onions (CNOs), or spherical graphite, as they are made of concentric fullerene cages separated by the same distance as the shells of graphite.

As used herein, “carbon nanotori” refers to carbon nanotubes bent into a toroid.

As used herein, “carbon nano buds” refers a material which combines two previously discovered allotropes of carbon: carbon nanotubes and fullerenes, the fullerenes being covalently bonded to the outer sidewalls of an underlying nanotube.

As used herein, “carbon peapod structures” refers to a molecular assembly of buckyballs inside carbon nanotubes.

As used herein, “electric current” refers to the flow of electric charge, for example, mobile electrons in a conductor, flow of ions in an electrolyte, or flow of ions in a plasma.

As used herein, “CNT” means carbon nanotube.

As used herein, “aligned CNTs” refers to a plurality of CNTs that are substantially grown perpendicularly to the plane of the substrate.

As used herein, “non-aligned CNTs” refers to a plurality of CNTs that are not substantially grown perpendicularly to the plane of the substrate.

As used herein, “thermal chemical vapor deposition” refers to thin film deposition under high temperature, and gas flows.

As used herein, “arc discharge process” refers to an electrical breakdown of a gas which produces an ongoing plasma discharge resulting from a current flowing through normally nonconductive media

As used herein, “laser-ablation process” refers to a process of removing material from a solid (or occasionally liquid) surface by irradiating the material with a laser beam. At low laser flux, the material is heated by the absorbed laser energy and evaporates or sublimes. At high laser flux, the material is typically converted to a plasma.

As used herein, “plasma enhanced chemical vapor deposition” refers to a process used to deposit thin films from a gas state to a solid state on a substrate which is placed between two electrodes where chemical reactions occurs after creation of a plasma.

As used herein, “capacitatively coupled microwave plasma process” refers to a process used to deposit thin films from a gas state to a solid state on a substrate which is placed between two electrodes where chemical reactions occurs after creation of a plasma by microwave frequency discharge.

As used herein, “a capacitively coupled electron cyclotron resonance process—is a process used to deposit thin films from a gas state to a solid state on a substrate by an ionized plasma which may be efficiently produced or heated by superimposing a static magnetic field and a high-frequency electromagnetic field at the electron cyclotron resonance frequency.

As used herein, “capacitively coupled radiofrequency process” refers to a process used to deposit thin films from a gas state to a solid state on a substrate which is placed between two electrodes where chemical reactions occurs after creation of a plasma by radio frequency discharge.

As used herein, “inductively coupled plasma process” refers to a chemical vapor deposition process assisted by a type of plasma source in which the energy is supplied by electrical currents which are produced by electromagnetic induction, that is, by time-varying magnetic fields.

As used herein, “template synthesis” refers to a process to selectively grow CNTs on a substrate masked by a pre-design template.

The antennae assembly electrodes include an electrically conductive layer at least partially surmounting a substrate; and an assembly of doped antennae vertically oriented with respect to the electrically conductive layer. Each of the doped antennae comprises a doped MWNT comprising: a base end attached to the electrically conductive layer, a mid-section comprising an outer surface surrounding a lumen, wherein at least a portion of the outer surface of the mid-section is capable of being in fluidic contact with an environment in contact with the antennae. The doped MWNT also has a top end disposed opposite to the base end, and a dopant attached to or contained within the lumen, a dopant attached to or contained within the outer surface, a dopant attached to or contained within the top end, or any combination thereof. Sensors and field-effect transistors can be suitably fashioned using these antennae assembly electrodes, as described further herein.

In certain aspects of the present invention there are provide MWNT based sensors that are composed of electrode arrays comprising aligned MWNTs that can be electrically conductive as well as chemically inert to water and biological media. Suitable sensors are capable of sensing one, and preferably more than one analytes in a test fluid. Such carbon material structures make ideal electrochemical sensors by evoking two properties of electrodes; the chemical inertness of diamond with the electrical conductivity (i.e., electron mobility) of a metal. The chemical inertness relates to the ability to measure an electro-chemical reaction without memory (i.e., retention) of such reaction. The graphene electron conductivity of MWNTs can range from metallic to semi-conducting while the surface chemistry can be controlled by varying the environmental conditions, such as, temperature, pressure, and chemical environment. The unique properties of MWNTs allow for the adaptation to novel detection schemes by manipulating conduction of CNTs and mediating such characteristic by chemical doping.

CNT's may be grown by Chemical Vapor Deposition (CVD) into a template of perpendicularly aligned arrays of CNT electrodes. The CNTs diameter, length and pitch is controlled by the chemical vapor deposition (“CVD”) growth process to create a spaced NT electrode array structure that optimizes effective electrolysis surface, yet minimizes Ohmic loss through the sample medium. In certain aspects, the nominally idealized CNT nanoarray structure comprises a 10:1 pitch:diameter ratio at nanometer dimensions. Without being bound by any particular theory of operation, the CNT nanoarray structure of various embodiments of the present invention apparently minimizes analytical measurement errors that are otherwise present in conventional electrode structures and materials.

The readily achievable CNT structural design disclosed herein provides a number of beneficial design attributes that are especially important for monitoring drinking water. The low salt content (high electrical impedance) of drinking water presents a unique challenge to electrochemical measurement because small variation in electrolyte content will introduce significant measurement error. The ability to measure variable conductivity water samples from drinking water to sea water without analytical performance degradation is an important criterion of robust product technology and especially important for continuous monitoring.

The CNT sensors can be used in different modes to selectively detect analytes. In one mode, the CNTs can be used as a source or depository of electrons to be exchanged with the medium in an electrolytic reaction. In a second mode, the CNTs can be used to function as a static electric field measurement in the potentiometric mode (i.e, zero current flow.) In some embodiments, CNT sensors can be used in continuous electrolytic monitoring of strong oxidants (such as chlorine) in drinking water.

Without being bound to a particular theory of operation, the CNT sensors are particularly well-suited for use in strong oxidants because of the high chemical resistance of CNTs. In electrochemical terms, the CNTs surface chemistry is essentially unaffected by chlorine in the presence or absence of electrolysis. This is characteristically unlike noble metal electrodes (e.g., Pt or Au) in which the surface can indeed be oxidized or electrolytically altered. This property allows for a broad operating voltage window for measuring electro-active molecules in water using various embodiments of the CNT-based sensors of the present invention. CNT working electrodes operating in the electrolytic measurement mode do not necessarily require coatings or dopants to effect selective measurement. In one embodiment, specificity and sensitivity of redox response is essentially enhanced by voltage (i.e., bias) programming techniques. Molecules with redox potentials that fall outside the operating voltage window can be mediated by dopants to shift the energy (i.e., voltage) to within the operating voltage window. Programming techniques are provided in U.S. Pat. No. 5,120,421 to Glass et al., “Electrochemical sensor/detector system and method”, the portion of which pertaining to programming is incorporated by reference herein.

In the potentiometric mode, the CNTs can measure static electric fields generated by ion charge accumulation. In these embodiments, the CNTs can be doped with selective ligand molecules that selectively bind ions. Such a CNT ion sensor can be employed to detect calcium ion content in drinking water as a measure of water hardness. In this mode, and without being bound by any particular theory of operation, the electrical conductivity of CNTs tends to be irrelevant to the measurement and the CNT appears to function as a conduit for the measure of static charge. In this mode, the dopant chemistry evokes selective chemical response which appears to be manifested as a chemical potential or voltage sensed by the CNT.

Doping of CNTs can be accomplished in several ways, i.e., by; “peapod” formation (e.g., nanotubes containing other atoms, molecules, or both residing within the interior of the nanotube), polymer film coatings/claddings of CNTs, and by chemical linkage to the graphene carbon of the CNT and/or linkage to the cladding. Further details on forming CNT peapods can be found in U.S. Pat. No. 6,863,857, “Hybrid materials and methods for producing the same” to Luzzi and Smith, the portion of which pertaining to the formation of filled CNTs is incorporated by reference herein. A doping embodiment can be characterized by a peapod structure created by one or more active reagents (or dopants) to a CNT lumen and annealing the CNT to encapsulate the active reagents or dopants. Without being bound by any particular theory of operation, this provides a cocoon-like CNT protection of active reagent or dopant while providing electron exchange (i.e., tunneling) between the interior dopant and the outside medium. The graphene carbons of the CNTs are believed to function as a conduit for electron transfer between the oxidation state of the sample molecule and the measurement circuit. The peapod electrolysis current is a measure of the rate of electron transfer incurred by the sample and mediated by dopant. In embodiments when the dopant is an ionophore, ion charge accumulation on the CNT can be manifested as a voltage that is related thermodynamically to the electrolyte solution chemical potential. Large binding constants of ion-ligand complex formation favors the partitioning of charge to the interior of the filled MWNT and the electric field generated is in equilibrium with sample ion content.

Another way to dope the MWNTs is to use electrospray ionization, which can selectively deposit dopants in, or on, particular MWNTs on the electrode. Details of selective doping of particular nanotubes on antennae assembly electrodes using electrospray are provided in U.S. Provisional Patent Application Ser. No. 60/762,613, “Electrospray Deposition: Devices and Methods Thereof”, by Salvatore Pace and Francis Man, filed Jan. 26, 2006, the entirety of which is incorporated by reference herein.

In certain embodiments, doped polymeric claddings that coat the CNT (i.e., graphene) backbone may be formed by free radical polymerization from organic monomers. Free radical polymerization may be mediated by a number of methods know in the art, including RF plasma reaction (i.e., in the gas phase), by electrolytic polymerization (i.e., in the liquid phase), or any combination thereof. One scheme for polymer impregation is accomplished by trapping dopant coincident with the polymerization in a co-deposition process. Alternatively, a polymer CNT cladding can be impregnated by phase transfer partitioning, for example, by using supercritical fluid carbon dioxide (“scCO₂”) as a partitioning solvent. Stable CNT interfacial boundaries can be created using a selective reagent that chemically links to the CNT backbone as a precursor step to polymer coating (i.e., cladding). In one embodiment, combining a peapod structure with an exterior CNT coating gives rise to unique reagent interactions depicted by the interplay of sample modulated electro-chemiluminescent (ECL) emission (e.g., Example #6). An ammonia sensor (e.g., Example #3) is another example of the interplay between the gas barrier PTFE cladding and a nonactin-doped peapod CNT.

The present invention relates to the design and methods of fabrication of MWNT chemical and biological sensors and their use thereof. MWNTs can be chemically doped with reagents to respond electro-chemically and/or photo-chemically to specifically targeted molecules in water samples and biological media. Devices and methods of detection are also provided that measure the transduction of chemical to electrical or chemical to photonic signals. These signal can be electronically processed to yield high sensitivity and specificity responses to a variety of analytically targeted molecules.

In one mode, the subject invention includes a plurality of CNT sensing elements patterned on a silicon chip. Each CNT sensing element comprises a plurality of substantially aligned MWNTs grown perpendicularly to the plane of the substrate (Si) and subject to contact or exposure to test sample fluid. Additional circuit elements may also be mounted on the substrate (e.g., a silicon chi, such as electrical conduits, termination points and amplifiers, photon sources, and other components. CNT growth can be generated by chemical vapor deposition (CVD) and the geometric patterns defined by the electron-beam lithography of the metal catalyst. The CVD grown CNT array patterns can be perpendicularly aligned and in electrical contact with the metal. In one embodiment, a suitable CNT sensing element includes a silicon chip comprising a combination of electrochemical sensing elements based on redox electrolysis and charge coupled ion transduction. A combination of these elements comprise a multi-sensor chemical profiling chip. An example of a nominal drinking water test combination of free and total chlorine and water hardness would deploy the following sensors: CNT-gated FET for calcium, a CNT Working electrode for free chlorine and a doped/cladded CNT peapod working electrode-photodiode combination for tot-Cl₂ modulated electro-chemiluminescence.

CNT sensor elements can be fabricated with processes known to those of skill in the art of semiconductor materials and processing. Each CNT sensor element can be doped with selective reagent to impart chemical detection specificity. In one embodiment, for example, an ensemble of CNT sensor elements can be operated in concert to effect the chemical profiling of drinking water. In other embodiments, undoped CNTs can be voltage programmed to elicit selective responses for electro-active molecules such as chlorine and chloramines. Redox mediators such as Ru(bpy) can be electrolytically activated to generate photon emission that can also be modulated by sample interaction. In the potentiometric mode (charge coupling), CNTs can be doped with ionophores that selectively react with sample target ions. A combination of CNT sensor elements can therefore be selected to detect for a drinking water “disinfection profile” as outlined in Table I. The CNT sensor elements of the present invention provide a broad electrolysis operating window for water samples and also virtually eliminate artifacts such as ion transport partitioning and non-specific ion exchange at sample/membrane interfaces that diminish the ion detection (sensitivity) limit of conventional ion selective electrode (ISE) sensors.

Redox Detection—Electrolytic sensing: In another mode, a CNT sensor element is provided that can be operated in an electrolytic measurement mode. In this mode, the CNT sensor element does not chemically participate in the electrolysis, rather it functions as an inert working electrode surface to conduct electrolysis of electro-active molecules. This property allows the CNTs to measure electrolytic currents with little or no inter-sample surface memory effects that would otherwise compromise precision and accuracy. Doped mediators can also be suitably used to facilitate the electron transfer at the CNT to enhance the kinetics of electron transfer, to lower the energy (voltage) required for the measurement, or both. Mediated electron transfer suitably allows for electrolytic measurement in a useful voltage region.

Suitable redox mediators can be electrolytically activated to excited states resulting in photon emission as they dismutate to the ground state. Such transitions can be electrochemically initiated at the CNT working electrode and modulated by suitable redox active sample target molecules. In certain embodiments, analytes such as mono-chloroamine can be chemically oxidized by Ru(bipy)2+ dopant to Ru(bipy)3+ while Ru(bipy)3+ can be electrolytically reduced to the Ru(bipy)2+. The interaction between the Ru oxidized species within the cladding and the peapod (e.g., the reduced species) generates photon emission at 610 nm which is, in turn, modulated by the sample. Without being bound by any particular theory of operation, electrolysis at the CNT surface triggers the electro-chemiluminescence (“ECL”) although the modulation is chemically induced by a sample oxidant, such as chloramines. Hence, for drinking water samples, the emission intensity can be used to measure total chlorine.

Ion & Gas Detection—Potentiometric Sensing: The potentiometric (ISE) sensor (voltage measurement at zero current) can measure CNT charge accumulation (i.e., electric field), as a consequence of ionic charge buildup on the CNTs. The CNTs can be doped with suitable ionophores (e.g., cyclic polyethers) to induce a selective ion response of a test water sample. Various suitable ionophores can be used as described herein. Without being bound by any particular theory of operation, the ionophores function as a specific binding agent for the ion. Accordingly, the accumulation of charge on the CNT can be measured with an electrometer amplifier circuit. The CNTs function as a nanofield of antennas that receive the modulating ion charge that, in turn, measures a chemical potential (i.e., voltage).

The CNT sensor elements can be electronically passive (i.e., no amplifier). In other modes, the ISE structure can combine one or more CNT sensor elements with an active circuit such as a field effect transistor (FET). For example, the CNT's can be CVD grown and patterned directly on a gate surface of a suitable FET. Suitable FETs can have a gate that is ion specifically modulated by the sample solution/ionophore interaction. The modulated ion response (or chemical potential) is tuned by the ionophore CNT-dopant chemistry. In a further embodiment, integrating amplifiers to sensors on a substrate chip can be used to improve signal/noise characteristic signal performance

Multi-Sensor CNT Array: A multi-sensor CNT array can be patterned on a silicon substrate and subsequently doped with a plurality of selective reagent to evoke specific response to a plurality of sample target molecules. Each CNT feature can be modified to detect a single chemical species in a sample, such as drinking water. A portion of the sensing elements of the multi-sensor CNT array can comprise unmodified CNTs to measure electrolysis currents at appropriate bias voltages corresponding to the electro-active species. In this embodiment, select voltage programs can be used to measure test species. Other sensing elements can be doped (chemically altered) with ionophoric or redox mediating species to measure surface potentials based on accumulated ion charge or redox ratio of electro-active molecules.

Among the various sensor embodiments described herein, the CNTs can be in contact with a catalytic metal surface that is patterned on a silicon substrate which is provided as an integral circuit component of an electrode ensemble. This ensemble comprises an array of sensors deployed to contiguously and selectively measure a plurality of test analytes. In certain embodiments, the device also includes one or more counter and reference electrode elements that are integrated onto the chip structure. Such electrode elements can be strategically positioned on the sensor to provide electrochemical support function but do not necessarily partake in the selective sensing/response process.

### EXAMPLES AND OTHER ILLUSTRATIVE EMBODIMENTS AND DESCRIPTION

### Silicon Chip Design and Process Schemes for Aligned CNT Patterns

### I. CNT Array Working Electrode Pattern, FIG. [1], CNT Array Working Electrode Structure for Electrolytic Cell Configuration

Process Description. Referring to the sequence of process steps in FIG. 9, the process starts with a 100 mm silicon wafer substrate (902) with a 500 nm thermal oxide layer (904) on top (steps 1 and 2). The patterning of TiW/Mo/TiW electrically conductive layer (906) is performed in a two-step lithography process. In the first step, a liftoff resist is spin coated, and baked. In the second step, a conventional photo-resist is spin coated, exposed, and developed. During resist development, the developer not only removes the exposed photo-resist, it also removes and undercuts the liftoff resist such that when the wafer is immersed in acetone, the subsequent metal stack is lift off leaving a clean metal definition. Then a stack layer of TiW/Mo/TiW: 40 nm/40 nm/40 nm (b) is sputtered, followed by a reactive sputtering of 15 nm TiN (b). The metal stack (step 3) is then liftoff by immersing in acetone. Afterwards, a conventional liftoff process is performed where photo-resist is patterned to define the gold metal contact pad (908) with a Cr adhesion layer, followed by evaporation of a 50 nm of gold, and immersion in acetone liftoff solution (step 4). Similarly, the 7 nm nickel catalyst layer (d) is patterned by liftoff process using the liftoff resist to produce a sharp nickel metal interface. Next, a 500 nm layer of PECVD silicon nitride protective layer (910) is deposited at 380C (step 5). Contact holes (912) are patterned and etched in reactive ion etching (914) (step 6). After that, the wafer is ready for MWNT (916) growth where substrate (902) is exposed to acetylene and ammonia gas at 400° C. (step 7), followed by further chemical functionalization (918) (step 8) to give rise to a doped CNT array working electrode (900).

Process Flow

Starting Wafer
p-type boron doped 100 mm silicon wafer, single side polished

Thermal Oxide Deposition
500 nm thermal oxide at 1000C for 30 mins

Lithography 1—Interconnect
Spin LOR-5a 40H rpm for 10 sec
Softbake on hot plate for 5 mins at 180C
Spin 220 4 k rpm for 10 sec
Softbake on hot plate for 90 s at 115C
Expose 5 sec at 25.0 mW/cm2
Post-exposure bake on hot plate for 90 s at 115C
Develop in MIF 300 for 2 mins
Rinse 2 mins in DI, spin dry

TiW/Mo/TiW/TiN Interconnect Deposition
Sputter 40:40:40 nm of TiW/Mo/TiW onto wafer
Sputter 15 nm of Ti under nitrogen environment
Liftoff in acetone
Rinse 2 mins DI, spin dry

Lithography 2—Contact Pad
Spin HMDS 4 k rpm for 30 s
Spin 220 4 k rpm for 10 sec
Softbake on hot plate for 90 s at 115C
Expose 5 sec at 25.0 mW/cm2
Post-exposure bake on hot plate for 90 s at 115C
Develop in MIF 300 for 2 mins
Rinse 2 mins in DI, spin dry

Gold Metal Pad Deposition
Evaporate 10:100 nm of Cr/Au onto wafer
Liftoff in acetone
Rinse 2 mins DI, spin dry

Lithography 3—Catalyst Deposition
Spin LOR-5a 40H rpm for 10 sec
Softbake on hot plate for 5 mins at 180C
Spin 220 4 k rpm for 10 sec
Softbake on hot plate for 90 s at 115C
Expose 5 sec at 25.0 mW/cm2
Post-exposure bake on hot plate for 90 s at 115C
Develop in MIF 300 for 2 mins
Rinse 2 mins in DI, spin dry

Nickel Catalyst Deposition
Evaporate 7 nm of nickel onto wafer
Liftoff in acetone
Rinse 2 mins DI, spin dry

Passivation nitride Deposition
PECVD deposit 500 nm of silicon nitride at 380C

Lithography 4—Contact Opening
Spin HMDS 4 k rpm for 30 s
Spin 220 4 k rpm for 10 sec
Softbake on hot plate for 90 s at 115C
Expose 5 sec at 25.0 mW/cm2
Post-exposure bake on hot plate for 90 s at 115C
Develop in MIF 300 for 2 mins
Rinse 2 mins in DI, spin dry

Passivation nitride etch
Plasma etch, P=100 W, P=100 mT, CF₄=40 sccm, O₂=lsccm

MWNT Grow (by the PECVD-Acetylene method or the thermal CVD growth method; A. gas phase, B. solid precursor)
PECVD Acetylene: ammonia=54 sccm:200 sccm, P=5 mBar, T=675C. or Thermal CNT growth (as outlined below)

### II. CNT-gated MOSFET Pattern; FIG. [2]; CNT-gated MOSFET Structure for Ion

Detection

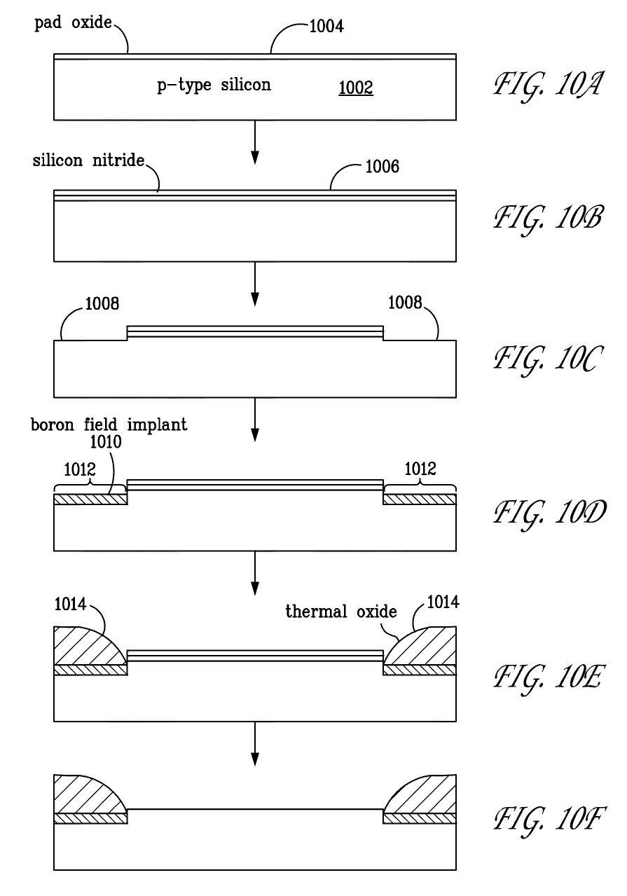

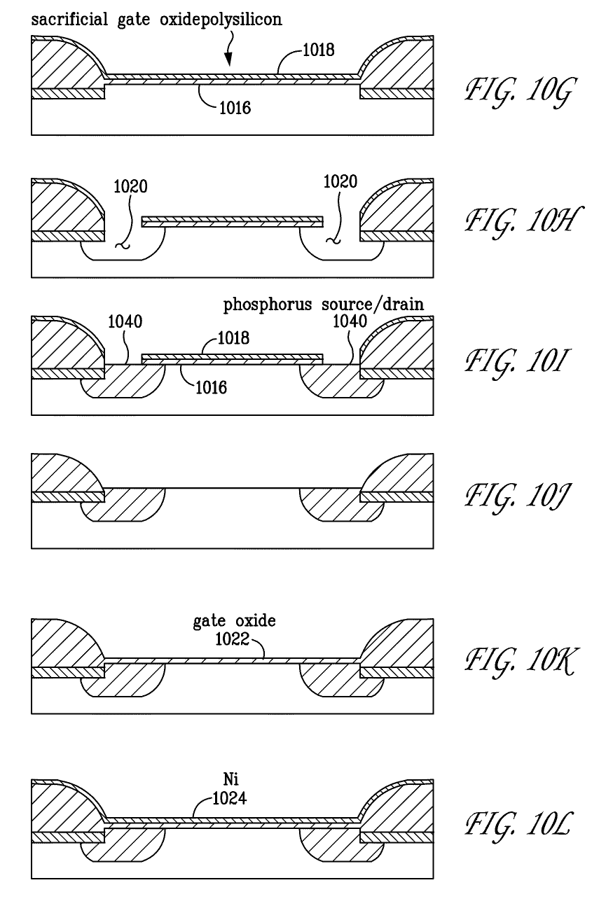

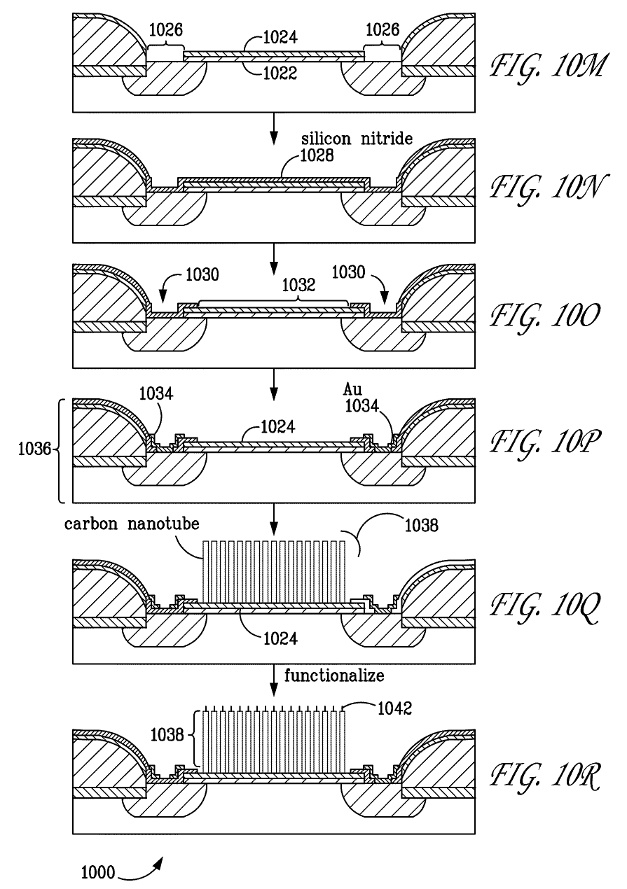

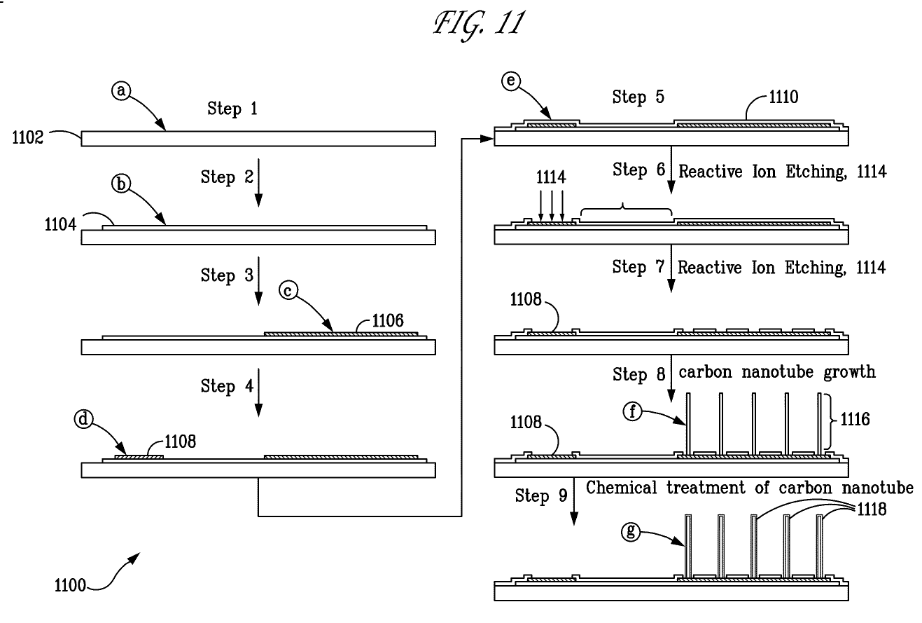

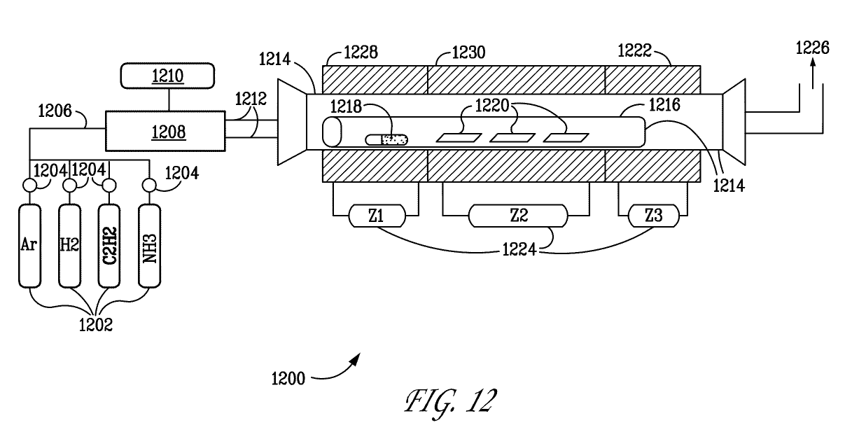

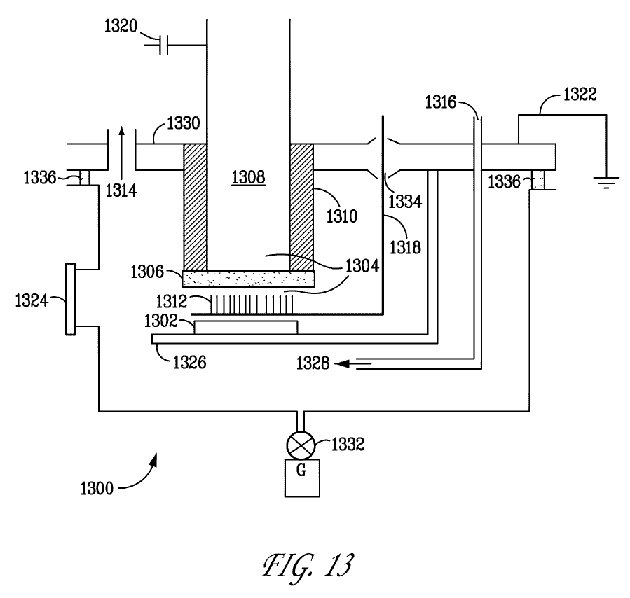

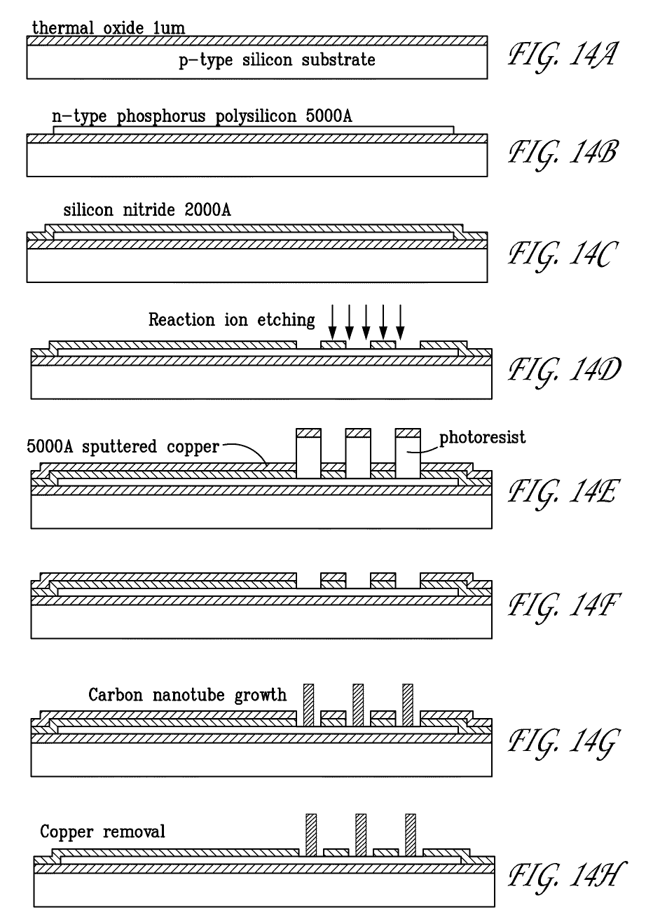

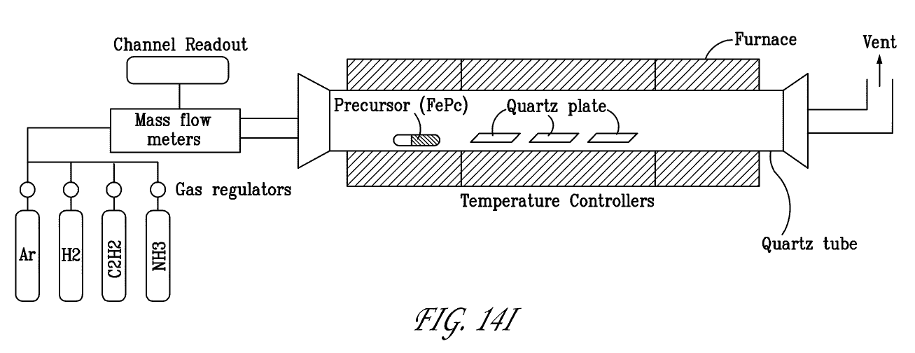

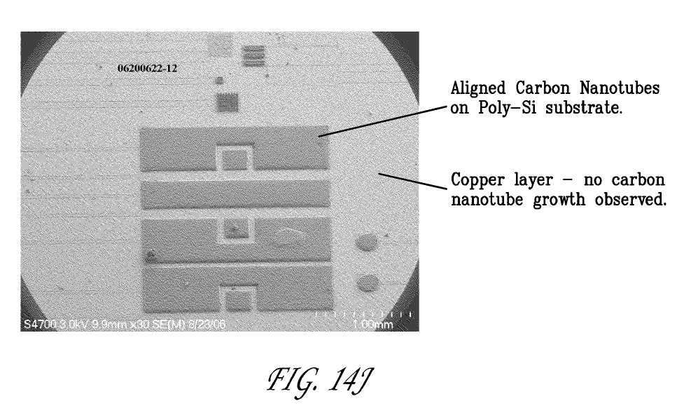

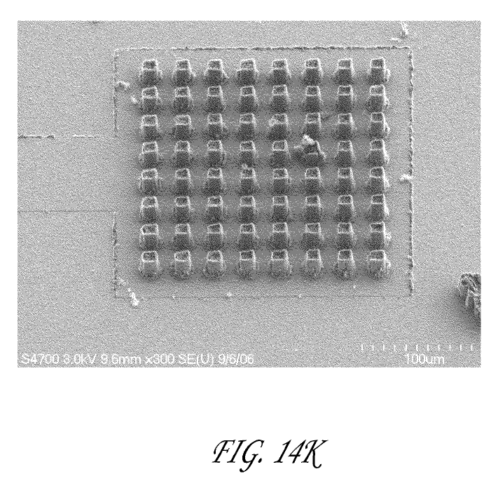

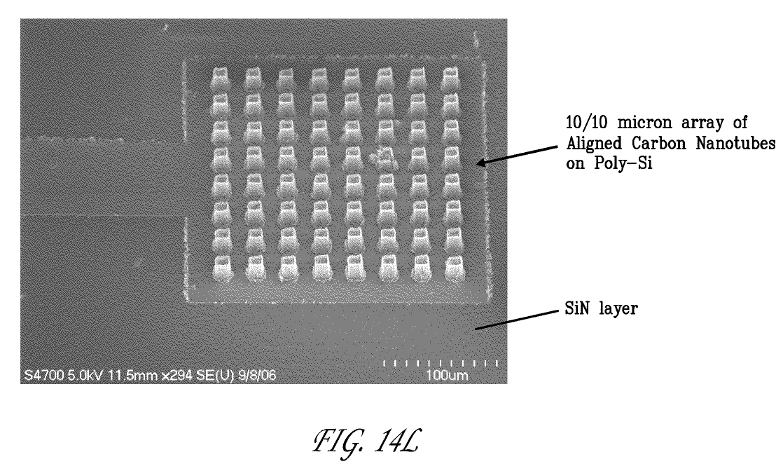

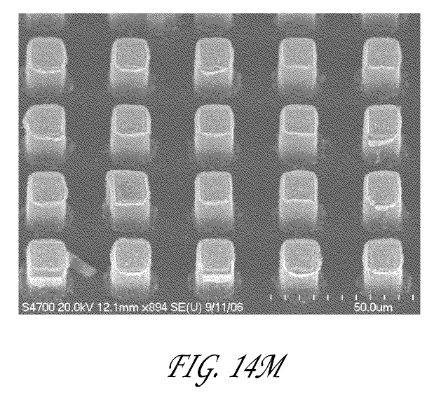

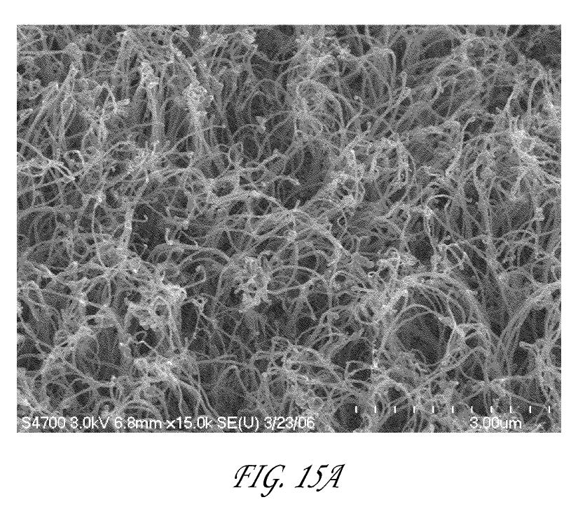

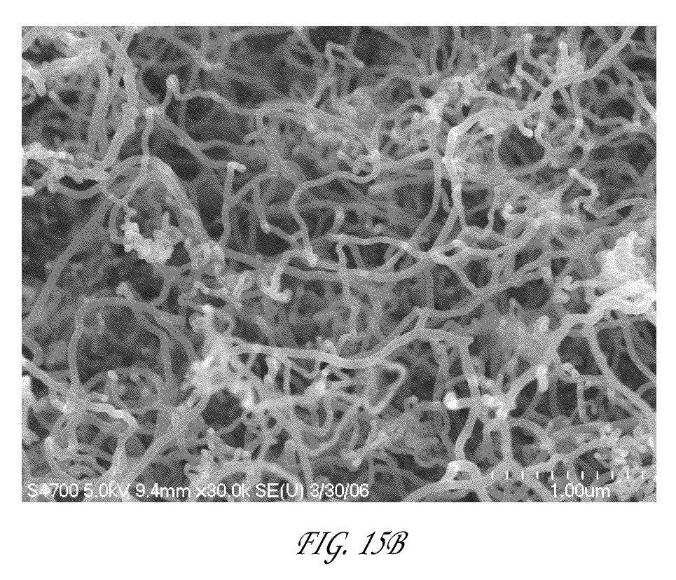

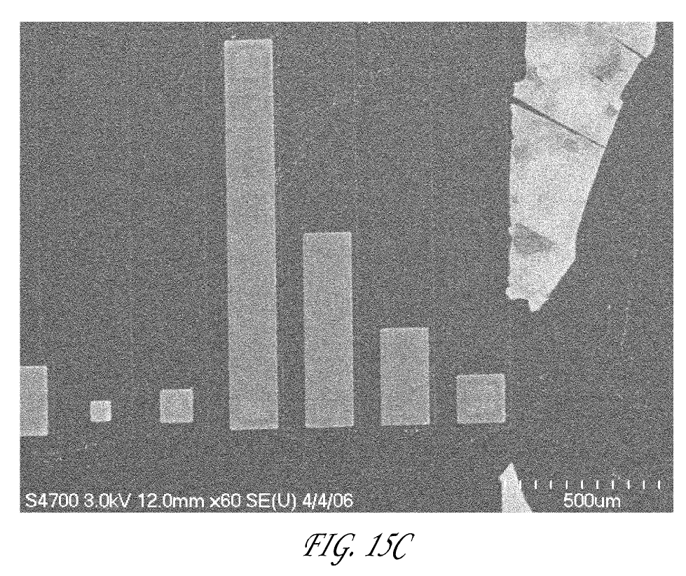

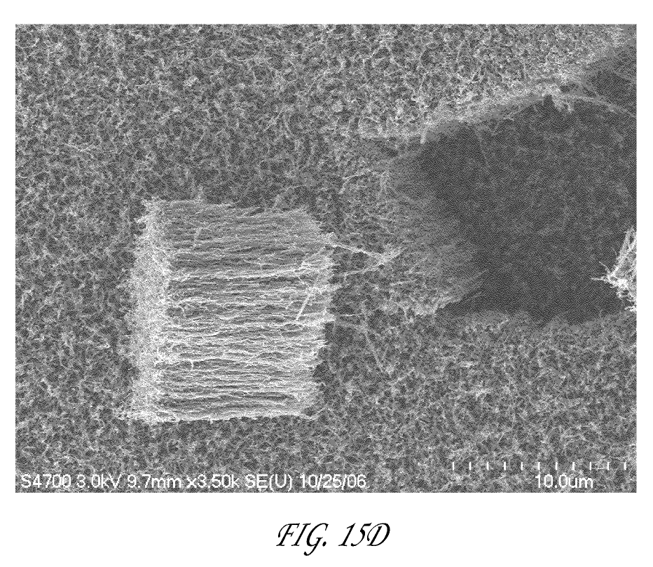

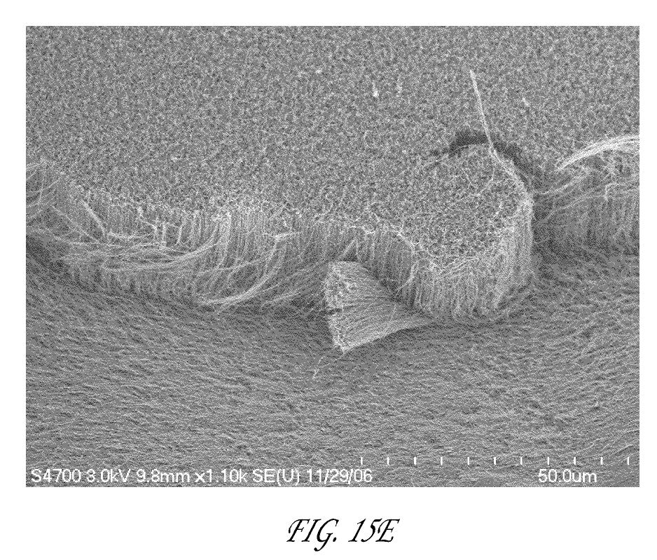

Process Description. Referring to the sequence of process steps in FIGS. 10a-10r, the starting material is a p-type silicon wafer (1002) with a 40 nm thick pad dioxide (1004) (FIG. 10a). A 200 nm thick LPCVD silicon nitride (1006) is then deposited at 820C (FIG. 10b). The nitride and pad oxide layer are patterned by conventional photo-resist, and etched in reactive ion etching followed by a 250 nm silicon recess etch (1008) (FIG. 10c). A dose of 5e13/cm2 boron (1010) is implanted at 60 kev to form the field implanation (FIG. 10d). After that, a 700 nm thick silicon dioxide (1014) is grown in the field area (1012) (FIG. 10e). Next, the nitride and pad oxide (1004, 1006) are stripped off by immersing into hot phosphoric acid and buffered hydrofluoric acid (FIG. 10f). A sacrificial gate oxide (1016) is grown at 1000C, followed by a polysilicon (1018) deposition at 625C (FIG. 10g). A conventional photo-resist is applied to define the source and drain areas (1020) of the transistor. Next, exposed polysilicon layer is etched using reactive ion etching and sacrificial gate oxide is wet etched (FIG. 10h). After that, a dose of phosphorus ion (1040) is implanted, followed by a drive-in (FIG. 10i). Subsequently, the polysilicon (1018) and oxide layer (1016) are sacrificially removed (FIG. 10j). Then another gate oxide (1022) is grown (FIG. 10k) and a 30 nm catalyst nickel layer (1024) is sputtered (FIG. 101). Conventional photoresist is then used to define the source and claim (1026) of each gate (1022) of the transistor where nickel (1024) and gate oxide (1022) is etched (FIG. 10m). A thin 200 nm of plasma-enhanced chemical vapor deposition (PECVD) silicon nitride is then deposited at 380C to form the passivation layer (1028) (FIG. 10n). The nitride is subsequently patterned and etched to define the contact holes (1030) to the source and drain (1026) and to reveal the CNT growth area (1032) (FIG. 10o). Photoresist (not shown) is next patterned and a 100 nm thick gold is then evaporated, and subsequently lift off to form metal contact (1034) (FIG. 10p). The wafer (1036) is then exposed to acetylene and ammonia gas at 400C (FIG. 10q) in a PECVD chamber where vertically aligned MWNTs (1038) are grown on the exposed nickel (1024). After that, the nanotubes are ready for chemical functionalization (doping) (FIG. 10r) with a dopant (1042).

Process Flow

Starting Wafer
p-type boron doped 1.2 ohm-cm, 100 mm silicon wafer <100>, single side polished

Grow Pad Oxide
Standard Prefurance cleaning—rinse to 15.2 M ohm-cm
Grow 40 nm of silicon dioxide: T_{dep}=22 min, dry O₂, 1000C, 40 nm thick
Anneal 10 min in N₂

LPCVD Nitride Deposition
Deposit 200 nm of LPCVD nitride: 820C, T_{dep}=40 min

Lithography 1: Active Area
Spin HMDS 4 k rpm for 30 s
Spin 220 4 k rpm for 10 sec
Softbake on hot plate for 90 s at 115C
Expose 5 sec at 25.0 mW/cm2
Post-exposure bake on hot plate for 90 s at 115C
Develop in MIF 300 for 2 mins
Rinse 2 mins in DI, spin dry

Nitride Etch
Descum: O₂, 20 W, 300 mT, 1 min
Reactive Ion Etch: CF₄:20 sccm, O₂: 1 sccm 100 mTorr, 100 W, 34 min

Pad Oxide Etch
Reactive Ion Etch: CHF₃=25 sccm, CF₄=25 sccm, P=183 W, P=40 mT,

Si Recess Etch
Wet etch in NH₄F:H₂O:HNO₃=3; 33:64 by volume, T_{etch}=4 mins
Rinse 2 mins in DI, spin dry

Field Implant
Boron, 5e13/cm², 60 kev

Strip resist
PRS-2000, 15 min, 100° C.
Acetone 3 mins
Propanol 3 mins
Rinse 5 mins in DI, spin dry

Field Oxidation
Standard prefurance clean
Grow 680 nm of silicon dioxide: O₂, T_{dep}=dry 5 mins/wet 70 mins/dry 5 mins, 1100° C.
Anneal 10 min in N₂

Oxynitride strip
Wet etch in BHF for 15 sec
Rinse 5 mins in DI, spin dry

Strip nitride
Wet etch in hot phosphoric acid for 30 mins at 160° C.

Pad Oxide Etch
Wet etch in BHF for 45 sec
Rinse 5 mins in DI, spin dry

Sacrificial gate oxide growth
Standard prefurance clean
Grow 40 nm of silicon dioxide: dry O₂, T_{dep}=22 mins, 1000° C.
Anneal 10 min in N₂

Polysilicon deposition
Deposit 52 nm of LPCVD nitride: 625C, T_{dep}=52 min

Lithography 2: Poly
Spin HMDS 4 k rpm for 30 s
Spin 220 4 k rpm for 10 sec
Softbake on hot plate for 90 s at 115C
Expose 5 sec at 25.0 mW/cm2
Post-exposure bake on hot plate for 90 s at 1115C
Develop in MIF 300 for 2 mins
Rinse 2 mins in DI, spin dry

Polysilicon etch
RIE etch of 52 nm of polysilicon, P=65W, P=5 mT, SF₆=20 sccm, O₂=3 sccm

Strip resist
PRS-2000, 15 min, 100° C.
Acetone 3 mins
Propanol 3 mins
Rinse 5 mins in DI, spin dry

Source/Drain Oxide Etch
Unmasked
Wet etch in buffered HF for 45 sec
Rinse 5 mins in DI, spin dry

Source/Drain Predep
Standard Prefurance clean with HF dip
Phosphorus diffusion: POCl₂: 450 sccm, O₂: 150 sccm, 950° C., 20 mins

Source/Drain Drive-in
Grow 140 nm of silicon dioxide: O₂, T_{dep}==dry 5 mins/wet 15 mins/dry 5 mins, 950° C.
Anneal 10 min in N₂

Strip polysilicon
Wet etch in NH₄F:H₂O:HNO₃=3; 33:64 by volume, T_{etch}=4 mins
Rinse 2 mins in DI, spin dry

Strip sacrificial gat oxide
Wet etch in buffered HF for 45 sec.
Rinse 2 mins in DI, spin dry

Gate oxide growth
Standard prefurance clean
Grow 40 nm of silicon dioxide: dry O₂, T_{dep}=22 mins, 1000° C.
Anneal 10 min in N₂

Nickel Catalyst Deposition
Evaporate 7 nm of nickel onto wafer

Lithography 2: Poly
Spin HMDS 4 k rpm for 30 s
Spin 220 4 k rpm for 10 sec
Softbake on hot plate for 90 s at 115C
Expose 5 sec at 25.0 mW/cm2
Post-exposure bake on hot plate for 90 s at 115C
Develop in MIF 300 for 2 mins
Rinse 2 mins in DI, spin dry

Nickel etch

Gate oxide etch
Wet etch in buffered HF for 45 sec
Rinse 2 mins in DI, spin dry

Passivation nitride Deposition
PECVD deposit 500 nm of silicon nitride at 380C

Lithography 4—Contact Opening
Spin HMDS 4 k rpm for 30 s
Spin 220 4 k rpm for 10 sec
Softbake on hot plate for 90 s at 115C
Expose 5 sec at 25.0 mW/cm2
Post-exposure bake on hot plate for 90 s at 115C
Develop in MIF 300 for 2 mins
Rinse 2 mins in DI, spin dry

Passivation nitride etch
Plasma etch, P=100 W, P=100 mT, CF4=40 sccm, O2=1 sccm

MWNT Grow
PECVD Acetylene: ammonia=54 sccm:200 sccm, P=5 mBar, T=675C.
   III. CNT Islands Pattern; FIG. [3] CNT patterned Islands. This CNT pattern and process is representative of a multisensor chip design.

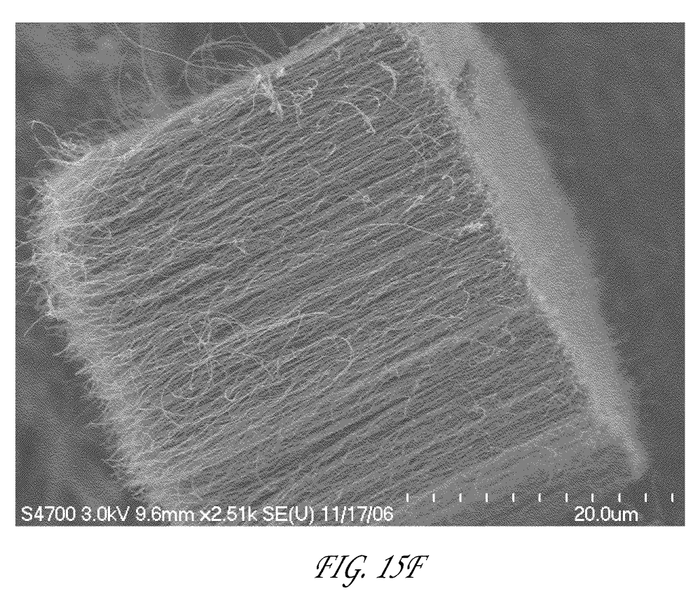

Process Description. A process for forming a doped CNT assembly electrode array having CNT patterned islands is illustrated in FIG. 11. The process starts with a 100 mm silicon wafer substrate (1102) with a 500 nm thermal oxide layer (1104) on top (step 1). The patterning of electrically conductive layer (1106) is performed in a two-step lithography process. In the first step, a liftoff resist is spin coated, and baked. In the second step, a conventional photo-resist is spin coated, exposed, and developed. During resist development, the developer not only removes the exposed photo-resist, it also removes and undercuts the liftoff resist such that when the wafer is immersed in acetone, the subsequent metal stack is lift off leaving a clean metal definition. Then a stack layer of TiW/Mo/TiW: 40 nm/40 nm/40 nm is sputtered, followed by a reactive sputtering of 15 nm TiN to yield the electrically conductive layer (1106). The metal stack is then liftoff by immersing in acetone. After that, a conventional liftoff process is performed where photo-resist is patterned to define the gold contact pad, followed by evaporation of a 50 nm of gold metal (1108), and immersion in acetone liftoff solution. Similarly, the 7 nm nickel catalyst layer (not shown) is patterned by liftoff process using the liftoff resist to produce a sharp nickel metal interface (step 4). Next, a 500 nm layer of PECVD silicon nitride passivation layer (1110) is deposited at 380C (step 5). Contact holes are patterned to expose the metal contact pads (1108) by e-beam lithography and etched in reactive ion etching (step 6). After that, the wafer is ready for MWNT (1116) growth (f) where wafer is exposed to acetylene and ammonia gas at 400C (step 8), followed by further chemical functionalization (g) (step g) to dope the MWNTs (not shown).

Process Flow

Starting Wafer
p-type boron doped 100 mm silicon wafer, single side polished

Thermal oxide Deposition
500 nm thermal oxide at 1000C for 30 mins

Lithography 1—Interconnect
Spin LOR-5a 40H rpm for 10 sec
Softbake on hot plate for 5 mins at 180C
Spin 220 4 k rpm for 10 sec
Softbake on hot plate for 90 s at 115C
Expose 5 sec at 25.0 mW/cm2
Post-exposure bake on hot plate for 90 s at 115C
Develop in MIF 300 for 2 mins
Rinse 2 mins in DI, spin dry

TiW/Mo/TiW/TiN Interconnect Deposition
Sputter 40:40:40 nm of TiW/Mo/TiW onto wafer
Sputter 15 nm of Ti under nitrogen environment
Liftoff in acetone
Rinse 2 mins DI, spin dry

Lithography 2—Contact Pad
Spin HMDS 4 k rpm for 30 s
Spin 220 4 k rpm for 10 sec
Softbake on hot plate for 90 s at 115C
Expose 5 sec at 25.0 mW/cm2
Post-exposure bake on hot plate for 90 s at 115C
Develop in MIF 300 for 2 mins
Rinse 2 mins in DI, spin dry

Gold Metal Pad Deposition
Evaporate 10:100 nm of Cr/Au onto wafer
Liftoff in acetone
Rinse 2 mins DI, spin dry

Lithography 3—Catalyst Deposition
Spin LOR-5a 40H rpm for 10 sec
Softbake on hot plate for 5 mins at 180C
Spin 220 4 k rpm for 10 sec
Softbake on hot plate for 90 s at 115C
Expose 5 sec at 25.0 mW/cm2
Post-exposure bake on hot plate for 90 s at 115C
Develop in MIF 300 for 2 mins
Rinse 2 mins in DI, spin dry

Nickel Catalyst Deposition
Evaporate 7 nm of nickel onto wafer
Liftoff in acetone
Rinse 2 mins DI, spin dry

Passivation nitride Deposition
PECVD deposit 500 nm of silicon nitride at 380C

Lithography 4—Contact Opening
Spin HMDS 2 k rpm for 20 s
Spin 950K-A2 5 k rpm for 45 sec
Softbake on hot plate for 30 mins at 180C
Expose 1000 pAs/cm at 30 kv
Post-exposure bake on hot plate for 2 mins at 100C
Develop in 1:3 MIBK:IPA for 2 mins
Rinse 2 mins in DI, spin dry

Passivation nitride etch
Plasma etch, P=100 W, P=100 mT, CF4=40 sccm, O2=1 sccm

MWNT Grow
PECVD Acetylene: ammonia=54 sccm:200 sccm, P=5 mBar, T=675C.

### III. Integrated Multi-Sensor Pattern:

FIG. [4] depicts a plan view of a four sensor chip lay-out comprising two electrolytic cell Sensor Structures and two CNT-gated MOSFETs. In this four sensor chip design one reference electrode (“Ref El”) services the FETs and the other Ref El and counter electrode is combined with the two CNT Working electrodes.

Fabrication Process (Multi-sensor Chip) The fabrication process comprises a combination of steps as described above for patterning CNT islands and FET structures. FIG. 5 is a schematic illustration of a cladded CNT peapod used in various embodiments of the present invention. CNTs can be chemically doped from within and outside the graphene wall. Suitable polymer claddings may comprise a variety of functional groups, i.e., conductive and insulating polymers, donor/acceptor semi-conducting polymers, redox active polymers, or any combination thereof. The peapod or cladding can also be doped with ionophores for the specific detection of ions in certain embodiments. Referring to FIG. 5, the cladded CNT peapod structure includes both a polymer outer coating as well as an internal reagent. This is a generic approach to chemically doped CNTs that augments the direct chemical and structural modification of the graphene wall itself. Polymers claddings may comprise of a variety of chemical functionality, i.e., conductive polymers, donor/acceptor semi-conducting polymers and redox active polymers. The CNT may be altered in p or n character, may be functionalized with reactive molecules, or any combination thereof.

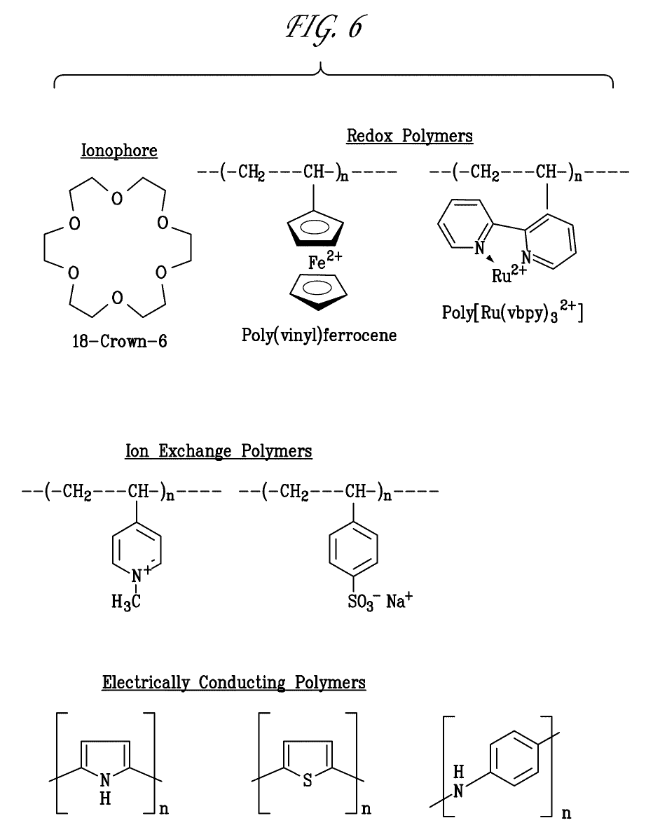

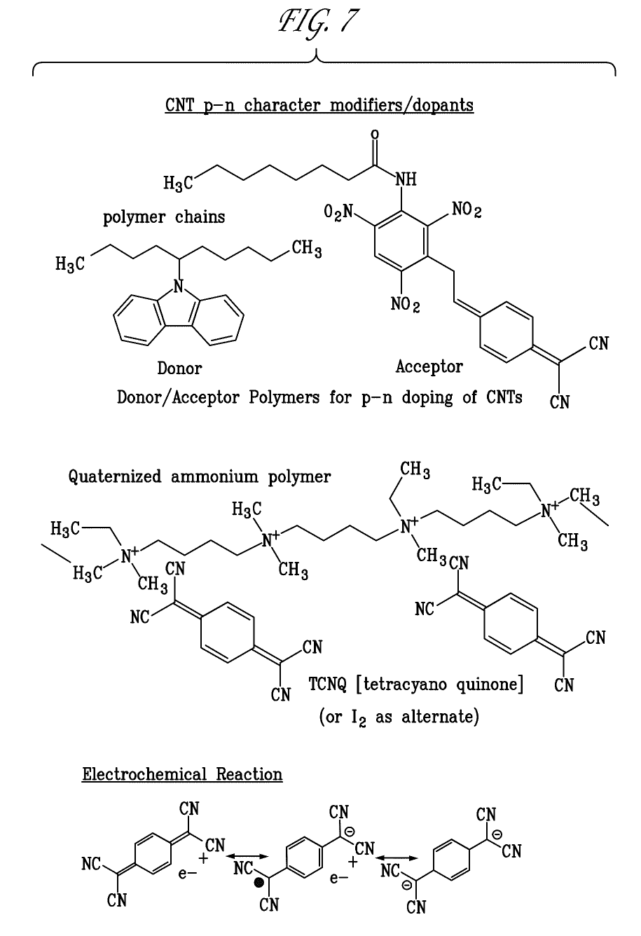

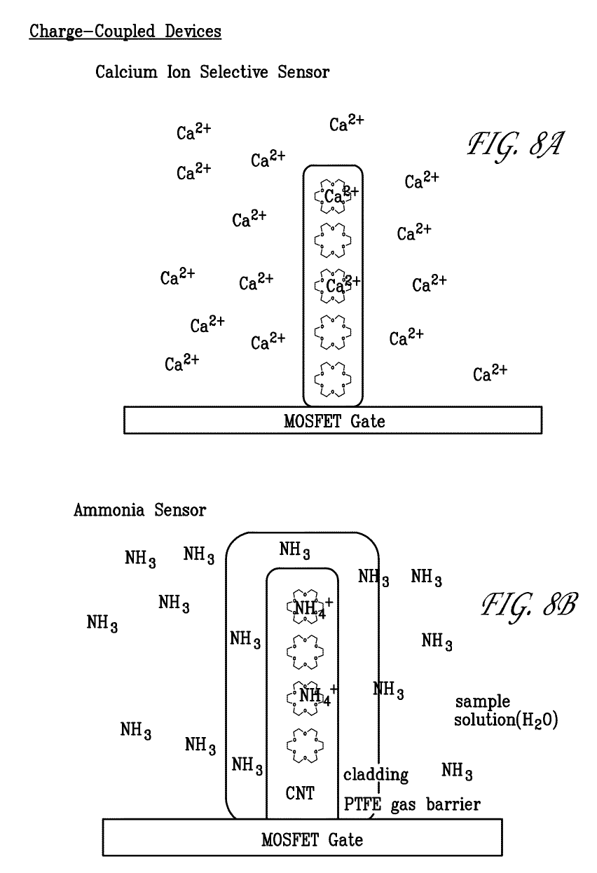

FIG. 6 is a representative set of chemical compounds and polymers that form the CNT claddings and peapods. Suitable dopant materials for cladded-peapod CNTs include ionophore charge carriers, redox polymers, ion exchangers, conductive polymers, and any combination thereof. The 18-Crown-6 polyether dopant is selective ligand for cations. Cryptands, calyxarenes and open chain polyethers are better ionophore performers as are the naturally occurring antibiotics, examples of which include valinomycin, monensin, and nonactin. Examples of conductive polymers are; electronic conduction redox polymers, ionic conduction ion-exchange polymers and electron donor/acceptor co-polymers. CNT electrolysis mediation may occur by direct exchange of electrons between the redox polymer and the solution phase species, or indirectly by modulation of the donor/acceptor conductivity or ion exchange rate, or both.

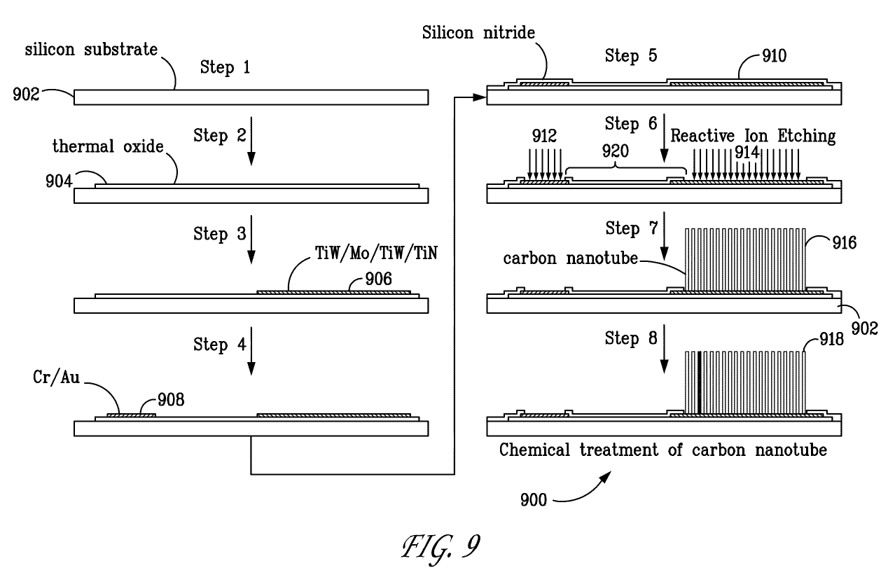

FIG. 7 provides illustrations of representative donor-acceptor polymer chemistries for CNT cladding dopants. These dopants modify the p-n character of CNTs using one or more polymer coatings. Donor-acceptor polymer dopants are particularly useful as p-n character modifiers of CNTs and are preferred over the use of metal impurity dopants. Donor-acceptor polymer dopants are can be readily synthesized free of impurities. Donor-acceptor polymer dopants are readily applied as claddings on the CNTs using RF plasma polymerization that is well known in the art. Tetracyano quinine (“TCNQ”) and iodine are representative electron acceptors for the polymers described.

FIGS. 8A and 8B provide schematic illustrations of a calcium ion selective sensor and an ammonia sensor. These sensors are charge coupled devices based on a FET design using peapod CNTs and cladded peapod CNTs. In FIG. 8B, the cladding can be PTFE which functions as a gas permeable barrier and the ionophore is selective to ammonium ion in the peapod. This is specific for ammonia gas because of the gas barrier and specificity for NH₄⁺. A comparable structure for carbon dioxide gas would employ pH ionophore in the peapod for specific CO₂ gas detection. A variety of other CNT-based sensor elements can be provided according to these design principles.

Suitable cladding includes any material that can function as a gas permeable barrier. Examples of suitable cladding materials include polymers, such as polytetrafluoroethylene (“PTFE”), and sol-gel ceramic materials, polymer/sol-gel hybrid materials, and any combination thereof. In this example, the 16-Crown-6 ether ionophore is selective to ammonium ion in the CNT peapod. This combination of cladding and peapod CNT is specific for ammonia gas because of the PTFE gas barrier and the specificity of the 16-Crown-6 ether ionophore for NH⁴⁺. A comparable structure for detecting carbon dioxide gas could employ a pH-specific ionophore in the peapod to detect pH change in response to CO₂ permeation into the peapod.

MWNTs Structure and Chemistry of Dopants. A MWNT (CNT) sensing device is provided that selectively responds to sample chemical composition at the molecular level. The CNTs can be functionalized and/or chemically doped with selective chemical agents that respond to chemical or electrical signals. In some embodiments the doping modifies the electrical conduction properties of the CNT and in other embodiments, chemical receptor sites can be constructed to elicit specific response. In one example, the CNT is polymer coated and doped with ionophore so that the CNT accumulates ionic charge. The charge is then measured by capacitive coupling to an electronic device such as a transistor.

Certain embodiments exploit the unique electrical, structural and chemical properties of CNTs to create sensing elements that function at the molecular level. Without being bound by any particular theory of operation, doped CNT array sensors may be viewed as nanoantennas that can transmit or receive electrical signals from its environment. As such, the antennas can be modified to react with chemical specificity, and such modification is depicted as the polymer-cladded CNT peapod on FIG. (7). Combinations of peapod structure (Luzzi patent) and cladding structure and CNT surface functionalization can be structured to create chemically specific molecular level responsive antennas.

CNTs can be doped to behave as semiconductors varying in electrical conductivity from “metal-like” to virtual insulators. The graphene can be modified or doped to effect dramatic changes in the electron transfer or propagation by attaching electron withdrawing groups on its surface (DS. Soane, Polymers in Microelectronics, Elsevier (1989)). Donor-acceptor polymer dopants influence CNT transconductance, or redox functionalized polymeric agents can mediate electron transfer across the graphene structure/solution interface. Doping chemistry to effect p/n semi-conducting character of CNTs is shown by FIGS. 9&10.

Ionophore CNT dopants can specifically interact with one or more ions in solution and electronically measured with a CNT gated FET. Redox reactive molecules also can include dopants that mediate current flow in an electrochemical cell device. One embodiment is described below to detect chlorine in drinking water. Other embodiments can detect ions or redox molecules that are coupled to enzymes (suitable enzymes are disclosed in SP Colowik, et. al., “Methods in Enzymology”, Vol. XLVI, K. Mosbach Ed., (1976)), antibodies (suitable antibodies are disclosed in M. Z. Atassi, et. al., “molecular Immunology”, Dekker, NY, (1984)), and DNA functionality (suitable DNA functionality is disclosed in L. Snyder, et. al., Molecular Genetics of Bacteria”, ASM Press, Washington D.C., (1997)) to achieve biochemical specificity and sensitivity for such cladded-CNT peapod “antennas”.

Suitable CNTs can vary in diameter from approximately 1 nanometer to 10 nanometers or more. CNTs may be as short as a fullerene sphere structure or as long as a few micrometers (Ajayan Review article). CNTs can be grown perpendiculary on surfaces (e.g., Si) to create densely packed, aligned NTs (or arrays) or patterned as arrays of aligned CNTs with space apart relationship templated by nanofabrication methods (e.g., E-beam lithography and plasma etching). The array pitch is controlled by E-beam lithography so that the final structure is of fixed CNTs diameter, length, and spacing. Random spacing is achieved by sputtering catalyst and is a useful process when precise pitch is not required by the design.

CNTs can be grown by chemical vapor deposition on templated catalytic surfaces to control CNT chemistry and structure uniformity, particularly for aligned CNT array arrays. Such arrays function and independent nanoelectrodes in electrolytic cells to function as nearly ideal (high current density/efficiency) electrodes that can be unencumbered by solution medium measurement artifacts such as Ohmic loss caused to solution resistance. Without being bound by any particular theory of operation, this property of CNT electrodes allows accurate current measurement in water samples which conductivity can vary dramatically in electrolytes content from drinking water (no salt/high electrical resistance) to sea water (with high salt content/no resistance). This is accomplished without manipulation of sample composition, a useful characteristic of sensors applied to continuous monitoring.

CVD growth process can generate a distribution of CNT's structures relative to graphene chirality and tube lumens. The tubes can exist as single wall nano tubes (“SWNTs”) or multi wall nano tubes (“MWNT's”). SWNTs work best as transconductance channels for FET structures and can be deployed as voltage gated, chemically gated devices, or both. Without being bound by any particular theory of operation, MWNT make better cladded CNT electrodes because the inner graphene wall structure is preserved and less likely to be impeded by the polymer coating. The outer graphene wall can be chemically altered by functionalization and not interfere with the inner graphene electrical properties. Although literature has focused on SWNT channel FET, practical voltage gated poly-1-FET may function best with polymer cladded MWNTs. Peapod sensing structures can be either SWNTs or MWNTs. When both the cladding and the CNT peapods can be doped MWNT's the electrochemical nature of the CNTs display unusual characteristics due to the coupling reactions of reactive species electrochemically generated at either side of the graphene lumen interphase.

CNT Growth Process: Aligned multiwalled MWNTs by thermal chemical vapor deposition. MWNTs (CNT's) may exist as single-walled graphene cylinder structures (SWNT) or Concentric cylinder structured multi-wall MWNTs (MWNT) (Dresselhaus, M. S; Dresselhaus, G. and Eklund, P., Science of Fullerenes and Carbon)-(Ebbsen, T., MWNTs, CRC Press, Boca Raton, Fla., (1997)) (Saito, R.; Dresselhaus, G. and Dresselhaus, M. S., Physical Properties of Carbon). The MWNT growth processes adapted for this invention can be based on Chemical Vapor Deposition (CVD). The primary requirements for CNT growth are; a catalyst consisting of transition metals (i.e., Fe, Ni, Co), Carbon source and high Temperature (500-900 deg.C.).

A. Gas phase thermal CVD method: The CVD reactor is sealed and flushed with Ar (100-300 Sccm) gas for 20-30 minutes. The whole furnace is set at 900° C. Ammonia is introduced in the system at a flow rate ranging from 20-250 Sccm, when the furnace temperature exceeds 600° C. The substrate is treated with ammonia gas inside the furnace for 15-20 minutes to form nanometer size catalytic particles. When the furnace temperature reaches the set value, Acetylene is introduced in the gas feed with a flow range of 20-300 Sccm. The flow ratio of ammonia and acetylene is optimized to get uniform ACNTs array. Acetylene gas is the source of carbon for the growth of the nanotubes. The growth time ranges from 10 to 30 minutes depending on the CNT length required.

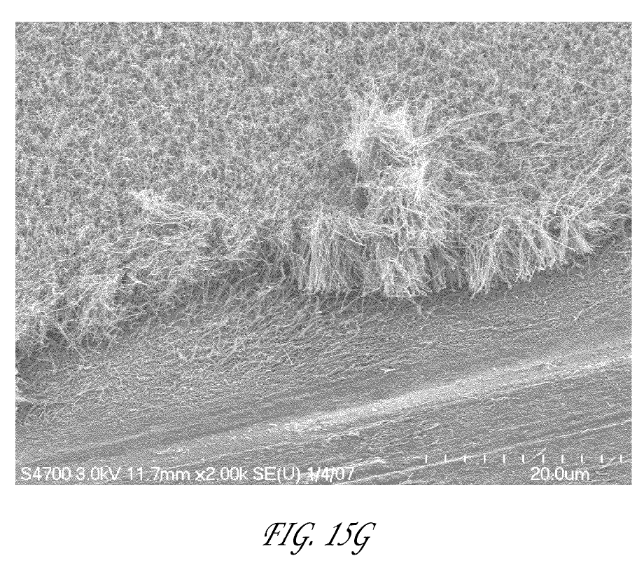

B. Solid precursor thermal method: Iron (II) phthalocyanine is used as both the carbon source and the catalyst for preparing aligned MWNTs (Huang, S.; Dai, L. and Mau, A. W. H., J. Phys. Chem. B. 103, 4223 (1999)). The substrate (Silicon Chip) is cleaned with acetone in an ultrasonic bath, rinsed with acetone again and finally dried in air before placing it in zone 2 (1230) of the flow reactor (1214) (quartz tube) (1214) (refer FIG. 12). Iron (II) pathalocyanine (0.3-0.5 g) is placed in another quartz/ceramic boat and placed in zone 1 of the quartz tube. The whole system is sealed and flushed with argon (Ar) for 20-30 minutes. This step removes any oxygen present in the quartz tube and provides an inert reaction atmosphere. The flow rate of Ar is reduced to 10 Sccm and H₂ is introduced in the gas flow at 20 Sccm. The gas flow is maintained steady through out the reaction. The temperature of zone 2 is set at 550° C. Zone 1 temperature is set at 500° C. As zone 1 attains the set temperature, the pyrolysis of the organometallic precursor is triggered inside the furnace. Iron is released into the gas phase and gets spread inside the furnace and onto the substrate via the Ar/H₂ gas flow. The pyrolysis step is maintained for 5 minutes. Following the pyrolysis step the zone 2 temperature is set to 900° C. and zone 1 is set to 800° C. As the temperature of zone 1 ramps up the organometallic precursor remaining in the boat starts decomposing, releasing carbon in the gas phase. The carrier gas transports the carbon in the gas phase to the high temperature zone 2 where the growth of MWNTs on the quartz plate is initiated by the metal catalyst. The furnace is maintained for 10 minutes when zone 1 and zone 2 reach their set temperatures. After the reaction time, the furnace is shut-off, the H₂ flow is turned off, and only Ar gas flow is maintained steady at a low flow rate. The black layer that forms on the Si substrate is analyzed ant micron resolution by SEM and subsequently at sub-micron resolution by transmission electron microscopy (“TEM”).

C. Plasma Enhanced CVD (PECVD), patterned growth Method: The MWNTs can be grown in a bell jar vacuum chamber at a base pressure of ˜10⁻² Torr. Si/SiO₂ and Si/TiN substrates with Ni metallization patterns can be used for PECVD patterned CNT growth. The metal catalyst film thickness ranges from 50-150 nm. The substrate is place in the chamber and pumped down to ˜10⁻² Torr pressure, at a temperature setting of 700° C. Ammonia etch gas (50-200 Sccm) is first introduced into the chamber for 5-10 minutes and subsequently followed by CNT growth acetylene gas at a nominal gas flow ratio (1:2-5) of acetylene to ammonia. The glow discharge plasma generator is set at 0.5-1 kV dc and depositions can be carried out at a bias current of ˜0.1 A. The growth reaction time can vary from 5-20 min depending on the required length of MWNTs and growth is observed only where the metal catalyst particle resides.

CNT Cladding Methods: Polymer CNT Claddings by Electrolytic Method: Conductive polymer films can be deposited electrolytically by monomer reduction at an electrode surface. Monomer reduction generates free radical that initiates and propagates the polymer synthesis (i.e., polymerization). Polymerization terminates when current ceases and the surface is passivated to electrolysis. Electrolytic polymerization is accomplished with suitable monomers including aniline, pyrrole, thiophene, phenol, or any combination thereof.

(i) Polypyrrole cladding method by constant voltage electrolysis: A potential of 1.0 V (VS. Ag/AgCl) is applied for 90 s in an aqueous solution of 0.1 M pyrrole and 0.1 M sodium per chlorate. Polypyrrole deposition is achieved on an aligned MWNT electrode. The electrolysis current exponentially decays during the polymer film formation and is a clear indicator for complete polymer coverage of the CNTs. Cladding formation is verified by SEM pre and post-electrolysis

(ii) Polyaniline cladding method by voltage scan electrolysis: The cyclic voltametric technique is effective for the preparation of aligned MWNT/polyaniline films. An aqueous electrolytic solution of 0.05 M aniline with 0.1 M of sulfuric acid is used to electrochemically deposit polyaniline over individual aligned MWNT surface. Controlling the scan rate and the number of cycles, a uniform and smooth coat of polymer can be obtained on the surface of the individual aligned nanotubes. Cyclic scanning of voltage allows for more controlled depletion of monomer during the electrolytic polymerization resulting in more uniform films.

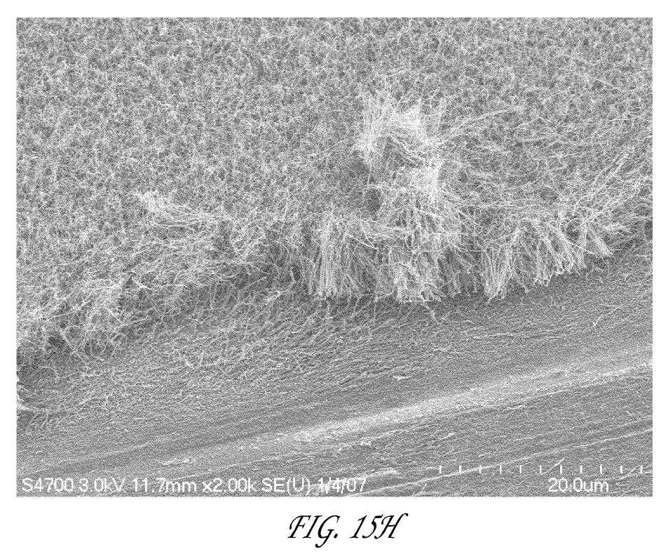

B. Cladding of ACNT surface by plasma polymerization technique: RF Plasma polymerization of dielectric monomers such as aliphatic hydrocarbons, substituted hydrocarbons, etc. is an attractive surface polymerizartion method of typically unreactive molecules to create dielectric films. A bell-jar type reactor can utilized with radio frequency glow discharge to initiate and propagate polymerization. The added advantage is that these films includes created at low pressure in the gas phase under in clean-controlled environments (Iriyama, Y.; Yasuda, T.; Cho, D. I. and Yasuda, H., J. Appl. Polym. Sci. 39, 249 (1990)) (Terlingen, J. G. A.; Gerritsen, H. F. C.; Hoffman, A. S, and Feijen, J. J. Appl Polym. Sci. 57, 969 (1995)) (Terlingen, J. G. A.; Gerritsen, H. F. C.; Hoffman, A. S, and Feijen, J. J. Appl Polym. Sci. 57, 969 (1995)). The process is quite generic for deposition of polymers 16 (For a general reference on plasma polymerization, see: (a) Yasuda, H. Plasma Polymerization; Academic Press: Orlando, (1995). (b) van Os, M. T.; Menges, B.; Fo rch, R.; Knoll, W.; Timmons, R. B. and Vancso, G. J., Mater. Res. Soc. Symp. Proc., 544, 45 (1999) (c) Hsieh, M. C.; Farris, R. J.; McCarthy, T. J. Macromolecules, 30, 8453 (1997) (d) Chatelier, R. C.; Drummond, C. J.; Chan, D. Y. C.; Vasic, Z. R.; Gengenbach, T. R.; Griesser, Langmuir, T. J., 11, 4122 (1995)), for immobilization of surfactant molecules 17 (Terlingen, J. G. A.; Feijen, J.; Hoffman, A. S. J., Colloid Interface Sci. 155, 55 (1993)), or etching of the specimen surface 18 (Manos, D. M. and Flamm, D. L., Plasma Etching, An Introduction, Academic Press: Boston, (1989)). The system depicted in FIG. 13 can be utilized for radio frequency sputtering and plasma polymerization.

FIG. 13 illustrates a radio frequency deposition system (1300) having a substrate (1302), sheath (1304), target (1306), excitation electrode (1308), insulation of excitation electrode (1310), discharge glow (1312), passage to pumps (1314), inlet for monomer gas or argon gas (M, Ar)(1316), shutter (1318) and power supply (1320) indicated by radio frequency.

Procedure to coat ACNT surface uniformly with hexane plasma layer is explained. A plasma reactor powered by a commercial high voltage radio-frequency generator operating between 100-500 KHz (AG0201HV-ACD) can be used to carry out the surface modifications of aligned MWNTs. The plasma chamber is connected with a plasma generator and a vacuum line. A film of aligned MWNTs is placed inside the plasma chamber on the electrode. A small quantity of a liquid monomer (hexane) is introduced in the monomer bottle. High vacuum (˜0.1 Torr) is created in the chamber, before the admission of the monomer particles in the glass chamber. Once the desired monomer pressure (˜0.15-0.7 Torr) is attained, a radio frequency generator is turned on (Power-30 W, Freq-250 KHz) for the desired discharge period (30-120 s) during which time the aligned MWNT surface is modified with plasma.

CNTs Doping Chemistry. The doping of CNTs is accomplished in several ways; by direct chemical bonding of functional groups on the RF plasma oxidized graphene carbon, by filling the CNT lumen to create peapods and, by forming a polymer film (cladding) on the graphene surface. Any or all combinations of these doping procedures can be useful in creating chemically selective sensing devices.

CNT peapods can be filled with ionophores from the class of such ligands as; cyclic poly-ethers (cryptands, calyxarenes), natural antibiotics (Valinomycin, Monensin, Nonactin) and other linear ion coordination ligands known in the art (Reference Jonophore literature). Such ligands selectively bind the ion into the CNT phase and the charge accumulation is determined by complex formation constant equilibrium, solubility factors and ion (CNT/solution) partitioning factors. Because the CNT is completely neutral to all ions in a sample, only the primary ion exchange will result in a charge gradient formation within the CNT. Conventional ISE membranes respond predominantly to the ionophore-bound ion, but can be susceptible to ion exchange with the polymer sites. Secondary ion interaction of the dielectric membrane contributes to background signal and thus, limits the detection sensitivity. Theoretically, this new ion selection mechanism can lower the detection limit from ˜10[−8] Molar (state-of-the-art) to ˜10[−12] Molar. Although this level of selectivity and sensitivity is not required for water analysis, it may be important to medical/pharmaceutical applications. Such CNT constructs can be much more durable than conventional membrane sensors that are susceptible to hydrolytic break down in water. Furthermore, the ionophores can be trapped within the CNT and will not leach as do conventional polymeric membranes.

Several electron mediators can effectively bridge the band gap and mediate electron transfer with solution or within the CNT/polymer phase: Ru(bpy)₃2+, Fe(bpy)₃2+, Ru(NH₃)₆3+, Tetracyanoquinodimethane (TCNQ), Quinone, Benzophenone, Ferrocene, Tetramethyll-p-phenylenediamine(TMPD), Tetrathiafulvalene, Tri-N-p-tolylamine(TPTA). Such polymers, whether electron donors or acceptor or ion exchangers/ion carriers or redox centers, all can be coated onto the CNT by electrolytic polymerization or RF plasma. These films can be easily applied as coatings on the outer CNT surface.

The CNT carbon structure is chemically altered by oxidative RF Plasma to activate the carbon surface and create oxide, hydroxide, carboxyls and phthalic anhydride which will subsequently chemically bond with appropriate functional groups, i.e., COOH, CONH2, COOCH3, OSiORx, etc. to provide chemical reactive functionality for Schiff base, carbodiimide, amide, etc. linkage to peptides (antibody, enzymes, DNA).

### CNT Doping Method by Supercritical CO₂

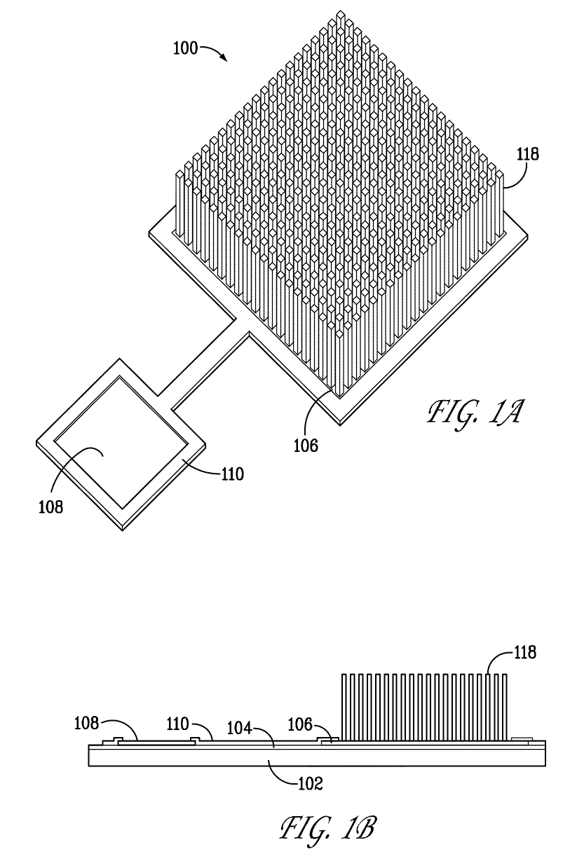

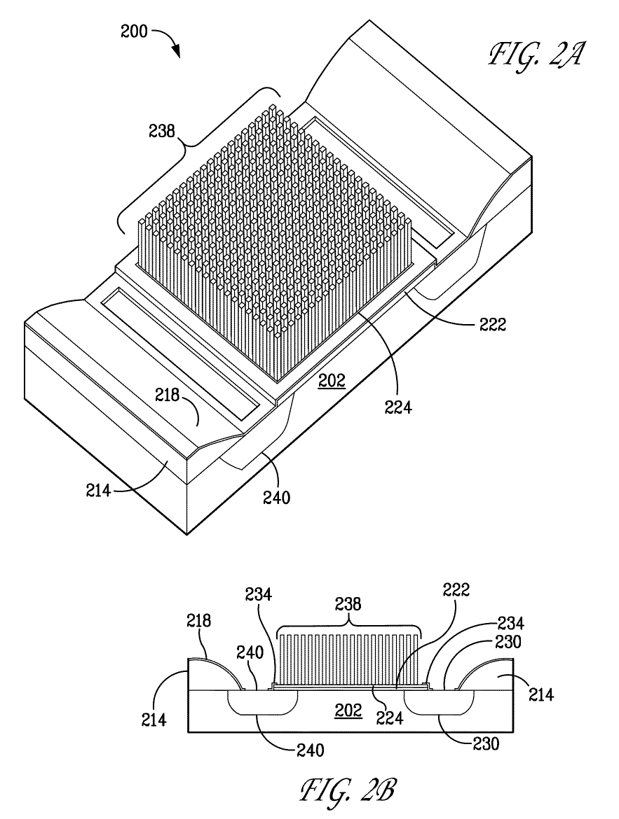

I. Super Critical CO₂ Assisted MWNT Doping (Peapod formation).
Goal. To drive target molecule (e.g. Ru(bpy)₃²⁺, C₆₀) into the cavity of MWNTs.
Materials: Silicon chip with CNT array pattern [FIG. 1], Fullerene (C₆₀), Ru(bpy)₃²⁺.
Solvents: 1,2-Dichlorobenzene, Chloroform, Tetrahydrofuran, Carbon disulfide, Ethanol, Toluene, De-ionized Water.
Experimental Procedure: Aligned CNT arrays filled with Ru(bpy).
(i) CNT-chip preparation: (Air oxidation—Optional): Heat the SWNTs under oxygen in a muffle furnace at 600° C. for ˜5 minutes. Weigh the CNT chip after heating, the mass of nanotubes should reduce to 30-50% of its original mass (˜6-10 mg).
(ii) Prepare a solution of Ru(bpy) in de-ionized water (e.g. 5 ml of 1 mM solution).
(iii) Place a drop of the solution mixture the chip and dry in air.
(iv) Introduce this wafer into the supercritical chamber. Fill the chamber with liquid CO₂.
(v) Attain super criticality and maintain a pressure of 100-150 bar @ 50-60° C. temperature for 3-4 hrs.
(vi) Collect the sample on the wafer; wash it with copious amount of de-ionized water to remove any molecules absorbed on the sidewalls of the nanotubes.
(vii) Characterize the sample by SEM/TEM.
   II. Super Critical CO₂ Assisted Impregnation of Ionophores onto CNT Surface.
   Goal. To drive target molecule (e.g. 18-Crown-6, Potassium-ionophore) into the cavity of MWNTs.

### Materials: Cladded MWNTs, Fullerene (C₆₀), Ionophores,

Trial Solvents Chloroform, Tetrahydrofuran, Ethanol, Toluene, De-ionized Water.

### Experimental Procedure:

(i) Prepare a film of aligned CNTs on a chip. Perform conformal cladding on the surface of the aligned CNTs.
(ii) Prepare a solution of 18-Crown-6 in Chloroform (e.g. 5 ml of 1M) in a vial.
(iii) Introduce the cladded—aligned CNT sample into the vial solution.
(iv) Place this vial in a super critical CO₂ chamber. Seal the chamber.
(v) Fill the chamber with liquid CO₂.
(vi) Super critical conditions are achieved and thereafter the pressure is maintained at 100-150 bar @ 50-60° C. for around 3-4 hrs.
(vii) The chamber is brought back to Room Temp and Pressure in a controlled manner, so that the dried contents remain in the sample vial.
(viii) Collect the cladded aligned CNT sample and characterize it by SEM/TEM.

### Example #1

CHLORINE DETECTION. Free Chlorine [HClO] and Total Chlorine [HClO & RHNCl & Cl-RH] may be detected with the Device in FIG. (1) when the CNTs are configured as a Working Electrode in an electrolytic cell configuration. By the application of the appropriate votage bias of 1.1V vs. Ag/AgCl (Ref.) free Chlorine (or HClO) will directly reduce in water according to the following reactions:

A. Free Chlorine Measurement with No Dopant Requirement:
Cl2(g)+H2O═HClO+HCl [pK(a1)=3.5]
HClO═H⁺ClO−[pK(a2)=7.5]
HClO+2e−+H2O═HCl+H2O2

The CNT islands in FIG. (3) are defined Working electrodes patterned from the Ni catalyst surface film. E-beam lithography can define the Ni film patterns with a resolution of 20-100 nm. Within this pad dimension, several CNTs will grow to form the working electrode. The ensemble of these 100 nm CNT islands make up the total working electrode surface. As depicted by the above electrochemical reaction, HClO will reduce to HCl and other chlorinated hydrocarbons and amines will similarly reduce at various volages (energies). Scanning bias voltages will induce electrolysis of electro-active sample species such that independent responses can be evoked at various voltages. The additional application of periodic perturbations (i.e., sinusoidal, pulse, etc.,) enhance the sensitivity and resolution of such electrolytic responses. Digital domain processing allows for deconvolution of response artifacts and noise filtering. Such signal processing techniques improve sensitivity and specificity by isolating signal from background and by resolving complementary signals in the time (kinetic) and voltage (energy) scale.

### B. Total Cholorine by Iodide/Iodine Dopant Mediator:

½Cl₂+I−=Cl−+½ I₂
RHNCl+I−=Cl−+RNH₂+Cl−+½I₂ Etc.

As the above reactions indicate, Iodine is a chemical reducing agent for chlorine and the I2/I−is also electroactive so that it not mediates electron transfer through the CNT but can also be reversibly regenerated after chlorine oxidation. All chlorinated organic species such as chloramines (disinfection byproducts) and oxichlorides can be reduced by iodide, hence, iodine content is a measure of total chlorine.

To effect total chlorine reduction, the CNTs can be doped with Iodine:

Method 1: The CNT sensor pad of FIG. (1) comprising of aligned CNTs (arrays) is oxidized in a furnace at 400 deg C. to create defects in the CNT. The CNTs are subsequently treated with supercritical fluid composition containing Iodine to effect phase transfer of iodine into CNT.

Method 2: The vertically aligned CNTs (array) is coated with polyanaline conductive polymer by electrolytic deposition from aniline monomer and subsequently impregnated with iodine by the scCO2.

Method 3: The vertically aligned CNTs (array) is coated with aliphatic hydrocarbon dielectric polymer deposited by RF plasma free radical polymerization of n-hexane. The dielectric polymer is subsequently impregnated with iodine by the scCO2 method above.

The total DC current measured corresponds to the rate of iodine reduction and reflecting the sum total of all chlorinated species that oxidize iodide ion to iodine. Both CNT peapods and cladded CNTs behave similarly in this mechanism as mediators, however, the peapod is a faster reaction since the electrons can be exchanged directly (tunneling) with the graphene CNT structure. In the case of the polyanaline cladded CNTs, the polymer phase conduction is likely to occur via a donor acceptor “electron hopping” mechanism.

C. Luminescence Detection mechanism for Tot Chlorine: CNT peopods are generated by the scCO2 method using the redox mediator Ru(II)(bpy)₂ as photo-emitter. The CNT peapods are cladded by dielectric hydrocarbon polymer (poly-n-hexane) by the by RF-plasma free radical polymerization method. The cladding is then pregnated with Ru(II)(bpy)2 by the scCO2 method. Samples containing chlorinated organics will react with Ru(II)(bpy)₂ to yield the oxidized state Ru(III) state within the cladding while peapod Ru(II)(bpy)₂ is reduced electrolytically to Ru(I). This dynamic generation of Ru (J) and Ru(III) will luminesce at 610 nm and modulated by the sample chlorine. The emission is detected by photo-diode.

### Example #2

CALCIUM ION DETECTION: Charge Coupled Devices:

The passive device of FIG. (1) may be applied as an ion selective ion sensor by doping the CNT array with ionophore or ion exchange ligands. Such a sensor responds to the test sample ion content according to the equation:

E=E^{o}+S ln [aᵢ+KijΣaij−E_{ref}]

where; E^{o} is the standard potential (ln aᵢ intercept)

(S ln aᵢ−E_{ref}) is the chemical potential term for the ion i.

Kij Σaij is the interference error term for ion j.

The assumptions are; E is referenced to Eref, slope is 50 mV for n=1, ionic strength is constant or activity coefficients χ=1, and Kij=>0. Hence, the CNT E response is a Log function of the target ion concentration (or ai).

The doping of the CNT with ionophore may assume the “peapod” structure with ionophore occupying the CNT interior void space. Alternatively, doping may be achieved by dielectric polymers coating (cladding) the CNT and impregnating the polymer with ionophore (See FIG. [10]). Examples of calcium specific ionophore and other ionophores significant to water analysis are given below:

### ETH 1062—Calcium Ionophore

N,N,N′,N′-Tetrabutyl-3,6-dioxaoctanedi(thioamide)

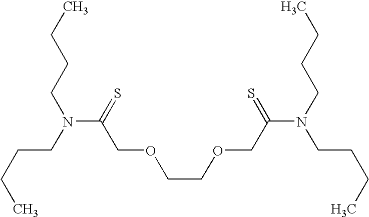

### ETH 129—Calcium Ionophore

N,N,N′,N′-Tetra[cyclohexyl]diglycolic acid diamide
N,N,N′,N′-Tetracyclohexyl-3-oxapentanediamide

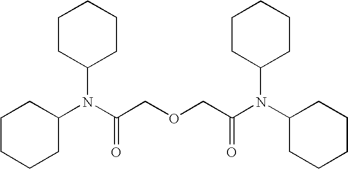

### ETH 6010—Carbonate Ionophore

Heptyl 4-trifluoroacetylbenzoate

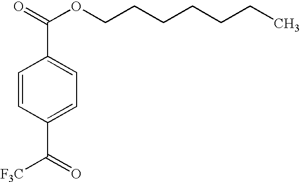

Proton ionophore I− pH

### Tridodecylamine—Molecular Formula [CH₃(CH₂)₁₁]₃N

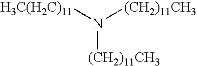

### Potassium Ionophore

### Valinomycin—Molecular FormulaC₅₄H₉₀N₆O₁₈

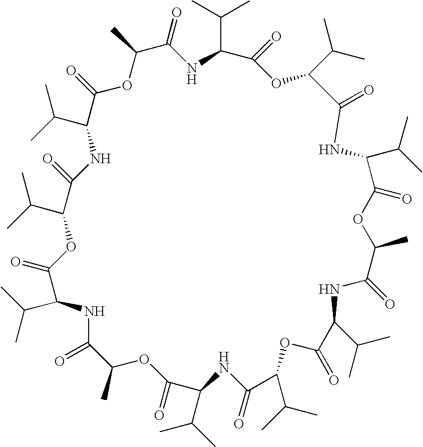

### Sodium Ionophore

Bis[(benzo-15-crown-5)-4′-ylmethyl] pimelate

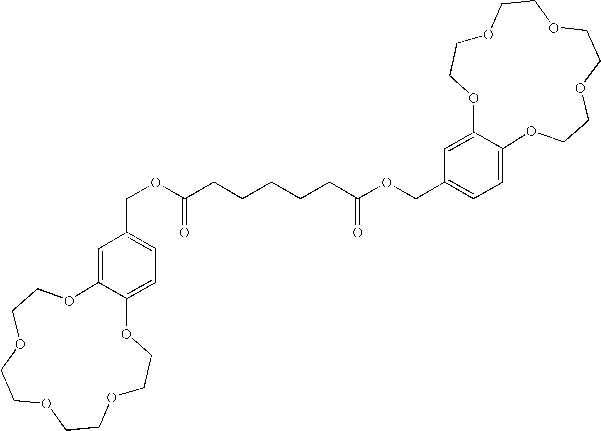

C₃₇H₅₂O₁₄ Molecular Formula

2, 3:11,12-Didecalino-16-crown-5
2,6,13,16,19-Pentaoxapentacyclo[18.4.4.4^{7,12}.0^{1,20}.0^{7,12}]dotriacontane

C₂₇H₄₆O₅ Molecular Formula

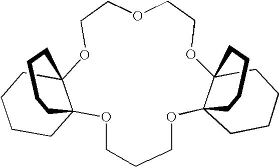

The FIG. [2] schematic is that of a doped CNT assembly (200). Here, a MOSFET Charge Coupled device can be constructed by standard IC manufacturing methods.

The gate oxide (222) is coated with a (non-templated) array of aligned CNTs (238). The gate oxide (222) is electrically insulated from the p-doped channel (202) so that the resulting high input impedance ensures that charge coupling will modulate the gate electric field and consequently, the electron conduction between source (240) and drain (230). The CNT functions as an antenna to accumulate charge from solution contact to generate an electric field (not shown) that in turn modulates the p-channel MOSFET drain current according the simplified general formula: (J. Janata, et. al., in “Ion Selective Electrodes in Analytical Chemistry”, V 2, H Freiser Ed., Plenum Press, 1980)

I_{D}/kR_{Ω}=(V_{G}−V_{T}+S ln aᵢ−E_{ref})

where;
k is a constant re. CNT dimensions and e-mobility
ID is the drain current
R_{Ω} resistance of the CNT channel
V_{G}−V_{T} represent gate and threshold voltages
(S ln aᵢ−E_{ref}) is the chemical potential term for the ion i.

This structure will respond only to chemical interactions on the CNT surface when doped with ion specific ionophore (i.e., 18-crown-6 cyclic polyether). The ionophore selectively binds ion (i.e., K+) specifically from solution to charge the CNT, which in turn modulates the p-channel semiconductor space charge. The chemical modulation may be measured as a gate voltage at constant drain current or modulated drain current at fixed gate bias voltage.

All CNTs (antenna filed) can respond to the same chemical entity (i.e., ion) for proper CNT-gated FET function. The signal-to-noise characteristics of such a CNT-gate FET is significantly superior to the comparative passive sensor (CNT-array), but all thermodynamic and kinetic response characteristics remain the same. The nanoantenna CNT chemical sensor is sensitive and specific (relative to the macro-membrane equivalent) because the signal focuses on the ion exchange interaction only and all artifacts regarding CNT chemical interactions liquid junction ion fluxes, etc., are non-existant.

Charged coupled mechanism of detection is based on the selective generation of an electric field on a CNT as a consequence of ion (charge) capture as described by the equations above, the solution chemical potential affects the gate voltage that modulates the source to drain current of a nominally operating FET device.

This MOSFET sensing device shown is a p-n-p FET operating in the inversion mode (large reverse voltage bias). The CNTs function as antennas and as a metal coating on the metal oxide insulator (MOI gate). The FET may or may not be operated in the Field Effect mode but as a conventional transistor with forward or reverse gate bias. In the reverse bias mode the CNT may operate as an ion-gated switch, in the forward gate bias mode as ion modulated drain current.

Several highly selective cationic ionophores for Calcium, Potassium, and Sodium ions and H+ and CO3=anion exchangers are shown above. Such ionophores target the Potable Water Panel of Table 1. The ion exchange polymers shown of FIG. 8 and the donor/acceptor polymers of FIG. 9 offer fixed site polymer structural cladding alternatives for stable selective chemistry. Ion exchangers such as polysulfonates (cationic) and quaternized polyalkylammonium (anionic) are effective fixed site charge conductivity mediators for cladded CNTs. The p/n modifiers (electron donor/acceptor polymers) are effective mobile electron/hole mediators for chemically modulating CNT transconductance.

Redox reactions can also apply to modulate Gate bias. Iodine cladded CNT (I2/I− couple) will oxidize chlorine to form Iodide ion. Hence donor/acceptor polymers based on Iodine as an electron acceptor dopant will mediate both conductivity and charge and is adaptable to either FET structure discussed above. Reduction-oxidation reactions in general; TCNQ/TCNQ= and Ru++/Ru+, etc. will modulate gate bias by charge ratio and/or conductivity and hence may be coupled to target molecules of interest for application on FET devices.

### Example #3

AMMONIA & CARBON DIOXIDE DETECTION/The sensor of FIG. (10) is based on the cladded peapod structure of FIG. (7). It couples the ammonium ion specific CNT peapod with a gas barrier polymer cladding. PTFE cladding is an effective NH₃ gas separator from dissolved NH4+OH− (ammonia) in solution. Nonactin is a selective ionophore for NH4+ that is immobilized within the peapod. NH₃ permeates through the cladding and NH4+ is captured and bound by the nonactin to generate CNT charge.

Similarly, CO2 can permeate gas barrier (cladding) to bind with Heptyl 4-trifluoroacetylbenzoate as carbonate anion. Alternatively, CO2 can be detected as a pH change with Tridodecylamine. Both mechanisms separate the gas from solution and generate ionic charge on the CNT. The measurement is accomplished by electrometric EMF measurement of a passive CNT array sensor or by active CNT-gated FET device. In either case the chemical potential of the NH4+ or CO3= is in equilibrium with the EMF of the CNT.

### Example #4

SARIN TOXIN DETECTION. (By Acetylcholinesterase (choline hydrolysis) inhibition reaction): Sarin (O-isopropyl methylphosphonofluoridate) inhibits the chlorinesterase catalyzed hydrolysis of acetylcholine to choline (quaternized ammonium salt). The quaternary ammonium ion is detected by cationic exchanger shown in FIG. (8) as modulated CNT conductivity. The CNT can be either peapod or ionic polymer cladded CNT. Cyclic poly-ethers can be selective to quaternary ammonium cations, albeit less selective than smaller ion sizes.

### Example #5

SARIN TOXIN DETECTION (By ImmunoAssay): Anti-Sarin capture antibody is Sandwiched with Anti-Sarin Urease conjugate. Step I is top capture Sarin on Nonactin CNT peapods with Anti-Sarin antibody. Step II is to sandwich Anti-Sarin-Sarin- and Urease Anti-Sarin Conjugate. Detect ammonium ion generated by Urease conjugate label captured at CNT peapod surface.

In this detection scheme the combined specificity of enzyme catalysis to the specific detection of the ion generated (ammonium in this case) yields exceptional sensitivity and detection specificity. And this sensor design approach is entirely generic with respect to sandwich immunoassay mechanism. The detection scheme is the same, i.e., match the enzyme label (antibody conjugate) to the product of the enzyme reaction for chemical amplification and the capture antiboby for specificity. The generation of label ion is confined to the cladding surface of the CNT (or peapod) concentrating ion product at the detection surface and the sensitivity multiplies many fold. This scheme is repeated with redox active label antibody conjugates as is the case for horse radish peroxidase (HRP) that generates peroxide on the FET gate surface. Peroxide reacts with I2/I− or Ru2+/Ru+ dopants to alter charge and/or conductivity

### Example #6

Microbial Identification (E-Coli) Oligonucleotide sequences that are complementary to target E-Coli DNA sequences will hybridizate to form dsDNA. When such hybridizations are confined to the CNT surface, the hybridization event may be detected by intercalation of transition metal ions. In the case of dsDNA hybridization on the CNT-gated FET intercalated ions, e.g., Ag+, Ru++, etc. would be detected by CNT gate voltage bias that is modulated by intercalated ion or by redox electrochemistry of the intercalated metal ions

To overcome the problem of mutant mismatch (false negatives or false positives) the Ramdomly Amplified Polymorphic DNA approach would be used with a high debsity CNT sensor array to detect polymorphism populations of DNA amplicons with subsequent pattern analysis.

TABLE I
A potable water panel comprising ac chemistry
profile that is a measure of water quality

| Water | | | Range-(Molar | |
|---|---|---|---|---|
| Parameters | Test | Selective Chemistry | Units) | |
| Potassium | K⁺ | Valinomycin- ISFET | 10⁻⁵-10⁻¹ | |
| Sodium | Na⁺ | Calyxarene- ISFET | 10⁻⁴-10⁻¹ | |
| Hydronium | pH | Tri-n-dodecylamine- ISFET | 5-9 | |
| Calcium | Ca⁺⁺ | ETH 1001- ISFET | 10⁻⁵-10⁻² | |
| Chloride | Cl⁻ | Quaternary Ammonium | 10⁻⁴-10⁻¹ | |
| | | Polymer - ISFET | | |
| Alkalinity | HCO3⁻ | PTFE cladding/pH-FET | 3 × 10⁻³-10⁻¹ | |
| Oxygen | pO₂ | PTFE cladding/Peapod | 0-300 | mmHg |
| | | Electrode | | |
| Ammonia | pNH₃ | PTFE cladding/NH4+-FET | 10⁻⁵-10⁻¹ | |
| Chlorine | Cl₂ | HOCl reduction- Peapod | 1-10 | ppm |
| | | Electrode | | |
| Oxidation - | ORP | CNT Potential | 0-1000 | mV |
| Reduction | | | | |
| Temperature | | RTD, Diode | 5-50° | C. |
| Conductivity | | Ti/Pt | 0-2000 | μS/cm |

TABLE II
DRINKING WATER MONITORING APPLICATION
CNT-array Dopants Chemistry

| Sensor Category | Target Analytes | Dopants/Chemistry |
|---|---|---|
| Ion Detection (H+) | Ca++, pH | Peapod or cladding/(Ca) Ionophore/tri-alkylamine |
| Gas Detection | Ammonia; | Cladded(dielectric)/Peapods (Nonactin-NH4+) |
| | Carbon Dioxide | Cladded (dielectric)/tri-alkylamine (H+) |
| | Oxygen | Cladded Peapod |
| Redox Detection | Free Chlorine; | CNT - electrode |
| | Tot Chlorine | Redox Mediator (I2), Peapod or cladding |
| | | (polyanyline) ECL of Ru(bpy)₃²⁺ |
| | Chloramines/ClO2 | CNT-electrode |
| | | Peapod or cladding doped w. Iodine or TCNQ |
| Toxins by Enzyme | Toxins | Acetyl Choline Esterase Inhibition |
| Inhibition | Sarin/Risin etc. | Immuno-assay by Cladded-Peapod |
| By Immuno-sensor | | Donor-Acceptor (Cladding or Peapod) |
| | | Ion Detection (Cladding or Peapod) |
| | | Redox Mediation (Cladding or Peapod) |
| | | ECL/Peapod-Cladding Combo |
| | Chloro- | Cladded Peapods |
| | Alkylamines | Ions/donor-acceptor/redox/ECL |
| Microbes by DNA | | Cladded Peapods |
| Hybridization | | Ions/donor-acceptor/redox/ECL |

TABLE III
CNT SENSORS

| | Fab Process | | |
|---|---|---|---|
| NT Structure | Chemistry | Analytical Method | Target Analytes |
| CNT arrays-undoped | CVD growth | Votage programs; a.c. | HCIO, O2 |
| CNT arrays | CVD growth | voltammetry | R—NH—Cl, Clo2 |
| CNT Islands | CNT gate-MOSFET | Votage pulse | HCO—Cl, Cl—CH2-CO |
| CNT-gate | ECL | transients | |
| | | Fourier Analysis of | |
| | | transients | |
| | | I-V measurements | |
| Cladded CNT's | Ionophores | Potentiometry | NH3, CO2 (gasses) |
| Dielectric | Redox | Capacitance | Ca++, pH |
| Cladding | Donor-Acceptor | NT Conductivity | HClO, O2 |
| Ionophore | | Selective I-V | R—NH—Cl, ClO2 |
| Functionalized | | | HCO—Cl, Cl—CH2-CO |
| Conductive | | | |
| polymer cladding | | | |
| Redox | | | |
| Functionalized | | | |
| Peapod CNTs | Polymer grafts | Potentiometry | Enzyme assays |
| Dielectric | Ionophores | Capacitance | Biotoxins |
| Cladding | Redox | NT Conductivity | Immuno-assays |
| Ionophore | Donor-Acceptor | Selective I-V | Biotoxins |
| Functionalized | | Electro- | Microbes |
| Conductive | | chemiluminescence | NH3, CO2 |
| polymer cladding | | Fluorescence | Ca++, pH |
| Redox | | Nanotitrations | |
| Functionalized Fluors | | | |
| Functionalization | Ionophores | Potentiometry | Enzyme assays |
| (NT's, peapods, | Redox | Capacitance | Biotoxins |
| claddings, | Donor-Acceptor | NY Conductivity | Immuno-assays |
| combinations) | Proteins | Selective I-V | Biotoxins |
| of peapods | Enymes | Electro- | Microbes |
| of claddings | Antibodies | chemiluminescence | NH3, CO2 |
| of NTs | DNA | Fluorescence | Ca++, pH |
| | | | Carcinogens |

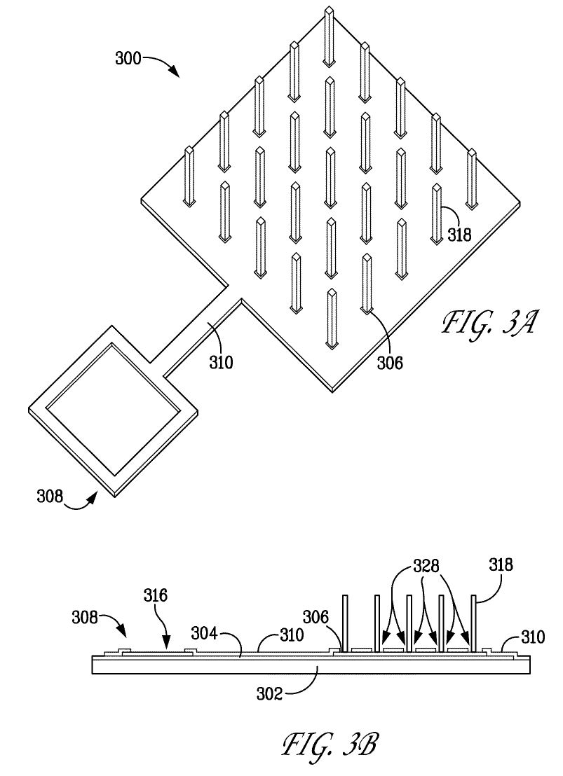

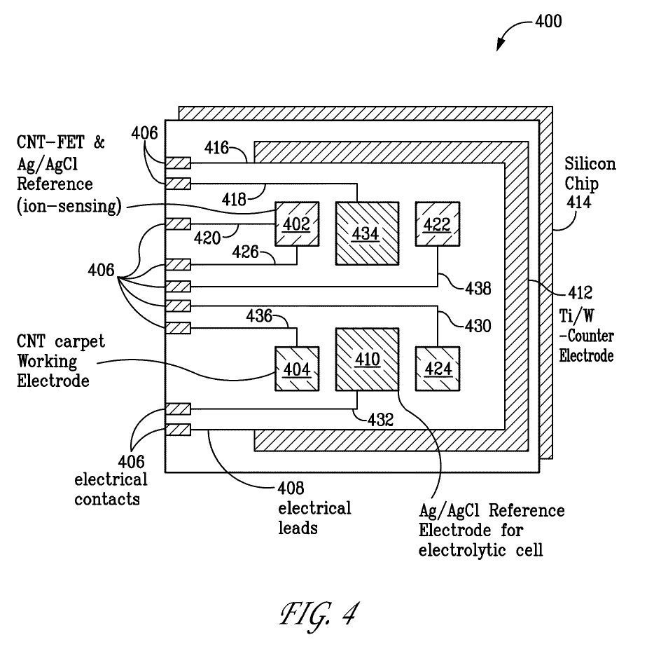

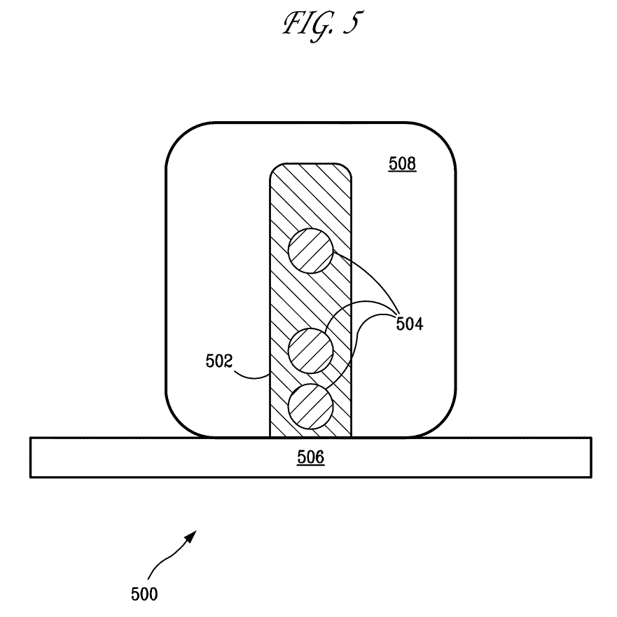

TABLE IV
Reference numerals description used in the figures.

| FIGS. 1A + 1B: | |
|---|---|
| 100 | doped CNT assembly electrode |
| 102 | substrate (oxidized silicon wafer) |
| 104 | electrically conductive layer (TiW/Mo/TiW/TiN) |
| 106 | catalyst (Ni) |
| 108 | metal layer (Cr/Au) |
| 110 | passivation layer (Silicon Nitride) |
| 118 | assembly of doped MWNTs |
| FIGS. 2A + 2B: | |
| 200 | doped CNT assembly FET |
| 202 | p-doped |
| 214 | thermal-oxide (insulating layer) |
| 218 | silicon nitride (protective layer) |
| 222 | gate oxide |
| 224 | catalyst layer |
| 230 | drain |
| 238 | array of aligned CNTs |
| 240 | source |
| 234 | silicon nitride |
| FIGS. 3A + 3B: | |
| 300 | a doped CNT assembly electrode array |
| 302 | substrate |
| 304 | thermal oxide layer or electrical conductive layer |
| 306 | nickel catalyst layer |
| 308 | metal contact layer |
| 310 | electrically conductive layer or silicon nitride |
| | insulating layer |
| 316 | contact holes |
| 318 | MWNT bundles |
| 328 | nickel metal interface |
| FIG. 4: | |
| 400 | integrated multisensor |
| 402 | CNT assembly FET |
| 404 | CNT assembly working electrodes |
| 422 | CNT assembly working electrodes |
| 424 | CNT assembly working elctrodes |
| 406 | electrical contacts |
| 408, 416 | electrical leads to counter electrode |
| 410, 434 | reference electrodes for electrolytic cell |
| 412 | counter electrode |
| 414 | substrate |
| 418, 432 | electrical leads to reference electrodes 410, 434 |
| 420 | ? gate lead to CNT assembly FET 402 |
| 426 | ? source lead to CNT assembly FET 402 |
| 428, 430, 436 | electrical leads to CNT assembly working electrodes |
| | to 422, 424, 404 |
| FIG. 5: | |
| 500 | vertically aligned doped CNT containing a fill material |
| | and having a cladding |
| 502 | CNT |
| 504 | fill material |
| 506 | catalyst layer/electrically conductive layer/substrate |
| 508 | cladding |
| FIG. 9: | |
| 900 | doped CNT array working electrode |
| 902 | substrate |
| 904 | thermal oxide layer |
| 906 | electrically conductive layer |
| 908 | metal contact pad |
| 910 | silicon nitride passivation layer |
| 912 | electrical contact hole |
| 914 | reactive ion etching |
| 916 | vertically-aligned MWNT array |
| 918 | chemically functionalized CNTs |
| FIG. 10 (a-r): | |
| 1000 | CNT-gated MOSFET |
| 1002 | substrate |
| 1004 | pad dioxide layer |
| 1006 | silicon nitride layer |
| 1008 | silicon recess etch |
| 1010 | boron |
| 1012 | field area |
| 1014 | thermal oxide (silicon dioxide) |
| 1016 | sacrificial gate oxide |
| 1018 | poly silicon |
| 1020 | source and drain areas |
| 1022 | 2nd gate oxide |
| 1024 | catalyst layer |
| 1026 | source + drain |
| 1028 | passivation layer (silicon nitride) |
| 1030 | contact holes |
| 1032 | CNT growth area |
| 1034 | metal contact |
| 1036 | water exposed to acetylene + ammonia gas |
| 1038 | vertically-oriented CNT array |
| 1040 | phosphorus ion implant |
| 1042 | dopant |
| FIG. 11: | |
| 1100 | Doped CNT assembly electrode array |
| 1102 | substrate |
| 1104 | thermal oxide layer |
| 1106 | electrically conductive layer |
| 1108 | metal contact pad |
| 1110 | silicon nitride passivation layer |
| 1112 | electrical contact hole |
| 1114 | reactive ion etching |
| 1116 | vertically aligned MWNT array |
| 1118 | chemically functionalized CNTs |
| FIG. 12: | |
| 1200 | CNT flow reactor system |
| 1202 | gas reactants and carrier gas cylinders |
| 1204 | gas regulators |
| 1206 | gas feed inlet conduit |
| 1208 | mass flow meters |
| 1210 | channel readout |
| 1212 | flow reactor inlet gas conduit |
| 1214 | gas flow reactor exterior |
| 1216 | gas flow reactor exterior |
| 1218 | CNT solid catalyst (Iron Phtholo) |
| 1220 | quartz plate substrates |
| 1222 | furnace, zone 3 |
| 1224 | temperature controllers |
| 1226 | reaction exhaust vent |
| 1228 | furnace, zone 1 |
| 1230 | furnace, zone 2 |
| FIG. 13: | |
| 1300 | Radio frequency deposition system |
| 1302 | substrate |
| 1304 | sheath |
| 1306 | target |
| 1308 | excitation electrode |
| 1310 | insulation of excitation electrode |
| 1312 | discharge glow |
| 1314 | passage to pumps |
| 1316 | inlet for monomer gas or argon gas |
| 1318 | shutter |
| 1320 | power supply |
| 1322 | grounding wire |
| 1324 | entrance for substrate |
| 1326 | substrate holder |
| 1328 | outlet for monomer gas or argon gas |
| 1330 | chamber housing |
| 1332 | Gauge Pump |
| 1334 | shutter feed-thru |
| 1336 | insulators |

A wide variety of doped antennae assembly electrodes, methods, sensors, and field-effect transistors, as well as associated methods of preparation are envisioned. For example, the doped antennae assembly electrode, can comprise: an electrically conductive layer at least partially surmounting a substrate; and an assembly of doped MWNTs vertically oriented with respect to the electrically conductive layer to provide the doped antennae assembly electrode. The doped antennae assembly electrode may further comprising a catalyst at least partially surmounting the electrically conductive layer, wherein at least a portion of the doped MWNTs are attached at their ends to the catalyst. The doped antennae assembly electrodes may comprise a plurality of MWNTs having one or more fill molecules. The doped antennae assembly electrodes may have fill molecules that include molecules, molecular ions, atoms, atomic ions, or any combination thereof. The doped antennae assembly electrodes may have fill molecules that comprise one or more fullerenes, doped fullerenes, ionophores, ion exchangers, redox molecules, conductive polymers, or any combination thereof. The doped antennae assembly electrodes may include ionophores that include cyclic polyethers, antibiotics, linear chain ligands or any combination thereof. The doped antennae assembly electrodes may have cyclic polyethers that comprise 12-crown-4 to 24-crown-8 polyethers, or any combination thereof. The doped antennae assembly electrodes may have ionophores that include one or more cryptands, calixarenes, rotaxanes, or any combination thereof. The doped antennae assembly electrodes may have fullerenes that include one or more of C60, C70, C80, C90, or any combination thereof. The doped antennae assembly electrodes may include fullerenes that are doped fullerenes. The doped antennae assembly electrodes may include doped fullerenes that are filled, coated, chemically functionalized, or any combination thereof. The doped antennae assembly electrodes may include ion exchangers that include quaternized PVC, sulfonated PTFE, or any combination thereof. The doped antennae assembly electrodes may include antibiotics such as valinomycin, nonactin, monensin, iosin, or any combination thereof. The doped antennae assembly electrodes may include linear chain ligands such as poly-oxyethylene, tri-n-alkylammonium halide, or any combination thereof. The doped antennae assembly electrodes may include fill molecules that are semiconductor polymers comprising donor-acceptor pairs. The doped antennae assembly electrodes may include semiconductor polymers that comprise donor-acceptor pairs include semicarbazole/TCNQ, ionene/iodine, or any combination thereof. The doped antennae assembly electrodes may include fill molecules that comprise conductive polymers. The doped antennae assembly electrodes may include conductive polymers that comprise a polypyrrole, a polyaniline, a poly-p-phenylene, a polyacetylene, or any combination thereof. The doped MWNT assembly electrods may include at least two of the doped MWNTs that comprise different fill molecules. The doped antennae assembly electrodes may include fill molecules that include a chemical agent capable of responding to a chemical or an electrical signal.

The doped antennae assembly electrodes may include a plurality of MWNTs having a cladding. The doped antennae assembly electrodes may include cladding that includes a dielectric, an ion conducting polymer, an electron conducting polymer, an ionophore polymer dopant, a redox-mediator dopant, or any combination thereof. The doped antennae assembly electrodes may include dielectric that includes a polyolefin polymer, a polyaliphatic polymer, a polysiloxane polymer, a polyurethane polymer, a polyvinylchloride polymer, alumina, or any combination thereof. The doped antennae assembly electrodes may include ion conducting polymer that includes nafion, polystyrene sulfonate, polyvinylpridinium, or any combination thereof. The doped antennae assembly electrodes may include electron conducting polymer that includes a doped polymer, an electrochemically doped polymer, a redox electroactive polymer, or any combination thereof. The doped antennae assembly electrodes may include doped polymer that includes a polyionine, a polysilicon, a polysemicarbazole, a polyphenylene, a polyacetylene, a polyphenylene sulfide, or any combination thereof. The doped antennae assembly electrodes may include doped polymer that includes a dopant, the dopant comprising AsF5, I2, Li, K, BF6-, PF6-, or any combination thereof. The doped antennae assembly electrodes may include electrochemically doped polymer that includes a polypyrrole, a polythiophene, a polyphenylquinone, a polyaniline, or any combination thereof. The doped antennae assembly electrodes may include redox electroactive polymers that include polyviologen, polyvinylferrocene, poly-Ru(vbpy)3++, or any combination thereof. The doped antennae assembly electrodes may include ionophore polymer dopant that includes a crown ether, a cryptand, a sphereand, a rotaxane, an antibiotic, a non-cyclic ligand, or any combination thereof. The doped antennae assembly electrodes may include redox-mediator dopant that includes Ru(bpy)3++, Br2/Br—, Fe(phen)3+++, Co(terpy)2+++, Fe(CN)6(3−), Ru(NH3)6+++, quinone, hydroquinone, methylviologen, tetracyanoquinodimethane, benzophenone, ferrocene, tetramethyl-p-phenylenediamine, tetrathiafulvalene, tri-N-p-tolylamine, or any combination thereof.

The doped antennae assembly electrodes may include cladding that comprises one or more functional reactive groups residing upon a surface of the cladding. The doped antennae assembly electrodes may include functional reactive groups that include an oxide, a hydroxide, a carboxylic acid, an ester, an ether, a carbonyl, an amine, an amide, an epoxide, a halide, or any combination thereof. The doped antennae assembly electrodes may include cladding that includes a linker attaching the cladding to the doped MWNTs. The doped antennae assembly electrodes may include a linker that includes a Schiff base, a carbodi-imide, an amide, or any combination thereof. The doped antennae assembly electrodes may include cladding linked to a selective functionality on the surface of one or more of the MWNTs. The doped antennae assembly electrodes may include selective functionality on the surface of one or more of the MWNTs that includes a protein, a phospholipids, a nucleic acid, an electron mediator, an ionophore, or any combination thereof. The doped antennae assembly electrodes may include protein that includes an enzyme, an antibody, or any combination thereof. The doped antennae assembly electrodes may include nucleic acid that includes an oligonucleotide, DNA, RNA, or any combination thereof.

The doped antennae assembly electrodes may include at least two of the doped MWNTs comprise different claddings. The cladded doped antennae assembly electrodes may include cladding that includes a chemical agent capable of responding to a chemical or an electrical signal. The cladded doped antennae assembly electrode may include a chemical agent capable of responding to a chemical or an electrical signal.

The doped antennae assembly electrodes may include MWNTs that comprise one or more functional reactive groups covalently attached to the graphene surface of the MWNTs. The doped antennae assembly electrode of claim 42, wherein the functional reactive groups include an oxide, a hydroxide, a carboxylic acid, an ester, an ether, a carbonyl, an amine, an amide, an epoxide, a halide, or any combination thereof. The doped antennae assembly electrodes may include functional reactive groups covalently attached to the graphene surface includes a linker attached to the doped MWNTs. The doped antennae assembly electrodes may include a linker that includes a Schiff base, a carbodi-imide, an amide, or any combination thereof. The doped antennae assembly electrodes may include functional reactive groups covalently attached to the graphene surfaceincludes a selective functionality. The doped antennae assembly electrodes may include selective functionality that includes a protein, a phospholipids, a nucleic acid, an electron mediator, an ionophore, or any combination thereof. The doped antennae assembly electrodes may include protein that includes an enzyme, an antibody, or any combination thereof. The doped antennae assembly electrodes may include nucleic acid that includes an oligonucleotide, DNA, RNA, or any combination thereof.

The doped antennae assembly electrodes may include an electrically conductive layer that comprises a metal, an electrically conductive polymer, a carbon film, or any combination thereof. The doped MWNT assembly e electrodes may include an electrically conductive layer that is a lead conductor residing between the substrate and the catalyst. The doped antennae assembly electrodes may include an electrically conductive layer that comprises Pt, Au, Ti, W, V, Mo, or any combination thereof. The doped antennae assembly electrodes may include metal that comprises a CVD-deposited metal. The doped antennae assembly electrodes may include CVD-deposited metal that comprises TiW, Mo, TiN, or any combination thereof. The doped antennae assembly electrodes may include an electrically conductive layer that is characterized as having a layer thickness in the range of from about 1 nanometer to about 1000 nanometers. The doped antennae assembly electrodes may include an electrically conductive layer that is characterized as having a layer thickness in the range of from about 10 nanometers to about 100 nanometers. The doped antennae assembly electrodes may include an electrically conductive layer that is characterized as having a layer thickness in the range of from about 50 nanometers to about 100 nanometers.

The doped antennae assembly electrodes may include catalyst that comprises Ni, Co, Fe, Ru, Rh, Pd, Os, Ir, or any combination thereof. The doped antennae assembly electrodes may include catalyst that comprises an organo-metallic catalyst, an iron-phthalocyanine, a cobalt-phthalocyanine, or any combination thereof. The doped antennae assembly electrodes may include catalyst capable of growing MWNTs. The doped antennae assembly electrodes may include catalysts capable of growing MWNTs such as nickel, cobalt, iron, or any combination thereof. The doped antennae assembly electrodes may include catalyst characterized as having a layer thickness in the range of from about 1 nanometer to about 10,000 nanometers. The doped antennae assembly electrodes may include catalyst characterized as having a layer thickness in the range of from about 500 nanometers to about 1000 nanometers. The doped antennae assembly electrodes may include catalyst characterized as having a layer thickness in the range of from about 700 nanometers to about 900 nanometers.

The doped antennae assembly electrodes may include a plurality of doped MWNTs perpendicularly oriented to the substrate. The doped antennae assembly electrode of claim 65, wherein the doped MWNTs are oriented parallel to each other. The doped antennae assembly electrodes may include a doped MWNT carpet, a doped MWNT array, or any combination thereof. The doped antennae assembly electrodes may include an electrically conductive layer that comprises a single contiguous conductive layer, and the doped MWNT carpet is in electrical communication with the single contiguous conductive layer. The doped antennae assembly electrodes may include an aligned array of nanotubes of a defined geometry and pitch oriented with respect to the electrically conductive layer. The doped antennae assembly electrodes may include an array of doped MWNTs. The doped antennae assembly electrodes may include catalyst patterned on the electrically conductive layer, and the assembly of doped MWNTs is attached to the patterned catalyst. The doped antennae assembly electrodes may include catalyst patterned as an array of islands, stripes, circles, squares, rings, triangles, polygons, or any combination thereof.

The doped antennae assembly electrodes can also be used as a working electrode in an electrolytic cell or sensor. The doped antennae assembly electrodes may include a substrate comprising quartz, aluminum oxide, alumina, silicon, a ceramic boat, chromium, iridum, aluminum, niobium, tantalum, titanium, tungsten, carbon, silicon oxide, silicon carbide, brass, bronze, silver, gold, glass, indium tin oxide, graphite, platinum, magnesium aluminum oxide, platinum crucible, magnesium aluminate spinel, or any oxide, alloy, or combination thereof. The doped antennae assembly electrodes may include one or more layers of quartz, aluminum oxide, alumina, silicon, a ceramic boat, chromium, iridum, aluminum, niobium, tantalum, titanium, tungsten, carbon, silicon oxide, silicon carbide, brass, bronze, silver, gold, glass, indium tin oxide, graphite, platinum, magnesium aluminum oxide, platinum crucible, magnesium aluminate spinel, or any oxide, alloy, or combination thereof.

Sensors may include any of the doped MWNT electrodes described herein. Likewise, field effect transistors may include any of the doped MWNT electrodes described herein.

Methods of making doped antennae assembly electrodes may include the steps of: surmounting a substrate with an electrically conductive layer; surmounting an assembly of MWNTs on the electrically conductive layer, the MWNTs being vertically oriented; and doping at least a portion of the MWNTs with a cladding, a covalent bond linkage, a functional dopant molecule, a fill material, or any combination thereof. The methods may include the step of surmounting the substrate with a thermal oxide layer, and the electrically conductive layer surmounts the thermal oxide layer. The methods may include the step of surmounting the thermal oxide layer with an electrically conductive contact pad. The methods may include the electrically conductive layer being surmounted to the substrate using a chemical vapor deposition process, a sputtering process, a fluid deposition process, or any combination thereof. The methods may include a catalyst being surmounted to the electrically conductive layer using a chemical vapor deposition process, a sputtering process, a fluid deposition process, or any combination thereof. The methods may include the chemical vapor deposition process including a gas phase thermal chemical vapor deposition method, a solid precursor chemical vapor deposition method, a plasma-enhanced chemical vapor deposition method, or any combination thereof. The methods may include a chemical vapor deposition method including microwave stimulation, radio frequency plasma stimulation, direct current plasma field enhancement, or any combination thereof. The methods may include the step of surmounting an assembly of MWNTs includes end-linking a plurality of MWNTs to the conductive layer. The methods may include the plurality of MWNTs self-assembling on the conductive layer.

The methods may include the MWNTs comprising an end-functionalized MWNT. The methods may include the conductive layer comprising functional groups that link to the ends of the MWNTs. The methods may include the MWNTs comprising an end-functionalized MWNT. The methods may include the MWNTs being provided as a dispersion of a plurality of MWNTs in a fluid, and the fluid may be an organic liquid, an aqueous liquid, or any combination thereof.

The methods may include the step of surmounting an assembly of MWNTs including growing an assembly of MWNTs on the conductive layer. The methods may include the step of growing an assembly of MWNTs includes gas phase thermal vapor deposition, solid precursor chemical vapor deposition, plasma enhanced chemical vapor deposition, or any combination thereof.

The methods may include the step of surmounting an assembly of MWNTs that includes surmounting the conductive layer with catalyst and contacting a MWNT forming composition and the catalyst at conditions necessary to grow the assembly of MWNTs from the catalyst. The methods may include the step of growing an assembly of MWNTs that includes gas phase thermal vapor deposition, solid precursor chemical vapor deposition, plasma enhanced chemical vapor deposition, or any combination thereof. The methods may include the MWNT forming composition comprising an organometallic precursor, or any combination thereof. The methods may include the organometallic precursor comprising a phthalocyanine, a porphorin, a carbon bearing ligand, or any combination thereof. The methods may preferably include the organometallic precursor comprising iron(II) phthalocyanine. The methods may include the carbon bearing ligand comprising a transition metal chelate including Fe, Co, Ni, Ru, Os, Eu, or any combination thereof. The methods may include the MWNT forming composition comprising one or more molecules composed of covalently bonded carbon atoms, hydrogen atoms, oxygen atoms, nitrogen atoms, or any combination thereof. Here, the molecules include gases comprising methane, ethane, propane, butane, ammonia, acetylene, ethylene, propylene, or any combination thereof. Alternatively, the molecules may include liquids comprising aliphatic hydrocarbons, olefins, or any isomer or combination thereof. The conditions necessary to form the assembly of MWNTs may include a temperature in the range of from about 300° C. to about 1000° C. and a pressure in the range of from about 10⁻¹ torr to 10⁻⁹ torr. The conditions necessary to form the assembly of MWNTs may include a temperature in the range of from about 500° C. to about 700° C. and a pressure in the range of from about 10⁻⁶ torr to 10⁻⁹ torr. Alternatively, plasma-enhanced chemical vapor deposition can be used to form the MWNTs.

The methods may include the step of doping that includes liquid coating, chemical vapor deposition, ion beam deposition, electrospray coating, supercritical fluid solute phase transfer, or any combination thereof. The methods may include ion beam deposition that includes electro-spray ionization, electron beam deposition, proton beam deposition, atomic ion beam deposition, molecular beam deposition, or any combination thereof. The methods may further include the step of depositing a metal on the electrically conductive layer to provide an electrode contact pad. The methods may include the electrode contact pad being distally located from the assembly of MWNTs. The methods may further include the step of patterning the assembly of MWNTs. The methods may include the step of patterning to give rise to an array of MWNTs. The methods may include the step of patterning that includes photolithography, UV lithography, e-beam lithography, reactive ion etching, chemical etching, nano-imprinting, electro-forming, or any combination thereof. The methods may further include the step of patterning the electrically conductive layer. Here, the step of patterning typically gives rise to an array of MWNTs. The step of patterning can include photolithography, UV lithography, e-beam lithography, reactive ion etching, chemical etching, nano-imprinting, electro-forming, or any combination thereof.

The methods may include the step of surmounting the substrate with an electrically conductive layer includes electroforming, electro-less deposition, electrochemical deposition, vapor deposition, sputtering, or any combination thereof. The methods may include using an assembly of doped MWNTs that comprise a plurality of MWNTs having a fill material. Fill material may include molecules, molecular ions, atoms, atomic ions, or any combination thereof. Fill material may include one or more fullerenes, doped fullerenes, ionophores, ion exchangers, redox molecules, conductive polymers, or any combination thereof. Ionophores may include ionophores include cyclic polyethers, antibiotics, linear chain ligands or any combination thereof. Cyclic polyethers may include 12-crown-4 to 24-crown-8 polyethers, or any combination thereof. Ionophores may include one or more cryptands, calixarenes, rotaxanes, or any combination thereof.

The methods may include the fullerenes including one or more of C60, C70, C80, C90, or any combination thereof. The fullerenes can be doped fullerenes. The doped fullerenes can be filled, coated, chemically functionalized, or any combination thereof. The methods may include ion exchangers including quaternized PVC, sulfonated TPFE, or any combination thereof. The methods may include antibiotics that include valinomycin, nonactin, monensin, iosin, or any combination thereof. The methods may include linear chain ligands that include poly-oxyethylene, tri-n-alkylammonium halide, or any combination thereof. The methods may include fill material that includes semiconductor polymers comprising donor-acceptor pairsSemiconductor polymers can comprise donor-acceptor pairs include semicarbazole/TCNQ, ionene/iodine, or any combination thereof. Alternatively, the fill material can include conductive polymers. Suitable conductive polymers comprise a polypyrrole, a polyaniline, a poly-p-phenylene, a polyacetylene, or any combination thereof.

The methods may include at least two of the doped MWNTs comprising different fill molecules. For example, the fill material may include a chemical agent capable of responding to a chemical or an electrical signal.

The methods may include at least a portion of the MWNTs are doped with a cladding. The cladding can include a dielectric, an ion conducting polymer, an electron conducting polymer, an ionophore polymer dopant, a redox-mediator dopant, or any combination thereof. The dielectric can include a polyolefin polymer, a polyaliphatic polymer, a polysiloxane polymer, a polyurethane polymer, a polyvinylchloride polymer, alumina, or any combination thereof. Ion conducting polymer can include nafion, polystyrene sulfonate, polyvinylpridinium, or any combination thereof. Electron conducting polymer can include a doped polymer, an electrochemically doped polymer, a redox electroactive polymer, or any combination thereof. The doped polymer can include a polyionine, a polysilicon, a polysemicarbazole, a polyphenylene, a polyacetylene, a polyphenylene sulfide, or any combination thereof. The doped polymer can include a dopant, the dopant comprising AsF5, I2, Li, K, BF6-, PF6-, or any combination thereof. The electrochemically doped polymer can include a polypyrrole, a polythiophene, a polyphenylquinone, a polyaniline, or any combination thereof. The redox electroactive polymers can include polyviologen, polyvinylferrocene, poly-Ru(vbpy)3++, or any combination thereof. The ionophore polymer dopant can include a crown ether, a cryptand, a sphereand, a rotaxane, an antibiotic, a non-cyclic ligand, or any combination thereof. The redox-mediator dopant can inlcude Ru(bpy)3++, Br2/Br—, Fe(phen)3+++, Co(terpy)2+++, Fe(CN)₆(3−), Ru(NH3)6+++, quinone, hydroquinone, methylviologen, tetracyanoquinodimethane, benzophenone, ferrocene, tetramethyl-p-phenylenediamine, tetrathiafulvalene, tri-N-p-tolylamine, or any combination thereof.

The methods may include cladding that comprises one or more functional reactive groups residing upon a surface of the cladding. The functional reactive groups can include an oxide, a hydroxide, a carboxylic acid, an ester, an ether, a carbonyl, an amine, an amide, an epoxide, a halide, or any combination thereof. The cladding can include a covalent bond linkage attaching the cladding to the doped MWNTs. The covalent bond linkage can include a Schiff base, a carbodi-imide, an amide, or any combination thereof. The cladding can be linked to a selective functionality on the surface of one or more of the MWNTs. The selective functionality on the surface of one or more of the MWNTs can include a protein, a phospholipids, a nucleic acid, an electron mediator, an ionophore, or any combination thereof. The protein can include an enzyme, an antibody, or any combination thereof. The nucleic acid can include an oligonucleotide, DNA, RNA, or any combination thereof.

The methods may also include at least two of the doped MWNTs comprise different claddings. The methods may inlcude at least a portion of the MWNTs being doped with a functional dopant molecule. The MWNTs may comprise one or more functional dopant molecules covalently attached to the graphene surface of the MWNTs. The functional dopant molecules may include an oxide, a hydroxide, a carboxylic acid, an ester, an ether, a carbonyl, an amine, an amide, an epoxide, a halide, or any combination thereof. At least a portion of the MWNTs may be doped with a covalent bond linkage that is covalently linked to the graphene surface of the MWNT. The covalent bond linkage may include a Schiff base, a carbodi-imide, an amide, or any combination thereof. The functional dopant molecules may be covalently attached to the graphene surface using a selective functionality. The selective functionality may include a protein, a phospholipids, a nucleic acid, an electron mediator, an ionophore, or any combination thereof. The protein may include an enzyme, an antibody, or any combination thereof. The nucleic acid may include an oligonucleotide, DNA, RNA, or any combination thereof.

The methods may include the electrically conductive layer comprises a metal, an electrically conductive polymer, a carbon film, or any combination thereof. The electrically conductive layer may be capable of being a lead conductor residing between the substrate and a catalyst surmounted to the electrically conductive layer. The electrically conductive layer may comprise Pt, Au, Ti, W, V, Mo, or any combination thereof. The metal may comprise a CVD-deposited metal. The CVD-deposited metal may comprise TiW, Mo, TiN, or any combination thereof. The electrically conductive layer can have a layer thickness in the range of from about 1 nanometer to about 1000 nanometers, in the range of from about 10 nanometers to about 100 nanometers, or in the range of from about 50 nanometers to about 100 nanometers. The catalyst can comprise Fe, Co, Ni, Mo, Ru, Pt, Cr, Pd, Pd, Si, Tb, Se, Cu, Al, Rh, Os, Ir, or any combination or alloy thereof. The catalyst can comprise Pd powder, Ni silicide, Fe—Ni alloy, Fe—Ni—Cr alloy, Mo—Fe alloy film, Fe—Tb alloy, Pd—Se alloy, Cu—Ni alloy, Co—Cu alloy, Al—Fe alloy, Cu—Fe alloy, Fe—Ni alloy, Alumina-Ni alloy, Alumina-Ni—Cu alloy, or any combination thereof. The catalyst can comprise an organo-metallic catalyst, an iron-phthalocyanine, a cobalt-phthalocyanine, or any combination thereof. The catalyst is usually capable of growing MWNTs. The catalysts capable of growing MWNTs includes nickel, cobalt, iron, or any combination thereof. The catalyst is characterized as having a layer thickness in the range of from about 1 nanometer to about 10,000 nanometers, in the range of from about 500 nanometers to about 1000 nanometers, or in the range of from about 700 nanometers to about 900 nanometers.

The methods may include a doped MWNT assembly comprising a plurality of doped MWNTs perpendicularly oriented to the substrate. The doped MWNTs can be oriented parallel to each other. The assembly of doped MWNTs can comprise a doped MWNT carpet, a doped MWNT array, or any combination thereof. The electrically conductive layer can comprise a single contiguous conductive layer, and the doped MWNT carpet is in electrical communication with the single contiguous conductive layer. The doped MWNT array can comprise an aligned array of nanotubes of a defined geometry and pitch oriented with respect to the electrically conductive layer. The assembly of doped MWNTs can comprise an array of doped MWNTs. The catalyst can patterned on the electrically conductive layer, and the assembly of doped MWNTs can be attached to the patterned catalyst. The catalyst can be patterned as an array of islands, stripes, circles, squares, rings, triangles, polygons, or any combination thereof.

Antennae assembly field-effect transistors can include a substrate comprising a source and a drain; a gate oxide layer at least partially surmounting the substrate, source and drain; an electrically conductive layer at least partially surmounting the gate oxide layer; and an assembly of doped MWNTs vertically oriented with respect to the electrically conductive layer.

Sensors can include at least two electrodes situated on a substrate, wherein at least one of the electrodes comprises a doped antennae assembly electrode, the doped antennae assembly electrode comprising an electrically conductive layer at least partially surmounting the substrate; and an assembly of doped MWNTs vertically oriented with respect to the electrically conductive layer to provide the doped antennae assembly electrode. The sensors can include electrodes that include at least one working electrode and at least one reference electrode. Sensors can have at least one working electrode comprises a doped antennae assembly electrode. Sensors can have at least one reference electrode comprises a doped antennae assembly electrode. At least one working electrode and at least one reference electrode can comprise a doped antennae assembly electrode. The reference electrode can be situated on a field-effect transistor. A field-effect transistor can comprises a source and a drain, the source and drain being electrically connected by conductive leads to electrical contacts situated on the substrate. Sensors can include field-effect transistors that comprises: a gate oxide layer at least partially surmounting the substrate, source and drain; the electrically conductive layer at least partially surmounting the gate oxide layer; and having the assembly of doped MWNTs vertically oriented with respect to the electrically conductive layer. Sensors may further comprise a counter electrode. Sensors may further comprise a counter electrode comprises a doped antennae assembly electrode, a metallic electrode, or any combination thereof. Sensors may further comprise a metallic electrode that is composed of gold, silver, platinum, palladium, copper, iron, titanium, tungsten, or any combination thereof. Sensors may further comprise electrically conducting leads connecting each of the electrodes to an electrical contact situated on the substrate.

### Patterned Growth of ACNTs by Solid Precursor Assisted CVD

In these examples a fabrication process is provided to grow carbon nanotube selectively in a chemical vapor deposition using an organic-metallic precursor Iron (II)

Phthalocyanine as a catalyst and a carbon source on a given substrate. The process of chemical vapor deposition (CVD) involves the transformation of gaseous molecules into solid material on the surface of the substrate. Metals, alloys, or polymeric films can be deposited by the chemical vapor deposition method and thus ideal for thermal growth of carbon nanotubes. A one step method is provided to prepare a well aligned carbon nanotube array which utilizes an organo-metallic precursor which serves as the source of carbon as well as the metal catalyst. This example shows that MWNTs do not grow on copper surfaces. This example provides a fabrication method to pattern copper on a substrate, which method selectively controls the growth of the nanotubes. A fabrication method is provided for depositing copper to prevent growth of carbon nanotubes generated by pyrolysis of Iron (II) Phthalocyanine. A fabrication method is provided for patterning copper to selectively grow aligned carbon nanotubes generated by pyrolysis of Iron (II) Phthalocyanine.

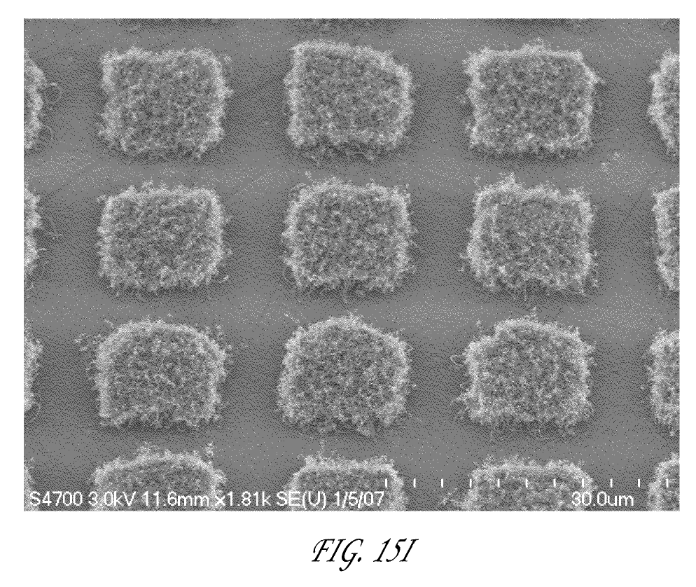

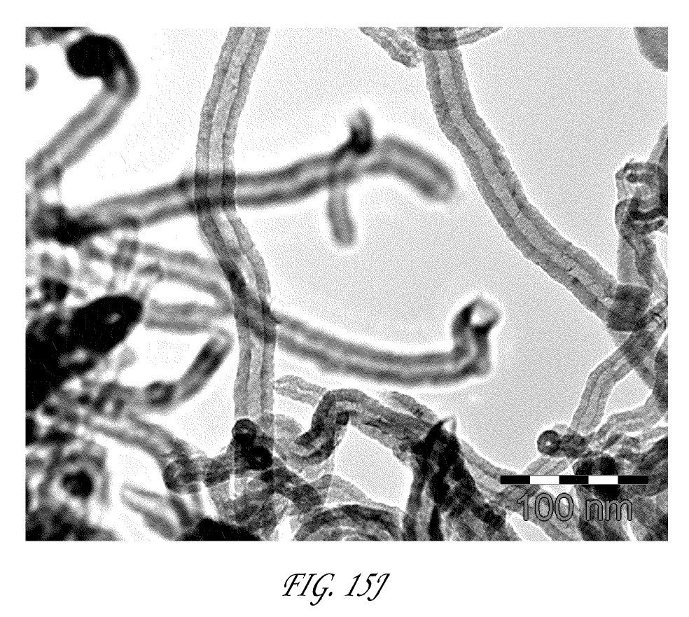

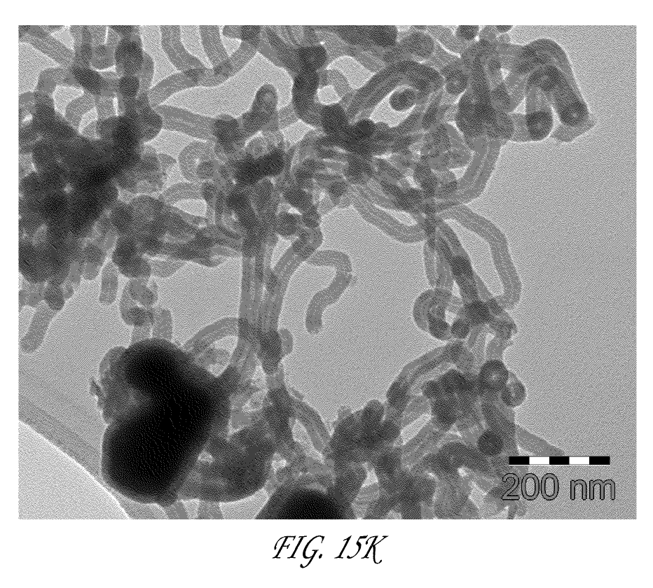

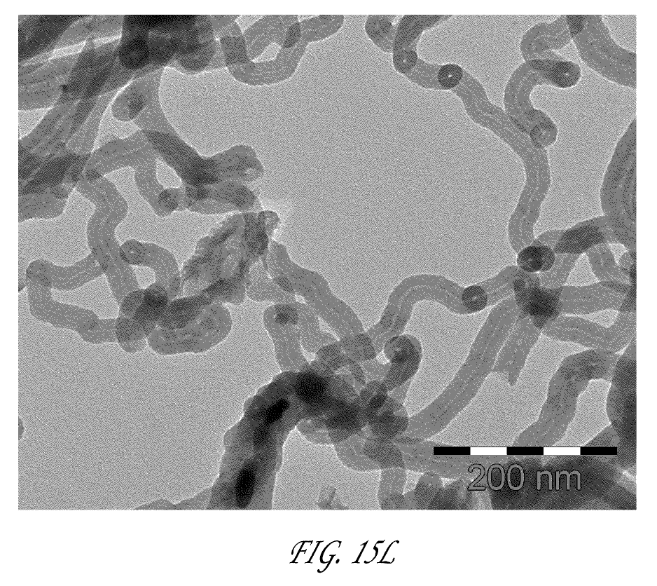

In this example, the process starts with a 100 mm p-type silicon wafer with a 1 um thick thermal oxide (FIG. 14A). A 2500A of polysilicon layer is deposited at 600C following by a phosphorus implantation (dose=1E16 J/cm2, energy=100 keV, 7° tilt), and another 2500A of polysilicon layer deposition. The dopant is activated at 1000C for one hour. The annealed polysilicon should have resistivity of 20-25 ohms/square. The polysilicon (FIG. 14B) is patterned using standard lithography technique and etched by reactive ion etching to form the sensing electrode. Next, a 2000A thick layer of silicon nitride (FIG. 14C) is deposited by low pressure chemical vapor deposition acting as an insulating material. Access holes are patterned and opened by reactive ion etching of silicon nitride (FIG. 14D). A 5000A thick copper layer (FIG. 14E) is sputtered and is patterned by the reverse mask of the previous access hole patterns. Copper is then lifted off by soaking into acetone (FIG. 14F). At this point, the sample surface essentially has two types of surface: 1) the conductive polysilicon electrode, and 2) copper masking layer.

ACNTs Growth Procedure:
1. The pre-patterned substrate is introduced into the flow reactor (quartz tube) (refer FIG. 141).
2. Iron (II) Phthalocyanine (0.1-0.7 g) is placed in a quartz/ceramic boat and placed inside the quartz tube.
3. The system is sealed and flushed with Argon (Ar) (300-500 Sccm) for 20-30 minutes. This step removes any oxygen present in the quartz tube and provides an inert reaction atmosphere.
4. The temperature of the furnace is set at desired growth temperature which may range from 800-960° C. depending on the size, density and quality of ACNTs.
5. As the temperature of the system reaches 800° C. the flow rate of Ar is reduced to desired flow rate (10-150 Sccm) and H₂ is introduced in the gas flow at a desired flow rate (10-150 Sccm). Allow 10 minutes for the gases to mix uniformly inside the reactor.
6. The gas flow is maintained steady through out the growth process.
7. Pyrolysis of the Precursor: Once the furnace attains constant set temperature, the precursor boat is transferred in the temperature range (450-750° C.) where the pyrolysis of the organo-metallic precursor is triggered. Iron and carbon source is released into the gas phase and gets carried into the flow stream by Ar and H₂. (30 sec-2 min)
8. The carrier gas transports the metal/carbon into the high temperature zone where the growth of carbon nanotubes on the substrate takes place. (2-10 min)
9. After the reaction time, the furnace is shut-off, the H₂ flow is turned off, and only Ar gas flow is maintained steady at a low flow rate (300-500 Sccm).
10. Once the furnace temperature reaches a safe value and all the H₂ is flushed out of the reactor system, the quartz tube is opened and exposed to air.
11. The ACNT growth will take place only on chip area which is not covered with Copper.
12. The substrate is taken out of the tube and taken for Copper removal process.

Post-Synthesis Clean Up—Copper Layer Removal Process:
1. After the synthesis of ACNTs on the patterned chip (CHEM Chip), the Cu—sacrificial/growth inhibiting layer has to be removed, without hindering the alignment and geometry of the carbon nanotubes.
2. Cu-removal solution: H₂O:HCl:H₂O₂ in the ratio of 20:0.4:0.2 v/v. Dip the ACNT coated CHEM Chip in Cu-removal solution with stirring for 5 min.
3. Remove the ACNT coated CHEM Chip from the Cu-removal solution and dip it in D₁-H₂O with stirring and allow to clean for 10 min.
4. After D₁-H₂O rinsing, dry the ACNT coated CHEM Chip in air.
5. The dry ACNT coated CHEM Chip is introduced into the RF Plasma Asher.
6. O₂ or H₂O Plasma treatment is carried out to remove residual organic deposits present on the ACNT coated CHEM Chip. Plasma Conditions: Power 25-50 W; Pressure 0.9-0.08 mbarr; Time 30 sec-10 min. While this plasma etches away the amorphous carbon, it also attacks the nanotube to some degree. An alternative fabrication process could involve depositing an additional silicon dioxide layer underneath the copper sacrificial layer. The amorphous carbon could then be lifting off when the sample is soaking in hydrofluoric acid, while nanotubes remain unattacked.
7. After the Plasma Clean Up Process, inert SiN layer is exposed and the ACNT patterned chip is ready for further characterization and sensor development.

### Growth of Aligned/Non-Aligned Carbon Nanotubes by Gas Phase Chemical Vapor Deposition

Carbon nanotubes (CNTs) are synthesized in a thermal CVD system using Argon (Ar), Ammonia (NH₃)/Hydrogen (H₂) as the carrier gas mixture and Acetylene (C₂H₂) as the carbon source. Gas Phase CVD growth has been successfully established on Nickel metal catalyst and various substrates like Si, SiO₂, SiN, Poly Si (Phosphorus doped) and P-type Si (Boron Doped). The tubes grown are either aligned or not aligned depending on the process conditions a substrate preparation. The diameter of these nanotubes range from 10-40 nm with thick walls and narrow cores. The growth conditions govern the synthesis of predominantly bamboo structured tubes or mixture of bamboo and hollow tubes. This growth process is defined by the catalyst and was successfully transferred onto the patterned chip to yield clean and patterned carbon nanotube growth. Non-aligned CNTs were grown on these substrates at growth temperature of 650° C. to 750° C. Aligned CNTs are grown by adding Titanium (Ti) as the barrier layer in between the substrate (Si) and catalyst (Ni). Titanium with thickness of 10-50 nm was deposited on the substrate prior to nickel deposition. The following describes detail experimental processes used to synthesize CNTs in a thermal CVD system.

Substrate Pre-treatment. Annealing. Sample annealing at temperature range from 350° C. to 450° C. is used prior to CNTs growth. Sample is introduced inside the furnace and flushed with Ar gas (100-300 sccm) for 10 minutes. The exhaust of the reactor is attached to a vacuum source which creates 10 to 1 Torr pressure inside the reactor. Ar flow is cut-off once vacuum is achieved inside the reactor. The furnace is turned on and temperature is set for 350° C. to 450° C. It takes approximately 5 to 7 minutes for the furnace to reach the set temperature. Heating under vacuum is carried out for 12 to 18 hours. At the end of the annealing time the furnace power is turned off and allowed to cool down until it reaches room temperature. The vacuum source is then cut-off and the system is purged with Ar. The system is opened and pre-treated substrate is ready for CNTs growth process.

CNTs growth processes by gas phase CVD. Annealed substrate is introduced inside the thermal CVD reactor. The CVD reactor is sealed and flushed with Ar gas (100 to 300 Sccm) for 10 minutes. After sufficient purging, the furnace power is turned on and the system is heated under Ar atmosphere until the set temperature (650° C. to 750° C.). Once the growth temperature is reached, Ar gas flow rate is changed to the desired value which can range from 5 to 400 sccm depending on the substrate combination used and quality of CNTs desired. Etching gas Hydrogen/Ammonia is introduced in the system at a flow rate ranging from 10 to 250 sccm. The etching process is carried out for 2 to 10 minutes to form nanometer size catalytic particles. After the etching step, Acetylene as the carbon source is introduced into the chamber to grow CNTs. The growth time ranges from 5 to 60 minutes. After the growth time, Acetylene is turned off while Ar and Hydrogen/Ammonia are kept at constant flow ratio for 1 minute. Then the Hydrogen/Ammonia and furnace are turned off and the sample is allowed to cool to room temperature in Ar (100-300 sccm) atmosphere. After cool down, the system is opened and sample is taken for further examination.

### Growth of Aligned Carbon Nanotubes by Solid Precursor Assisted Chemical Vapor Deposition

These examples pertains to a chemical vapor deposition process for growng aligned multiwalled carbon nanotube film on a variety of substrates. The chemical vapor deposition recipes adapted for the growth of aligned carbon nanotubes are very specific as they allow for the use of these films as electrodes for sensing applications.

The process of chemical vapor deposition (CVD) involves the transformation of gaseous molecules into solid material on the surface of the substrate. Metals, alloys, or polymeric films can be deposited by the chemical vapor deposition method and thus ideal for thermal growth of carbon nanotubes. A one step method is developed to prepare a large quantity of well aligned carbon nanotube film without any substrate pre-treatment or a preformed template, which utilizes an organo-metallic precursor as the source of carbon as well as the metal catalyst. This one-step production of bundles of aligned carbon nanotube array requires no prior preparation of the substrate or an external template to direct the alignment. This process allows growth of ACNTs on variety of conducting as well as insulating substrates like Silicon, Doped Silicon, Poly Silicon, Silicon Nitride, Silicon Oxide etc. Iron (II) Phthalocyanine (FePc) is used as the source which provides metal catalyst as well as carbon feed for preparing aligned carbon nanotubes. A mixture of Argon (Ar) and Hydrogen (H₂) is used as carrier gas during the growth process. The carbon nanotubes grown by this method are multiwalled carbon nanotubes, with length in the range of 1-50 μm and diameter in the range of 40-100 nm. The tubes grown are a mixture of hollow and bamboo structured tubes. The core size of these tubes range from 5-15 nm which is favorable for further doping processes. Trace amount of amorphous carbon have been detected on the side walls of the nanotube, but no apparent interference on the electrode properties has been observed.

ACNT Growth Procedure
1. The substrate (quartz slide/silicon chip) is cleaned with Isopropyl alcohol, dried in air and introduced into the flow reactor (quartz tube) (refer FIG. 14I).
2. Iron (II) phthalocyanine (0.1-0.7 g) is placed in a quartz/ceramic boat and placed inside the quartz tube.
3. The whole system is sealed and flushed with Argon (Ar) (300-500 Sccm) for 20-30 minutes. This step removes any oxygen present in the quartz tube and provides an inert reaction atmosphere.
4. The temperature of the furnace is set at desired growth temperature which may range from 800-960° C. depending on the size, density and quality of ACNTs.
5. As the temperature of the system reaches 800° C. the flow rate of Ar is reduced to desired flow rate (10-150 Sccm) and H₂ is introduced in the gas flow at a desired flow rate (10-150 Sccm). Allow 10 minutes for the gases to mix uniformly inside the reactor.
6. The gas flow is maintained steady through out the growth process.
7. Pyrolysis of the Precursor: Once the furnace attains constant set temperature, the precursor boat is transferred in the temperature range (450-750° C.) where the pyrolysis of the organo-metallic precursor is triggered. Iron and carbon source is released into the gas phase and gets carried into the flow stream by Ar and H₂. (30 sec-2 min)
8. The carrier gas transports the metal/carbon into the high temperature zone where the growth of carbon nanotubes on the substrate takes place. (2-10 min)
9. After the reaction time, the furnace is shut-off, the H₂ flow is turned off, and only Ar gas flow is maintained steady at a low flow rate (300-500 Sccm).

10. Once the furnace temperature reaches a safe value and all the H₂ is flushed out of the reactor system, the quartz tube is opened and exposed to air.

The substrate is taken out of the tube and further examination is carried out (SEM/TEM).

### Encapsulation of Catalyst at the Base of the MWNTs

This example provides a fabrication process to insulate mainly the catalyst at the base of the carbon nanotubes, without insulating the tip or the wall (e.g., mid-section) of the tubes. Such insulation allows electrochemical response of carbon nanotubes with the sample solution while preventing undesirable electrochemical interaction of the catalyst with the solution. The insulation material also provides additional mechanical support for carbon nanotubes when the nanotubes are exposed to harsh environment such as high flow.

The MWNTs make an ideal electrode candidate for electrochemical detection. Nanotubes can be grown on catalyst such as nickel, iron, and lead. During electrochemical analysis, the catalyst can also be exposed to the solution thus exhibit electrochemical response. In order to prevent such undesirable electrochemical response, the catalyst can be insulated. This example provides a fabrication method of depositing silicon nitride as an insulating material for ion sensing application. This example also provides a fabrication method of depositing an insulating material covering nanotube structures where the insulating material is patterned by partial exposure of a positive photoresist. Also described is fabrication method for preventing nanotubes from forming honey-comb structure arising from stiction by supercritical point carbon dioxide drying method.

The processes in this example start with a 100 mm silicon wafer (FIG. 17A) with aligned carbon nanotube film. This process can also be applicable to other substrates such as glass wafers. Next, a 500A thick silicon nitride (FIG. 17B) is deposited by plasma-enhanced chemical vapor deposition at 380C acting as an insulating material. Other insulating material such as silicon oxide can also be used. Deposition method is not limited to evaporation, sputtering, thermal, hot wired deposition. In this application, silicon nitride is used because it effectively stops ionic molecules in contact with the nanotubes. After that, a positive photoresist (AZ9260) is spin-coated (2K rpm, 20 sec) and soft baked (115C, 260 sec, hot plated) covering the entirety of the nanotubes (FIG. 17C). The photoresist undergoes partial ultra-violet exposure (300 mW/cm2, 4 sec) (FIG. 17D), such that some photoresist is left after development (AZ400:DI H20: 1:3, 2.5 min) covering the lower portion of the nanotubes, while the upper portion of the silicon-nitride covered nanotubes are exposed. After development of photoresist, the sample might be undergoing supercritical point carbon dioxide drying to prevent nanotubes from sticking to each other forming honey-comb structures due to capillary-induced stiction. Subsequently, the sample (FIG. 17E) is exposed to wet etching such as buffered hydrofluoric acid (2 min) to etch away exposed silicon nitride residing on the sheath of the tubes. Finally phororsist (FIG. 17F) is removed by soaking in acetone or other solvents for a short time. The sample might again undergo supercritical point carbon dioxide drying to prevent nanotubes from sticking to each other forming honey-com structures due to capillary-induced stiction.

### Doping of MWNTs by Supercritical Treatment

In these examples, the gas like behavior of supercritical CO₂ is used to spread out along a surface more easily than a true liquid, while maintaining the dissolving property of a liquid. The supercritical CO₂ transports and encapsulates the molecules/compounds of interest into nanoscopic cavities like that of a hollow nanotube. Successful encapsulation of interesting molecules/compounds into nanotube cavities would give rise to ‘peapod’ like structures. The discussion that follows provides details of experiments carried out in supercritical medium with ACNTs, SWNTs and a target molecule of interest, which has a specific electrochemical signal. The characterization shows that we were able to dope the carbon nanotubes with the target molecule, both inside the hollow core and on the outer walls, while maintaining the electro activity of the molecule.

A critical point dryer is an instrument for drying materials/samples using a supercritical carbon dioxide (CO₂) medium. Carbon dioxide is known to form a very clean and inert supercritical fluid, which achieves super criticality at 31° C. and a pressure about 1070 psi.

Procedure—Condition 1: Substrate/Sample: ACNT film (Solid Precursor CVD), SWNT (commercial sample).

Target molecule: {6}-1-(3-(2-thienylethoxycarbonyl)-propyl)-{5}-1-phenyl-[5,6]-C61. (64BFA)

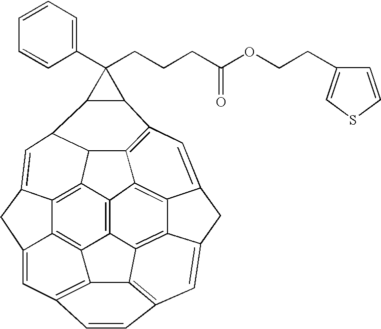

Solvent: Carbon Disulfide (CS₂)

Temperature: 80° C.

Pressure: 2000 psi

Time: 2 days

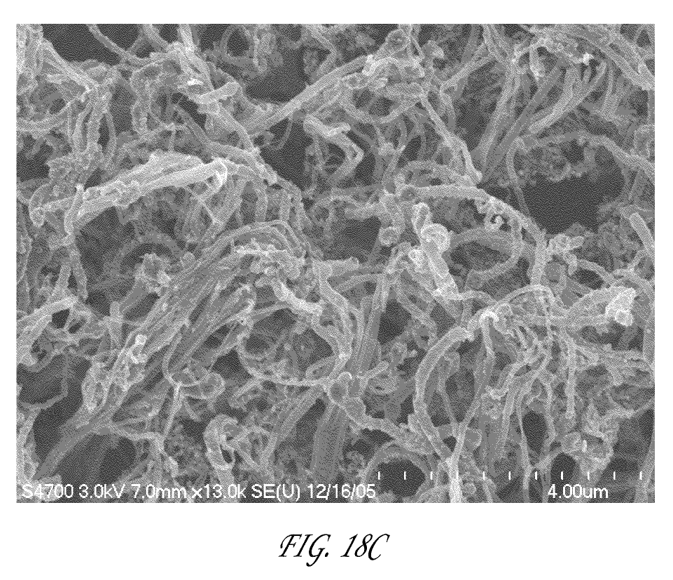

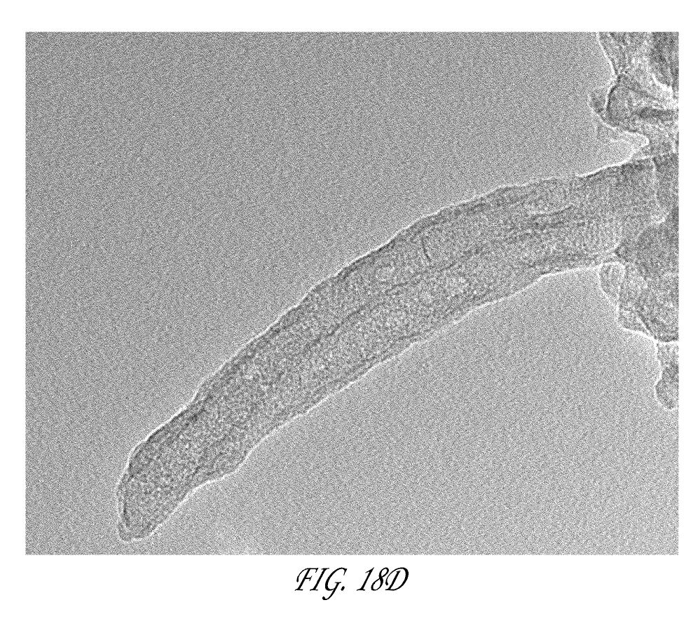

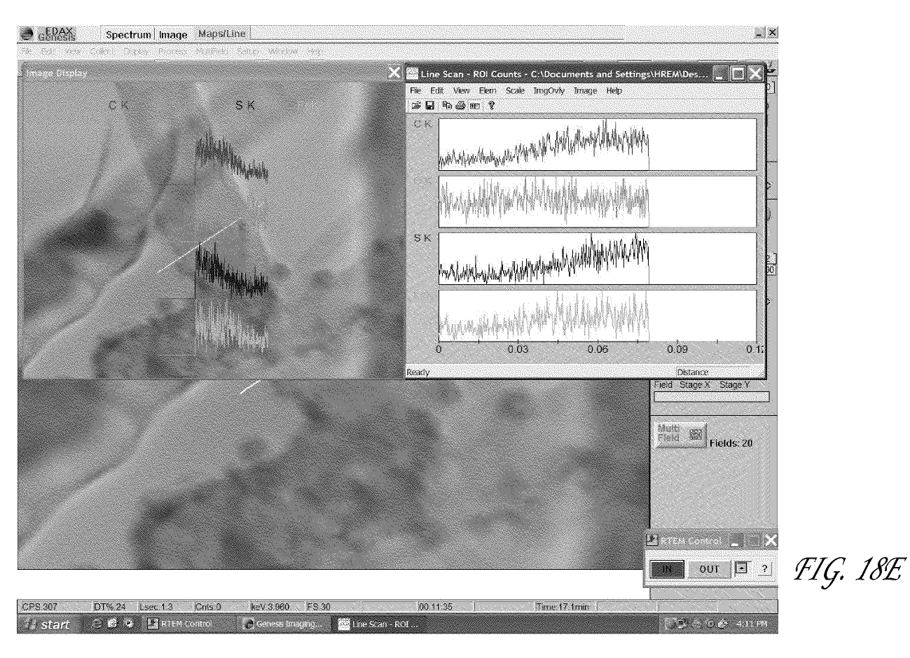

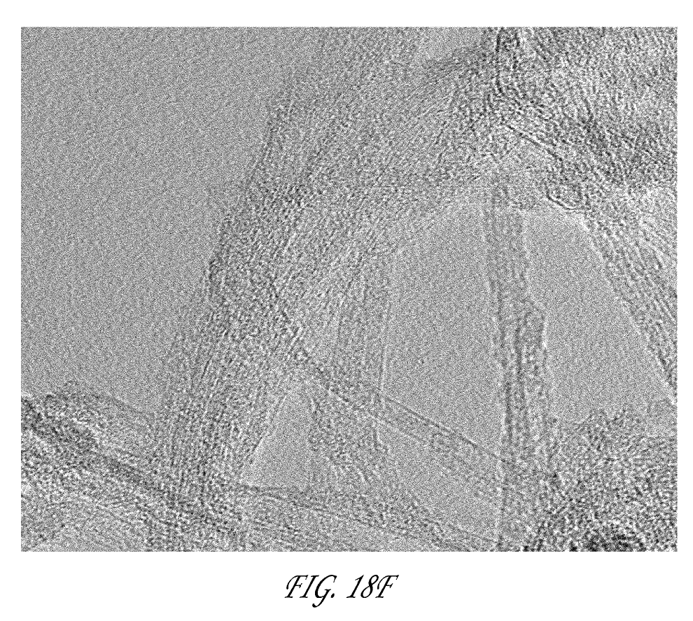

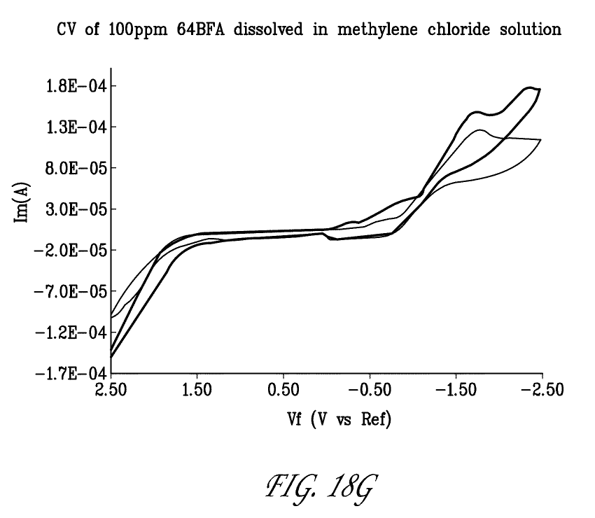

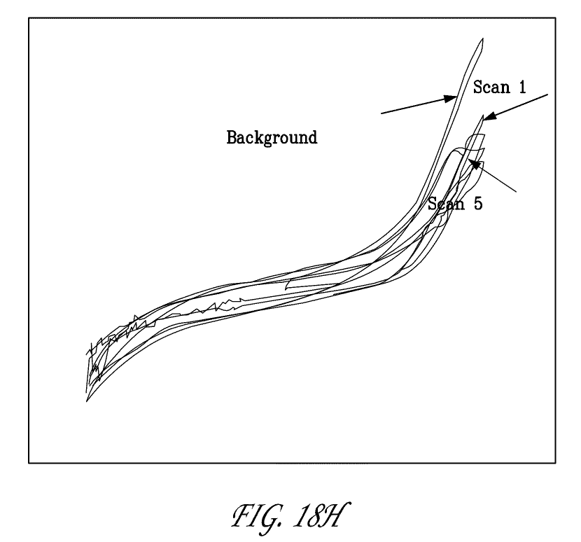

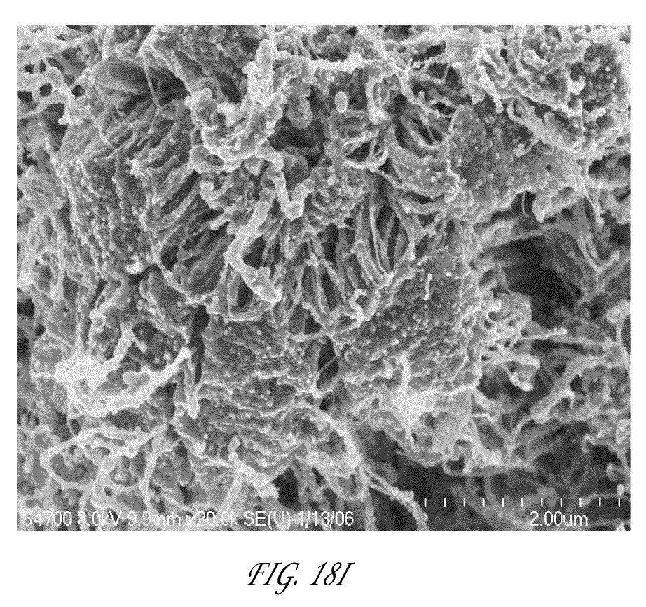

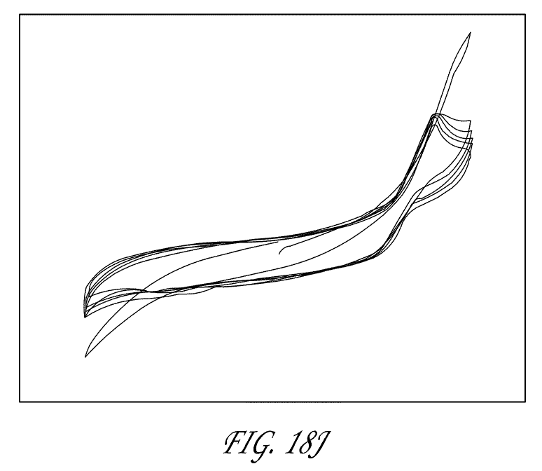

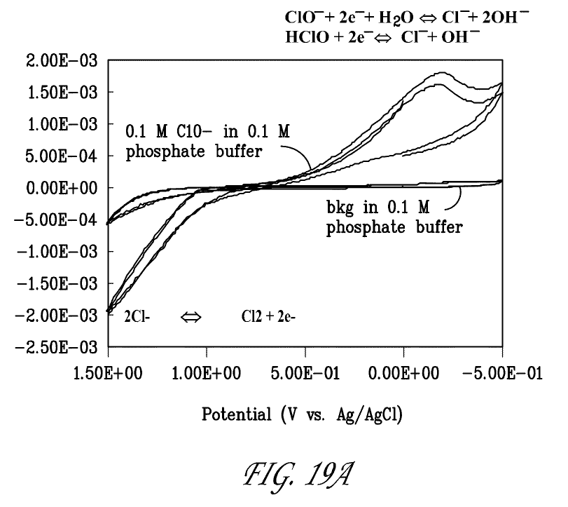

Characterization: The ACNT film and SWNT powder were air oxidized (conditions in lab book) prior to any treatment, in order to create defects (holes) on the walls of the CNTs. They were characterized with SEM and TEM (FIG. 18A) before the supercritical treatment with Condition 1. The electrochemical behavior of the ACNT film was also recorder prior to the treatment.

After the supercritical treatment, the samples were thoroughly washed with CS₂ and MeOH and prepared for further characterization. The treated ACNT film was examined in the SEM and it was evident that there is a coating on the nanotube surface. The TEM evaluation shows that there is a definite coat in/around the carbon nanotubes. To confirm that the target molecule is not only present on the surface of the nanotubes, but also inside the hollow core of the tubes, (energy dispersive X-ray) EDX was performed. From FIG. 18E, it is evident that there is an increase in the levels of carbon and sulfur (indicative of the target molecule) in the centre of the tube.

The SWNT powder sample was characterized with high resolution TEM, where in the presence of fullerene like molecule structure are visible (FIG. 18F).

After the verification that target molecule moieties are present in the core of the nanotubes, the ACNT sample film was characterized electrochemically to check for the specific target molecules. The CVs exhibit specific target molecule signal (FIG. 18G, 18H) providing proof that the molecule is electrochemically active even after the treatment.

As shown in FIG. 18 (G, H) it is evident from the signature peak observed at ˜−1.5V that the target molecule 64BFA is present and electrochemically active on the ACNT film after the supercritical treatment.

Condition 2: Substrate/Sample: ACNT film (Solid Precursor CVD)
Target molecule: {6}-1-(3-(2-thienylethoxycarbonyl)-propyl)-{5}-1-phenyl-[5,6]-C61. (64BFA)
Solvent: Carbon Disulfide (CS₂)
Temperature: 40° C.
Pressure: 1200 psi
Time: 5 hrs

ACNT film was treated with Condition 2, in different Critical Point Dryer instrument, which had limited temp and press range. The treatment was carried out with the same target molecule as in Condition 1. The film was air oxidized (550° C. for 30 sec) prior to any treatment. Supercritical treatment (Condition 2) was carried out in the Bio imaging Lab facilities (DBI). The ACNT sample after treatment was thoroughly rinsed with CS₂ and MeOH solvents, to remove any loosely attached compounds. The SEM characterization (FIG. 18I) showed coating on the surface of the nanotubes (Similar to that observed with Condition 1 samples).

The electrochemical response of the film after the treatment was also recorded. It was observed that the target molecule specific signals are present and that the compound is electro-active. (Ref FIG. 18(G) for signature electrochemical signal for the target molecule in solution)

### Amperometric Reduction of Free Chlorine at Carbon Nanotube Films

When either chlorine gas (Cl₂), hypochlorite solution (NaOCl), or solid Ca(OCl)₂ are added to water (for water disinfection), the following reactions take place
Cl₂+H₂O→HOCl+H⁺+Cl⁻
OCl⁻+H₂O→HOCl+OH⁻

The reduction reaction of the hypochlorite ion at the electrode in aqueous solutions can be described as: ClO⁻+2e⁻+H₂O [symbol] Cl⁻+2OH⁻

Carbon nanotube electrodes (CNTs) are designed to be electrochemically robust to strong oxidizing agents such as the oxoacids of chlorine. In these examples, CNTs were used as working electrodes for the analysis of free chlorine in aqueous solutions using the reduction reaction of free chlorine described above.

The amperometric reduction of ClO— was conducted at 0 V for 5 s. The resulting charge under the i-t curve was used for quantitation.

A single compartment three electrode glass cell was used. The planar CNT working electrode was pressed against a viton o-ring and clamped to the bottom of the cell. A graphite rod was used as the counter electrode and a commercial Ag/AgCl (BAS systems) served as a reference electrode (E⁰ Ag/AgCl=0.034 V Vs calomel). The geometric area of the working electrode was ca. 0.2 cm². All measurements were performed at room temperature ˜25° C.

Chemicals. Phosphate buffer was prepared by mixing appropriate volumes of solutions of 0.05 M sodium phosphate dibasic and 0.05 M sodium phosphate monobasic (Sigma-Aldrich) to yield the desired pH (usually pH 7). Chlorine solutions were initially prepared from a stock of 5% w/w hypochlorous acid (EMD chemicals Inc.). This “bleach”solution was found to be unstable in spite of being stored at 4° C. and there was ambiguity as to its exact concentration. Henceforth, Free Chlorine Standard (Hach Voluette, catalog no. 14268) was used as the stock solution of the hypochlorous acid (initial concentration of HOCl=79.3 ppm or 61.9 ppm). These stock solutions had been commercially prepared by generating and dissolving chlorine gas in slightly alkaline, high purity water of zero chlorine demand. All solutions were prepared in glassware treated to make them chlorine demand free.

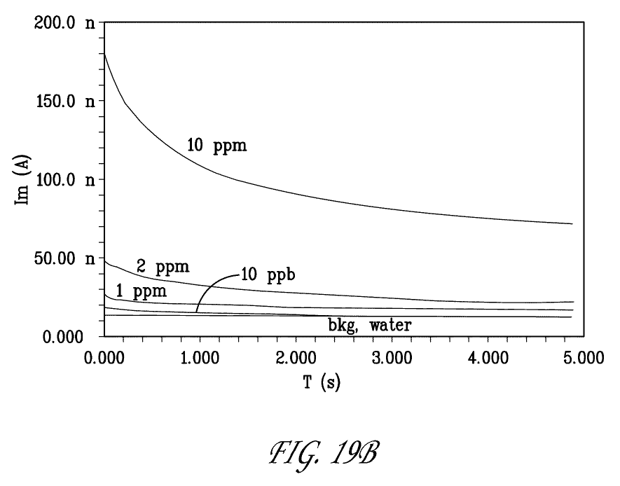

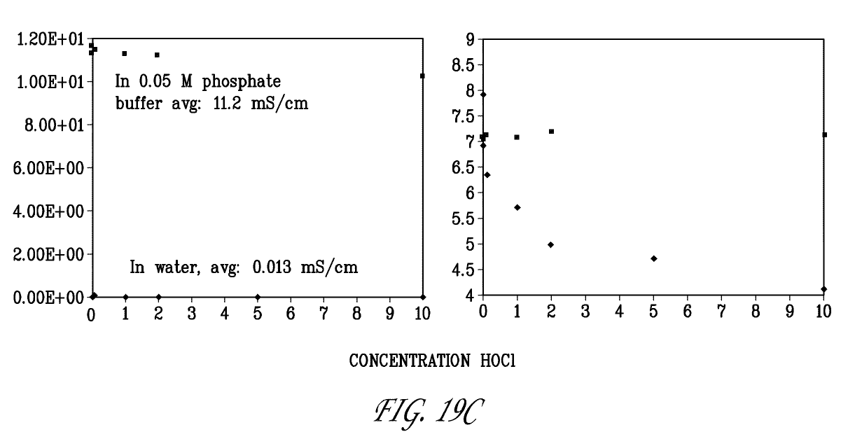

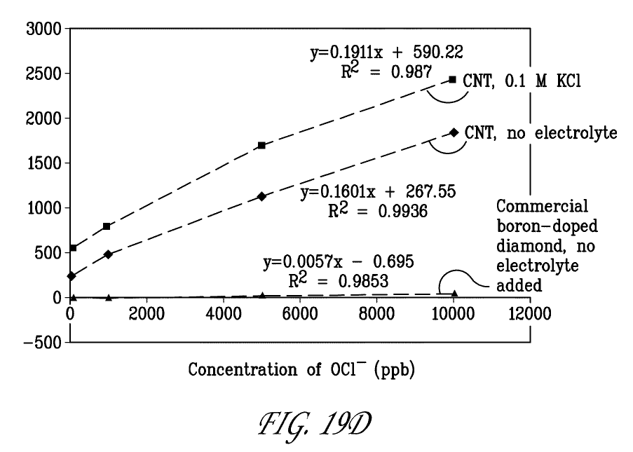

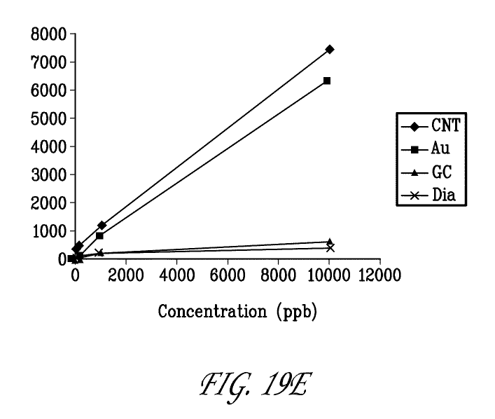

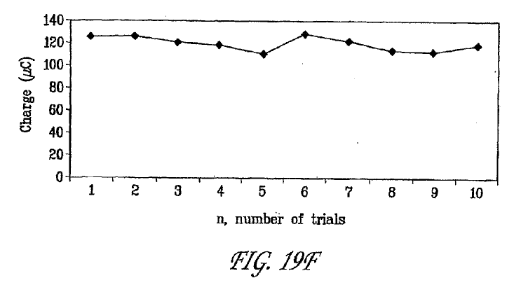

FIG. 19A shows the i-E curves for the electrolysis of 0.1 M ClO⁻ in 0.1 M phosphate buffer (pH 6.8) and for the phosphate buffer by itself. The oxidation peak observed is for the chlorine evolution reaction which shows an onset potential of about 900 mV at the CNT electrodes.

The cathodic charge observed in the potential range from 0 mV to −500 mV is due to the reduction of the hypochlorite ion/hypochlorous acid species according to the listed equations.

FIG. 19B shows typical amperometric reduction curves obtained for the reduction of the free chlorine species in water (solid-phase grown CNT, 0.11 cm² inner area of o-ring). These curves are for solution concentrations of chlorine ranging from 10 ppb to 10 ppm. Plots of the resulting charge under the curves versus the solution concentration of chlorine are linear (R²=0.9888 in this case).

The current vs. t^{-1/2} plots also showed a linear relationship, indicating a semi-infinite linear diffusion of the chlorine species to CNT electrodes.

The pH of the solution determines the relative proportions of hypochlorous acid (HOCl) and hypochlorite ion (OCl⁻). At 0° C. and pH 7.9, chlorine is present as half active HOCl and half inactive OCl⁻. The dissociation reactions of chlorine dissolved in water can be written as follows:
Cl₂+H₂O→H⁺Cl⁻+HOCl pKₐ=4.6 at 25° C.
HOCl→H⁺+ClO⁻ pK₂=7.5 at 25° C.

FIG. 19C demonstrates the conductivity and pH trends for solutions of dissolved chlorine.

FIG. 19D demonstrates the effect of electrolyte on the response for the reduction of the hypochlorite ion on CNTs in comparison with a commercial sample of conducting diamond (a model planar electrode). Plots of resultant hypochlorite reduction charge Vs. its solution concentration are presented. CNTs are expected to have a minimum internal iR drop due to their small sizes and good electrical conductivity. Indeed, the ratio of the sensitivities of response with no added electrolyte was CNT:Diamond 28.5.

Based on these experiments, one can carry out the free chlorine reduction assay on CNT electrodes without addition of electrolyte.

FIG. 19E shows the CNT comparison plot of resultant hypochlorite reduction charge Vs. its solution concentration using different electrode surfaces such as diamond, glassy carbon (GC) and gold. The R² values were found to be CNT: 0.9997, Au: 0.9996, GC: 0.9853 and conducting diamond: 0.9263. It was found that the sensitivities were highest for CNTs followed by Au, GC and diamond in that order.

FIG. 19F gives an example of the repeatability of the response of the free chlorine reduction reaction on CNTs. Here, the plot of trial number (n) versus the resultant charge for the same concentration of hypochlorite (100 ppb ClO— in 0.05 M phosphate buffer) is shown.

The Coefficient of Variation (%) of a set of values is calculated as: 100*(Standard Deviation)/(mean value of set). In this case the coefficient of variation was found to be 5.25% which is in an acceptable range.

CNT based sensors for free chlorine have been demonstrated in these examples to provide superior sensitivity as compared to conventionally used electrode materials such as diamond, gold and glassy carbon. The response is precise and the linear dynamic range spans 4-5 orders of magnitude. Assays without the addition of supporting electrolyte are also analytically useful.

### Potentiometric Measurement of Calcium Based On a Conducting Polymer Cladded MWNT Structure

Ion-selective electrodes are electrochemical sensors that measure a wide range of analytes in aqueous solutions. A solid-contact calcium selective electrode is described that is based on a calcium ionophore doped conducting polymer CNT cladding. The analytical performance of this sensor (potentiometric) was evaluated. When the ionophore doped CNT electrode was in contact with an aqueous solution containing calcium, an electrode potential develops across the surface which is dependent on the level of free calcium ion.

The electrochemical cell consisted of ion selective and reference electrodes. The potential difference between the cladded CNT (ion selective) and reference electrode (Silver/Silver chloride) was measured with a commercial pH/mV meter. All the measurements were carried out in Tris buffer (pH 7.2), and at room temperature (˜25 C). The potential readings were taken after stabilization for 1 minute.

Chemicals: 0.05 M Tris Hydroxy methyl amino methane (Fisher, N.J.) buffer (pH 7.2) was used for all the potentiometric measurements. 10⁻¹-10⁻⁵ M Calcium chloride (Sigma, Mo.) solutions were prepared from 0.1 M CaCl₂ stock solution in Tris buffer. Polyaniline (PANI) emeraldine base powder, Di(2-ethylhexyl)phosphate (H+DEHP⁻) and Potassium tetrakis(4-chlorophenyl)borate KB(ClPh)₄ were purchased from Sigma. Calcium ionophore (ETH 1001) was obtained from EMD Biosciences. All the aqueous solutions were prepared using deionized water.

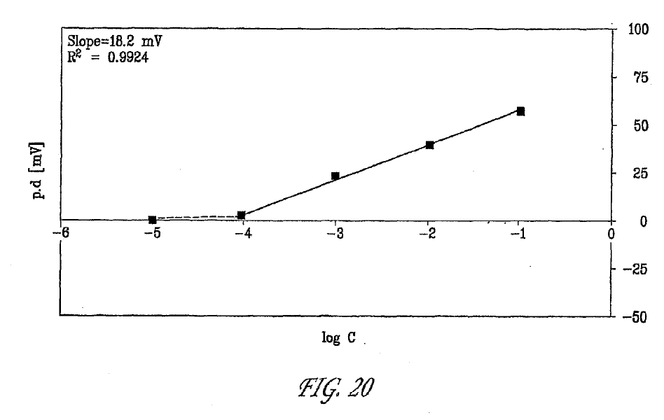

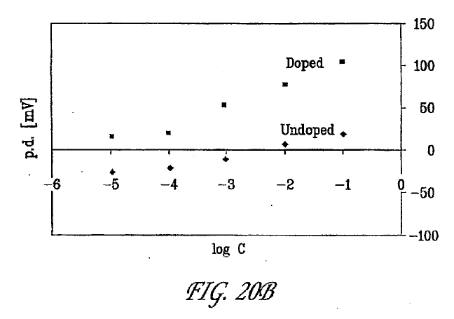

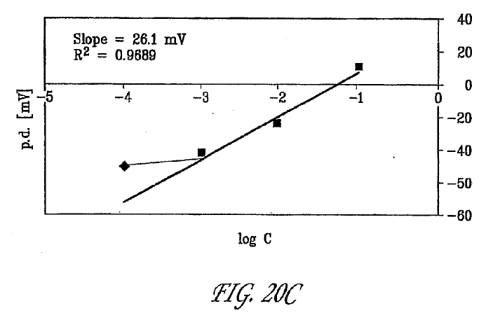

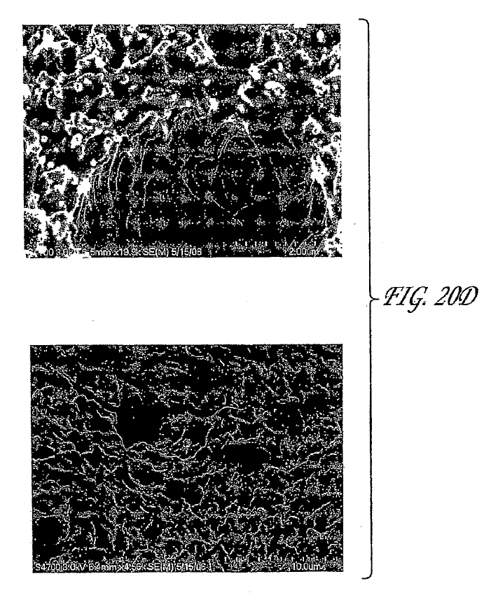

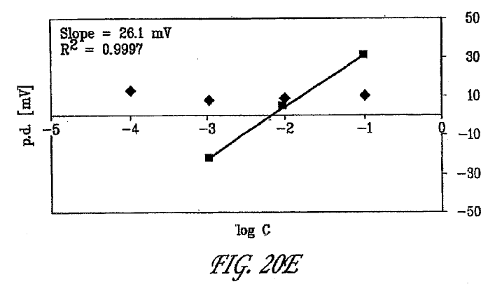

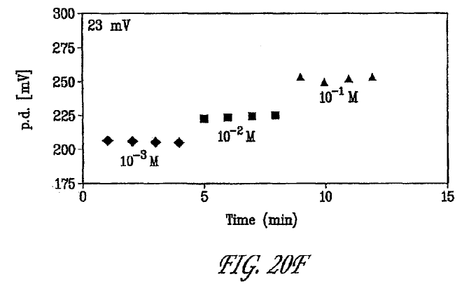

Referring to FIGS. 20A and 20B, the electrode showed Nernstian response toward calcium with a slope of 18.2 mV (ideal theoretical Nernstian slope is 29.5 mV). The undoped PANI film showed a concentration dependent ionic response. To account for this, the potential difference values at each concentration were corrected for the calcium response of the doped PANI electrode. Linear response ranges from 10⁻⁴ to 0.1 M Ca²⁺. The response is similar to a conventional PVC membrane matrix cast on a conducting polymer cladded CNT electrode. Thus, the conducting polymer by itself can act as a matrix and demonstrate a stable response. Measuring the PANI film with the calcium ionophore, gave rise to the slope of the graph being drastically improved. An overlay of the response curve for the doped and undoped PANI electrode is shown in FIG. 20B.

Referring to FIG. 20C, the electrode showed Nernstian response toward calcium with a slope of 26.1 mV. Linear response ranges from 10⁻³ to 0.1 M Ca²⁺. There is an order of magnitude difference in the detection limit with tap water (10⁻³ M). The redox and pH sensitivity of the PANI limits the performance of the sensor. The conductivity of polyaniline is known to be strongly affected by the oxidation state as well as the degree of protonation.

Interference Studies. Selectivity studies of the Calcium selective electrode were carried out with respect to K⁺, Na⁺ and Mg²⁺ respectively. Mg²⁺ is the major cation that causes measurement errors in water sensing devices. Both Ca²⁺ and Mg²⁺ contribute to the total hardness of water. In regard to measuring water total hardness, interference from Mg²⁺ apparently does not alter the sensor performance.

Results. CNT based sensors provide robust, portable, simple, and relatively inexpensive methods of analysis. Polymer cladded CNTs can provide miniaturized electrochemical sensors.

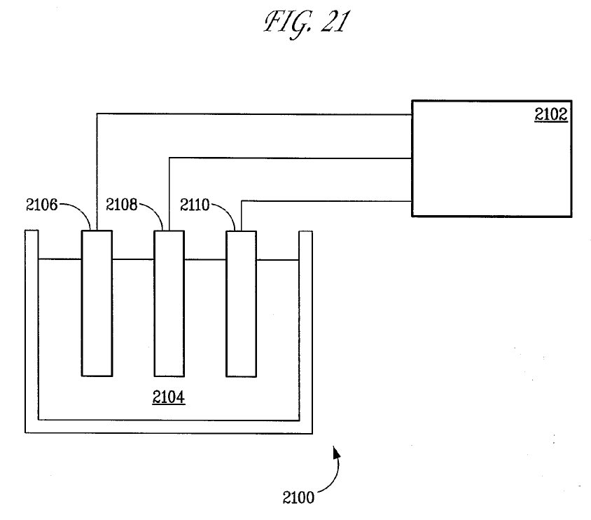

Measurement of residual chlorine concentration using a diamond working electrode. An apparatus having the general configuration depicted in FIG. 21 may be used to measure chlorine concentration in solution via amperometry. Methods of measuring chlorine concentration are known, for example see published U.S. Patent Application 2007/0114137 to Nomura et al., the entirety of which is incorporated by reference herein. Accordingly, a suitable residual chlorine measuring method includes the steps of bringing a counter electrode, a working electrode and a reference electrode into contact with a sample solution containing a residual chlorine. A voltage between the counter electrode and the working electrode is applied and a current value is measured to calculate a concentration of the residual chlorine. The working electrode can be comprised of an electrically conductive diamond to which an element selected from a group of boron, nitrogen and phosphorus is doped into a diamond coating. The reference electrode is a silver/silver chloride electrode. A current value, when setting the potential of the electrically conductive diamond electrode to the silver/silver chloride electrode, is in the range of +0.5 V to +1.5 V for measurements. The working electrode can comprise diamond, for example, it may be diamond coated. Suitable working electrodes may be a DIACHEM electrode, with both sides coated, available from Condias GMBH of Fraunhofer Str. 1B, Itzehoe, Germany. The diamond electrodes can also be manufactured on the microscale or nanoscale, for example using chemical vapor deposition methods known in the art of CVD diamond coatings. The diamond coatings can also be combined with the CNT electrode devices described elsewhere herein.

Without being bound by any theory of operation, it is believed that while a diamond electrode is still not immune to oxidation, diamond oxidation is confined to the surface and does not produce any morphological or micro-structural damage to the diamond electrode due to the strong three-dimensional bonding and high atomic density of diamond. The physicochemical properties of the diamond surface may be described by its voltammetric response. In the potential range from about +0.8V to about −0.4V vs Ag/AgCl, the voltammetric response is flat and featureless. Because of its low background current density and wide working potential window, diamond is a useful electrode for electrochemical analysis.

Through operation of the apparatus depicted in FIG. 21, amperometric residual chlorine measurement may be made wherein the applied potential across the diamond working electrode and silver/silver chloride reference electrode ranges from about +0.5V to about −1V. At this potential range, the diamond is not susceptible to oxygen interference.

Certain methods for measuring residual chlorine concentration using an amperometric method may include bringing a counter electrode, a working electrode and a reference electrode into contact with a sample solution containing residual chlorine. Applying a voltage between the working electrode and reference electrode, the current generated by reduction of residual chlorine on the working electrode is measured. The working electrode may be electrically conductive diamond electrode in which a doping element, such as one selected from a group comprising boron, nitrogen and phosphorus may be doped into the diamond electrode. Other diamond doping elements known in the art may be used. The potential applied across the diamond working electrode and silver/silver chloride reference electrode typically ranges from about +0.5V to about −1V.

Suitable diamond electrodes typically have a thickness in the range of from about 500 nm to about 50 microns, or from about 1 micron to about 20 microns, or from about 2 microns to about 10 microns, or from about 4 microns to about 8 microns, or even about 5 microns thick. Suitable substrates for diamond electrodes include niobium, Si, SiC, graphite, tantalum, tungsten, or any combination thereof.

Undoped CNT-based Electrode Device for Electrochemical Sensing. Electrochemical sensors can be fabricated using electrodes composed of undoped carbon nanotube(s). The electrochemical sensors are rugged in use, chemically stable and readily manufactured. These undoped carbon nanotube(s) can be either single wall or multi-wall. Suitable electrodes can be adapted for use in medical testing of biological fluids, in testing the safety of pharmaceuticals, beverages and food, as well as for use in testing potable water.

Without being bound to a particular theory of operation, the CNT electrode-based sensors are particularly well-suited for use in strong oxidants because of the high chemical resistance of CNTs. In electrochemical terms, the CNTs surface chemistry is essentially unaffected by chlorine in the presence or absence of electrolysis. This is characteristically unlike noble metal electrodes in which the surface can be oxidized or electrolytically altered. This property allows for a broad operating voltage window for measuring electro-active molecules in water using various embodiments of the CNT-based sensors of the present invention. CNT working electrodes operating in the electrolytic measurement mode do not necessarily require coatings or dopants to effect selective measurement.

Table III describes undoped CNT arrays measuring target analytes such as HClO, O₂, R—NH—Cl, ClO₂, HCO—Cl, and Cl—CH₂—CO. An example of a normal drinking water test combination of free and total chlorine and water hardness would deploy the following sensors: CNT-gated FET for calcium, a CNT working electrode for free chlorine and a doped/cladded CNT peapod working electrode-photodiode combination for tot-Cl₂ modulated electro-chemiluminescence.

Undoped CNT Device Non-aligned/Aligned for Electrochemical Sensing. Undoped aligned CNT antenna assembly electrodes can have an electrically conductive layer at least partially surmounting a substrate and an assembly of undoped antennae vertically oriented with respect to the electrically conductive layer. Each of the undoped antennae may comprise an undoped CNT, in which each of the CNTs have a base end attached to the electrically conductive layer. The mid-section of the CNTs typically include an outer surface surrounding a lumen, wherein at least a portion of the outer surface of the mid-section is capable of being in fluidic contact with an environment in contact with the antennae. The CNTs also have a top end disposed opposite to the base end.

Undoped non-aligned CNT antenna assembly electrodes may also be comprised of an electrically conductive layer at least partially surmounting a substrate, which has an assembly of undoped antennae not vertically oriented with respect to the electrically conductive layer. In these electrodes in which the antennae are not vertically oriented, each of the undoped antennae may include a number of undoped CNTs. These undoped CNTs will each have a base end attached to the electrically conductive layer of the electrode. The CNTs also have a mid-section comprising an outer surface surrounding a lumen. At least a portion of the outer surface of the mid-section is capable of being in fluidic contact with an environment in contact with the antennae. The environment can be a suitable aqueous test specimen, such as water, for testing one or more components of the test specimen, such as free chlorine in water. The CNTs may further have a top end disposed opposite to the base end.

Non-aligned/Aligned CNTs for Electrodes. MWNTs can be grown on a substrate using any of a variety of methods set forth herein. For example, MWNTs can be grown by depositing a suitable metal catalyst, such as nickel, on a substrate and contacting the metal catalyst with a gas mixture comprising a carrier gas and a carbon source gas. Suitable process temperatures can be in the range of from about 600° C. to about 750° C. Suitable carbon source gases include acetylene and the like. Suitable substrates may include silicon, silicon dioxide, silicon nitride, phosphorus doped poly silicon, or boron doped P-type silicon. Exposure of the carbon source gas to the metal catalyst at the stated conditions give rise to non-aligned MWNTs attached to the metal catalyst.

Growth of Aligned/Non-Aligned Carbon Nanotubes by Gas Phase Chemical Vapor Deposition. Carbon nanotubes can be synthesized in a thermal CVD system using Argon (Ar), Ammonia (NH₃)/Hydrogen (H₂) as the carrier gas mixture and Acetylene (C₂H₂) as the carbon source. Gas Phase CVD growth has been successfully established on nickel metal catalyst and various substrates like Si, SiO₂, SiN, Poly Si (phosphorus doped) and P-type Si (boron doped). The tubes grown are either aligned or not aligned depending on the process conditions and substrate preparation. The diameter of these nanotubes range from about 10 nm to about 100 nm with thick walls and narrow cores. The growth conditions govern the synthesis of predominantly “bamboo type” structured tubes or mixture of bamboo and hollow tubes. This growth process is defined by the catalyst and can be readily transferred onto the patterned chip to yield clean and patterned carbon nanotube growth. Non-aligned CNTs can be readily grown on these substrates at temperatures in the range of from about 650° C. to about 750° C.; higher and lower process temperatures are possible too. Aligned CNTs can be grown by adding titanium (Ti) as the barrier layer in between the substrate (Si) and catalyst (Ni). Titanium with thickness in the range of from about 10 nm to about 100 nm can be deposited on the substrate prior to metal catalyst (e.g., nickel) deposition. The following paragraphs describe detailed experimental processes used to synthesize electrodes comprising CNTs in a thermal CVD system.

Substrate Pre-treatment. Annealing: Sample annealing at temperature range from 350° C. to 450° C. is used prior to CNTs growth. Sample is introduced inside the furnace and flushed with Ar gas (100-300 sccm) for 10 minutes. The exhaust of the reactor is attached to a vacuum source which creates 10 to 1 Torr pressure inside the reactor. O₂ gas in introduced in the chamber (20-60 sccm) along with Ar gas and chamber pressure is stabilized. The furnace is turned on and temperature is set between 350° C. and 450° C. It takes approximately 5 to 20 minutes for the furnace to reach the set temperature. Heating under vacuum is carried out for 3 to 18 hours. At the end of the annealing time the furnace power is turned off, O₂ flow is shut off and chamber is allowed to cool down until it reaches room temperature. The vacuum source is then cut-off and the system is purged with Ar. The system is opened and pre-treated substrate is ready for a CNT growth process.

CNTs growth processes by gas phase CVD. Annealed substrate is introduced inside the thermal CVD reactor. The CVD reactor is sealed and flushed with Ar gas (100 to 300 sccm) for 10 minutes. After sufficient purging, the furnace power is turned on and the system is heated under Ar atmosphere until the set temperature (650° C. to 750° C.). Once the growth temperature is reached, Ar gas flow rate is changed to the desired value which can range from 5 to 400 scan depending on the substrate combination used and quality of CNTs desired. Hydrogen/ammonia gas is introduced in the system at a flow rate ranging from 10 to 250 sccm. This process is carried out for 2 to 20 minutes to form nanometer-sized catalytic particles. After the etching step, acetylene as the carbon source is introduced into the chamber to grow CNTs. The growth time ranges from 2 to 60 minutes. After the growth time, acetylene is turned off while Ar gas is kept on to purge the chamber. Furnace is turned off and the sample is allowed to cool to room temperature in Ar (100-300 sccm) atmosphere. After cool down, the system is opened and sample is taken for further examination.

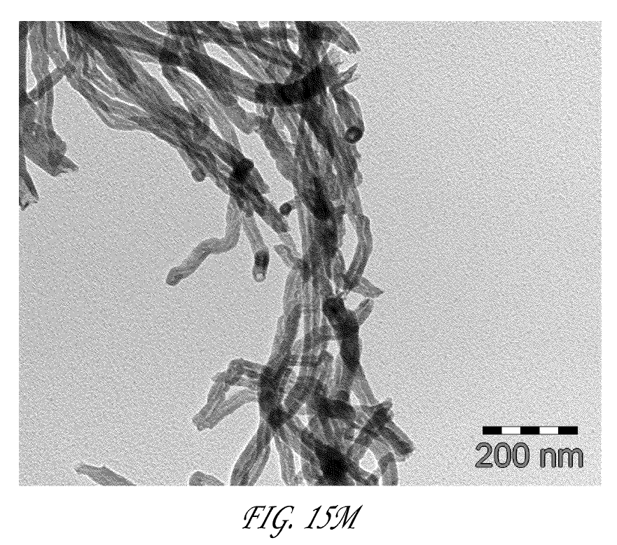

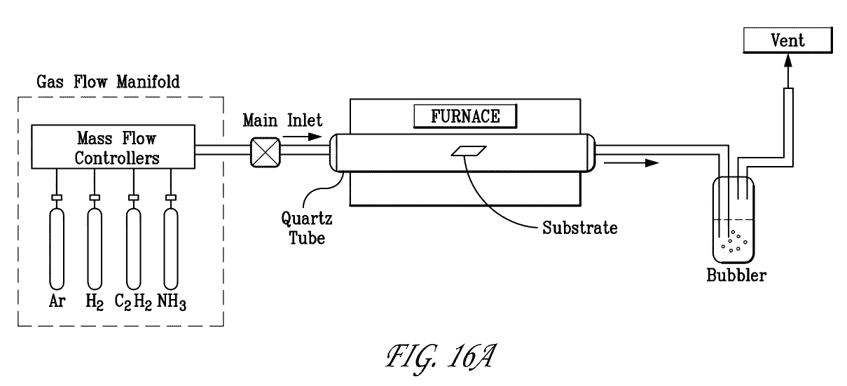

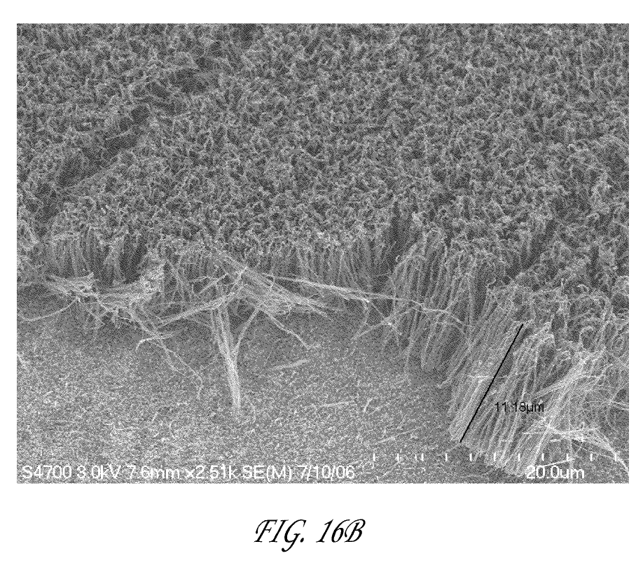

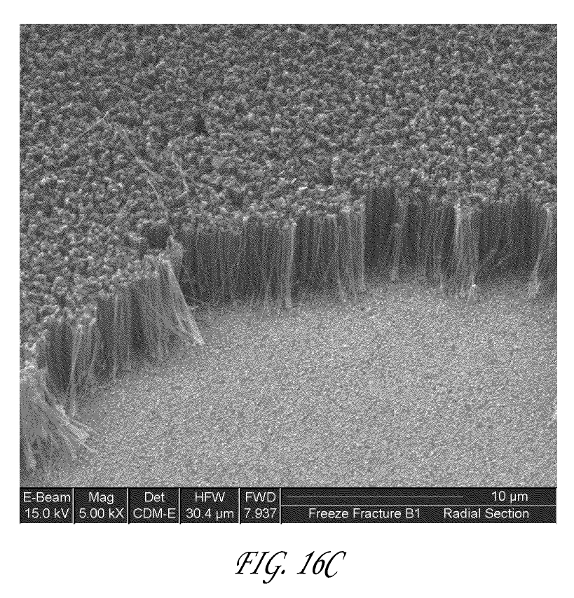

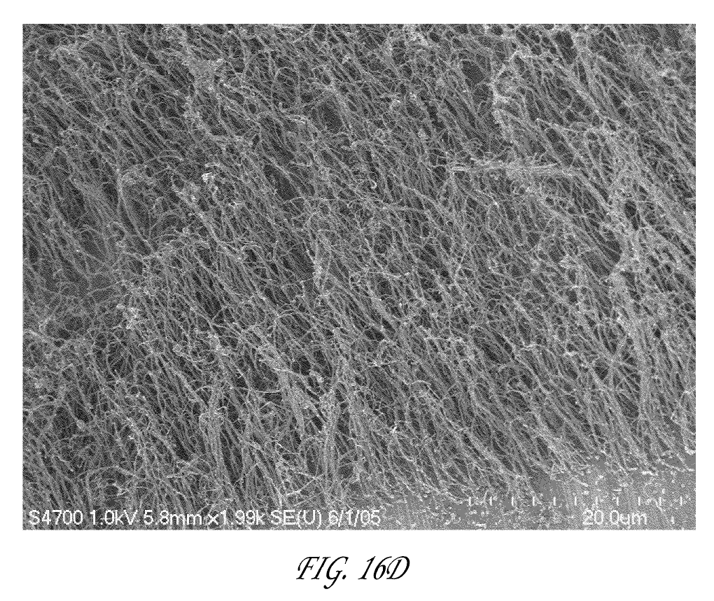

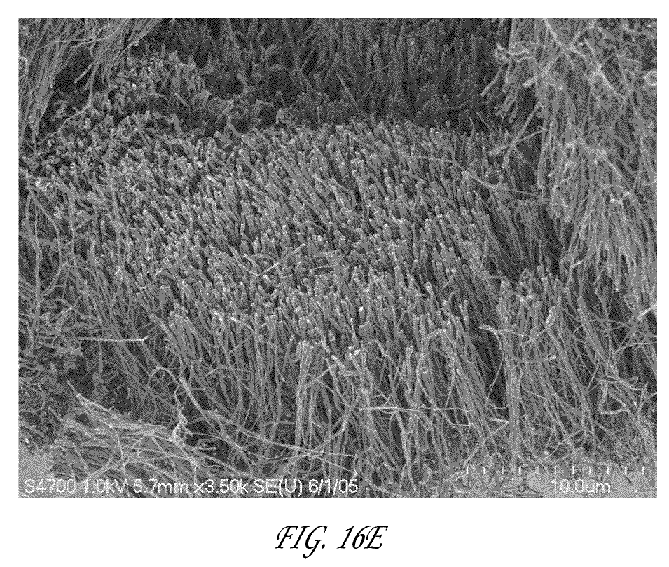

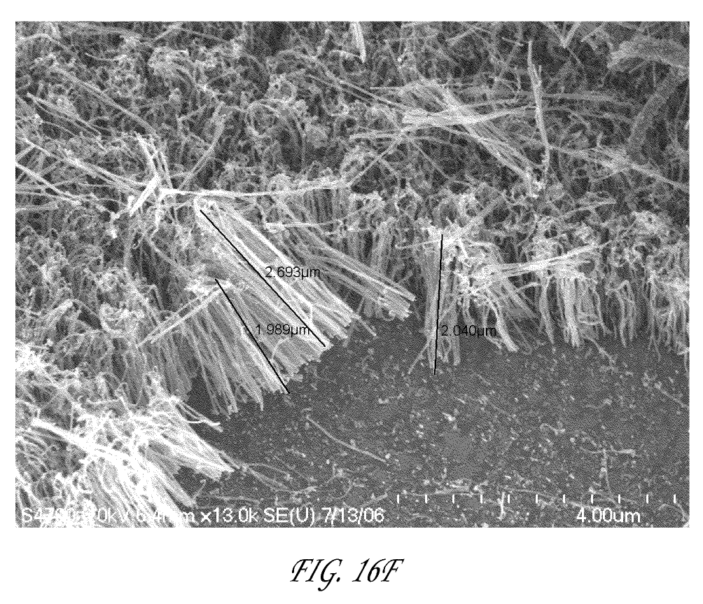

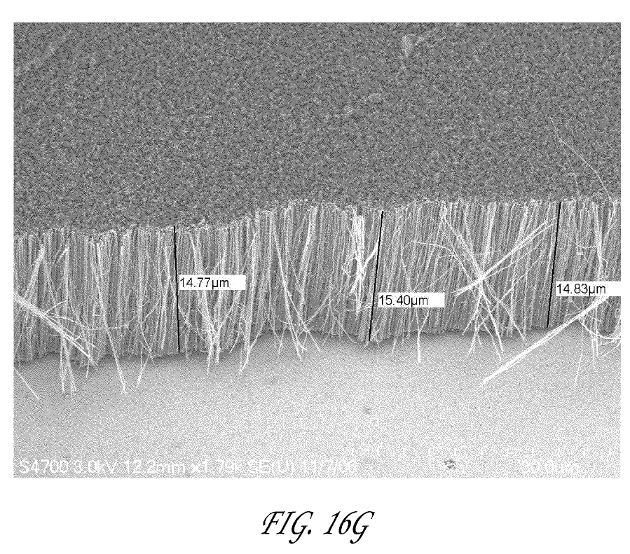

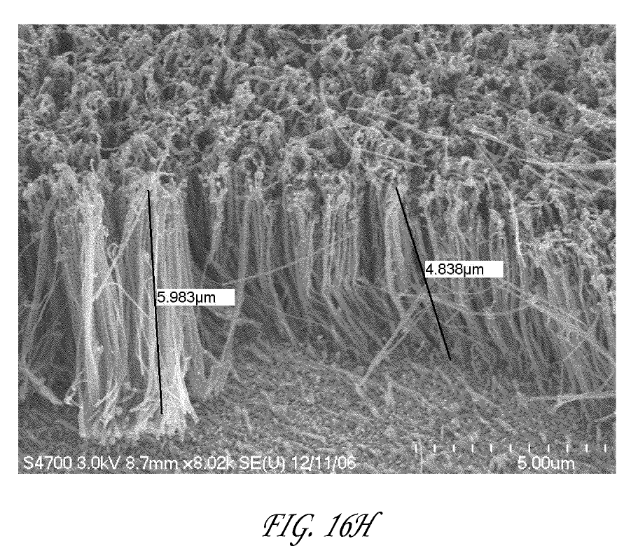

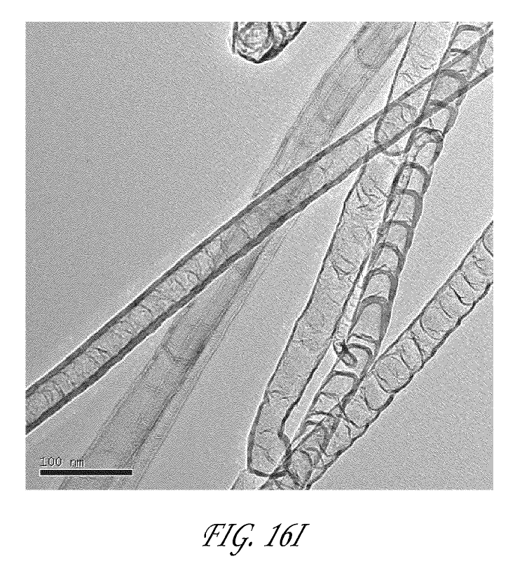

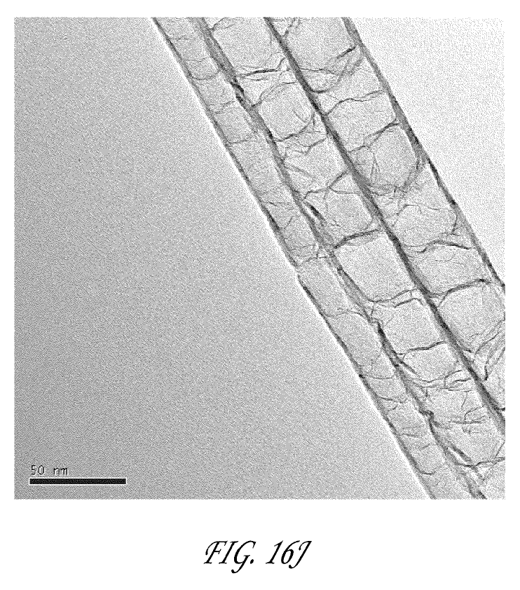

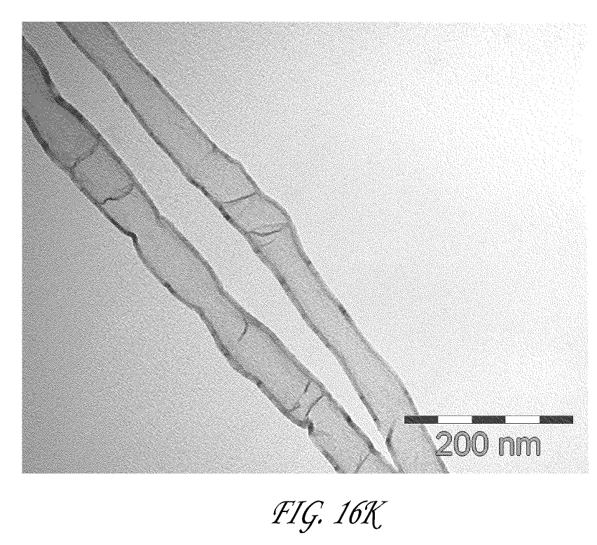

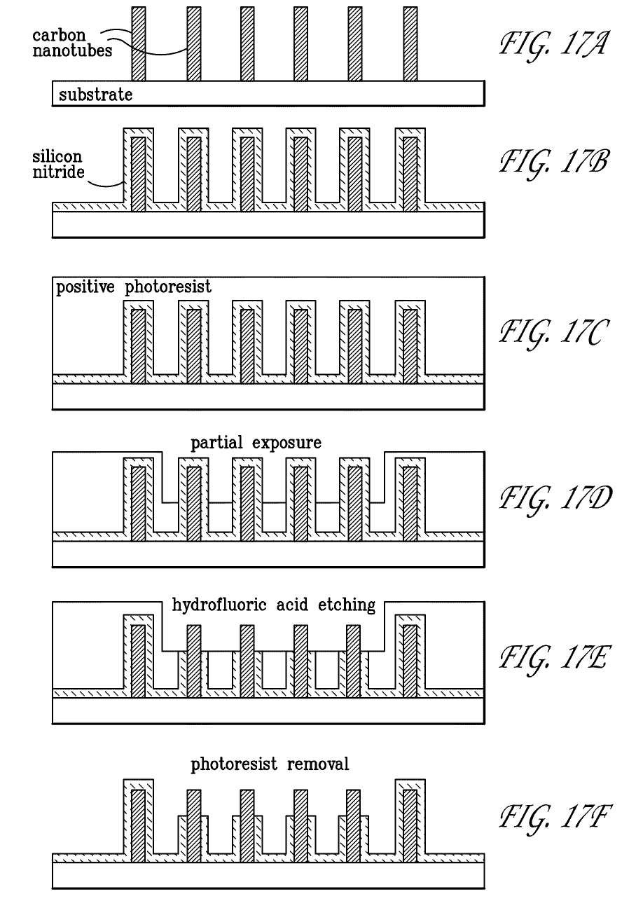

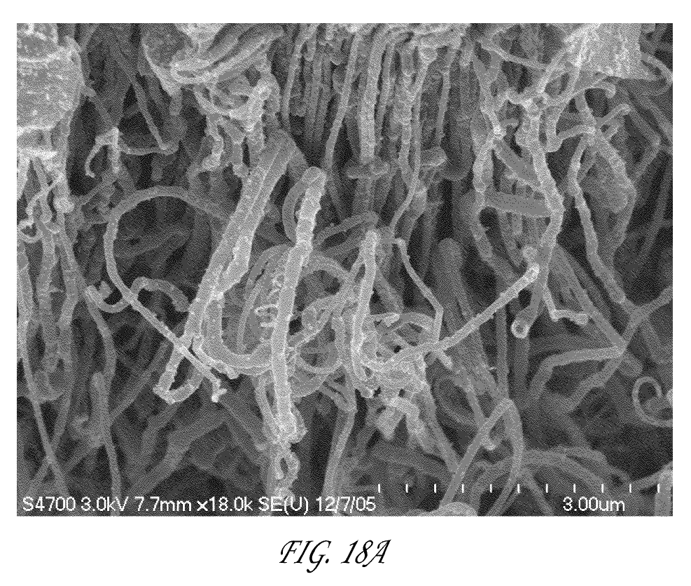

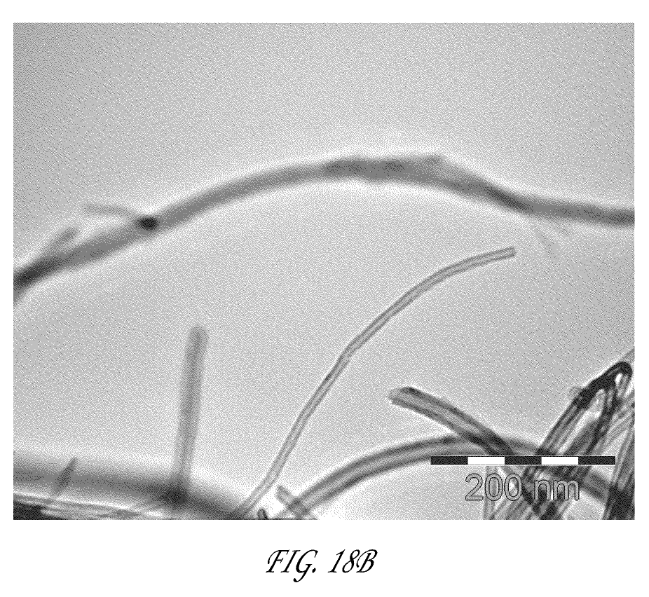

FIG. 15 illustrates patterned CNTs grown on 30 nm Ni on 50 nm Ti on Poly-silicon (patterned sample was annealed at 400° C. for 15 hours) with gas ratio of Ar/H₂/C₂H₂: 30/125/20 sccm at 745° C.

Plasma Enhanced CVD (PECVD), Patterned Growth Method: The MWNTs can be grown in a bell jar vacuum chamber at a base pressure of 10⁻³ Torr. Si/SiO₂ and Si/TiN substrates with Ni metallization patterns can be used for PECVD patterned CNT growth. The metal catalyst film thickness can be in the range of from about 2 nm to about 30 nm. The substrate is place in the vacuum chamber and evacuated to a pressure of abuot 10⁻³ Torr, at a temperature of about 600° C. Argon/ammonia/hydrogen or a combination of these gases can be introduced into the chamber to create optimum growth pressure 1-10 Torr at flow rates in the range of 50-200 sccm. A radio-frequency plasma generator is set in the range of 100-200 W, which is turned on for etching process anywhere from 5-30 mins. This is subsequently followed by introduction of acetylene gas at a nominal gas flow ratio (1:2-5) of acetylene to ammonia/hydrogen for CNT growth—at the same plasma power and chamber pressure. The growth reaction time can vary from 15 min to 2-3 hrs depending on the required length of MWNTs and growth is observed only where the metal catalyst particle resides.

Methods for measuring free chlorine in solution can apply a voltage between a working electrode and a reference electrode, and measuring the current on the working electrode corresponding to the concentration of free chlorine in solution, wherein the working electrode comprises carbon nanostructures. Suitable carbon nanostructures may comprise single wall carbon nanotubes, multi-wall carbon nanotubes, amorphous carbon, 2D-3D graphene structures, diamond, fullerites, fullerene molecules, buckyballs, carbon nano wires, carbon nano whiskers, carbon nano horns, carbon nano cones, carbon nano fibers, carbon nano ribbons, carbon nano spheres, carbon nano rods, carbon nano bowls, carbon nano onions, carbon nanotori, carbon nano buds, carbon peapod structures, or any combination thereof. In these methods, a third electrode, the counter electrode can be introduced to the electrochemical cell to ensure that current does not run through the reference electrode which would otherwise disturb the reference electrode potential. A suitable reference electrode comprises silver/silver chloride; other reference electrodes known in the art may also be used. The applied voltage is typically in the range of from about +1.5V to about −1V, although higher and lower voltages are contemplated as well. Other applied voltage ranges are also contemplated, for example the voltage can be in the range from about 0V to about −0.15V. The concentration of free chlorine can vary widely, but is typically in the range of from about 0 ppm to about 10 ppm. The working electrode typically comprises a surface area between that of a single carbon nanotube to about 10 cm².

In other embodiments, the working electrode may include non-aligned CNT antenna assembly electrodes. Suitable non-aligned CNT electrodes, as provided elsewhere, may comprise: an electrically conductive layer at least partially surmounting a substrate; and an assembly of undoped antennae non-aligned (e.g., not vertically oriented) with respect to the electrically conductive layer. In these electrodes each of the undoped antennae may comprise an undoped CNT having a base end attached to the electrically conductive layer, a mid-section comprising an outer surface surrounding a lumen, and a top end disposed opposite to the base end. At least a portion of the outer surface of the mid-section of the CNT is capable of being in fluidic contact with an environment in contact with the antennae.

Suitable working electrodes may include aligned CNTs antenna assembly electrodes. Such electrodes may have an electrically conductive layer at least partially surmounting a substrate, and an assembly of undoped antennae vertically oriented with respect to the electrically conductive layer. Each of the undoped antennae may be composed of undoped CNTs having a base end attached to the electrically conductive layer, a mid-section comprising an outer surface surrounding a lumen, and a top end disposed opposite to the base end. It is typically in this embodiment that at least a portion of the outer surface of the mid-section is capable of being in fluidic contact with an environment in contact with the antennae.

Suitable working electrodes may also comprise CNTs that are grown by any of a variety of methods. Suitable CNT growth methods include thermal chemical vapor deposition, arc discharge process, laser-ablation process, natural, incidental and controlled flame environments, plasma enhanced chemical vapor deposition, capacitively coupled microwave plasma process, a capacitively coupled electron cyclotron resonance process, a capacitively coupled radiofrequency process, an inductively coupled plasma process, a dc plasma assisted hot filament process, template synthesis or any combination thereof.

Working electrodes may also comprises CNTs that is grown on metal catalyst substance. The metal catalyst substance can be, but not limited to Ni, or Fe, or Co. The thickness of the catalyst ranges from sub nanometer (less than about 1 nm) to about several hundred nanometer (e.g., about 300 nm) thickness. The working electrode may also comprise CNTs of selected patterns. Suitable selected patterns include CNTs bundle together in arbitrary shapes including rectangle, square and circle, as well as arrays of selected patterns.

Methods of measuring electrochemically-active species in solution include the steps of applying a voltage between a working electrode and a reference electrode, and measuring the current on the working electrode corresponding to the concentration of electrochemically-active species in solution, wherein the working electrode comprises carbon nanostructures. Typical electrochemically-active species that can be measured include Potassium iodide, I−, N,N-diethyl-p-phenylenediamine (“DPD”), potassium ferrocyanide K₄Fe(CN)₆, ruthenium (II) bipyridyl complex [Ru(bpy)3]2+, ferrocene Fc, and any combination thereof. Suitable devices for measuring the concentration of electrochemically-active species in an aqueous solution can use an amperometric method may include bringing a counter electrode, a working electrode and a reference electrode into contact with a sample solution containing residual chlorine.

Devices for measuring residual chlorine concentration in an aqueous solution, can include a counter electrode, a working electrode comprising carbon nanostructures, and a reference electrode. Each one of the electrodes is capable of contacting an aqueous solution comprising residual chlorine, wherein the electrodes are capable of being in ionic communication with the aqueous solution. The working and reference electrodes are operatively coupled to give rise to a measurable current at the working electrode upon application of a voltage between the working electrode and the reference electrode. The counter electrode is operatively coupled with the working and reference electrodes to minimize electrical communication between the reference electrode and the working electrode.

Amperiometric Reduction of Free Chlorine at Carbon Nanotube Films. Example. Chlorine Detection: Free Chlorine [HClO] and Total Chlorine [HClO and RHN—Cl and Cl-R^{H}] may be detected with the Device in FIG. 1 when the CNTs are configured as a working electrode in an electrolytic cell configuration. By the application of the appropriate voltage bias of −0.5 to +1.1V vs. Ag/AgCl (Ref.) free Chlorine (or HClO) will directly reduce in water according to the following reactions:

Free Chlorine measurement with no dopant requirement:
Cl₂(g)+H₂O═HClO+HCl [pK(a1)=3.5]
HClO═H⁺ClO−[pK(a2)=7.5]
HClO+2e−+H2O═HCl+H2O2
Cl₂(g)+H₂O→HClO+HCl [pK(a1)=3.5]
HClO→H⁺ClO⁻[pK(a2)=7.5]
HClO+2e−+H₂O→HCl+H₂O₂

The CNT islands illustrated in FIG. 3 are defined as working electrodes patterned from the Ni catalyst surface film. E-beam lithography can define the Ni film patterns with a resolution of 20-100 nm. Within this pad dimension, several CNTs will grow to form a suitable working electrode. The ensemble of these 100 nm CNT islands make up the total working electrode surface. As depicted by the above electrochemical reaction, HClO will reduce to HClO and other chlorinated hydrocarbons and amines will similarly reduce at various voltages (energies). Scanning bias voltages will induce electrolysis of electro-active sample species such that independent responses can be evoked at various voltages. The additional application of periodic perturbations (Le., sinusoidal, pulse, etc.,) enhance the sensitivity and resolution of such electrolytic responses. Digital domain processing allows for de-convolution of response artifacts and noise filtering. Such signal processing techniques improve sensitivity and specificity by isolating signal from background and by resolving complementary signals in the time (kinetic) and voltage (energy) scale.

When either chlorine gas (Cl₂), hypochlorite solution (NaOCl), or solid Ca(OCl)₂ are added to water (for water disinfection), the following reactions take place
Cl₂+H₂O→HOCl+H⁺+Cl⁻
OCl⁻+H₂O→HOCl+OH⁻

The reduction reaction of the hypochlorite ion at the electrode in aqueous solutions can be described as:
ClO⁻+2e⁻+H2O<=>Cl⁻+2OH⁻

Carbon nanotube electrodes (CNTs) are electrochemically robust to strong oxidizing agents such as the oxoacids of chlorine. In the following examples, CNTs were used as working electrodes for the analysis of free chlorine in aqueous solutions using the reduction reaction of free chlorine described above.

Examples. The amperometric reduction of ClO— was conducted in the voltage range of −0.5 to +1.1V. The resulting charge under the i-t curve was used for quantitation. A single compartment three electrode glass cell was used. The planar CNT working electrode was pressed against a Viton rubber O-ring and clamped to the bottom of the cell. A graphite rod was used as counter electrode and a commercial Ag/AgCl (BAS Systems) served as a reference electrode. The geometric area of the working electrode was about 0.2 cm². All measurements were performed at room temperature ˜25° C.

Chemicals. Phosphate buffer was prepared by mixing appropriate volumes of solutions of 0.05 M sodium phosphate dibasic and 0.05 M sodium phosphate monobasic (Sigma-Aldrich) to yield the desired pH (usually pH 7). Free Chlorine Standard (Hach Voluette, catalog no. 14268) was used as the stock solution of the hypochlorous acid (initial concentration of HOCl=79.3 ppm or 61.9 ppm). These stock solutions had been commercially prepared by generating and dissolving chlorine gas in slightly alkaline, high purity water of zero chlorine demand. All solutions were prepared in glassware treated to make them chlorine demand free.

FIG. 19A illustrates the i-E curves for the electrolysis of 0.1 M ClO— in 0.1 M phosphate buffer (pH 6.8) and for the phosphate buffer by itself. The peak observed is for the chlorine evolution reaction which illustrates an onset potential of about 900 mV at the CNT electrodes. The cathodic charge observed in the potential range from 0 mV to −500 mV is due to the reduction of the hypochlorite ion/hypochlorous acid species according to the listed equations.

FIG. 19B illustrates typical amperometric reduction curves obtained for the reduction of the free chlorine species in water at 0V applied for 5 sec (solid-phase grown CNT, 0.11 cm² inner area of O-ring). These curves are for solution concentrations of chlorine ranging from 10 ppb to 10 ppm. Plots of the resulting charge under the curves versus the solution concentration of chlorine are linear (R²=0.9888 in this case). The current vs. V plots also showed a linear relationship, indicating a semi-infinite linear diffusion of the chlorine species to CNT electrodes.

FIG. 19D illustrates the effect of electrolyte on the response for the reduction of the hypochlorite ion on CNTs in comparison with a commercial sample of conducting diamond (a model planar electrode). Plots of resultant hypochlorite reduction charge vs. its solution concentration are presented. CNTs are expected to have a minimum internal iR drop due to their small sizes and good electrical conductivity.-Based on these experiments, one can carry out the free chlorine reduction assay on CNT electrodes without addition of electrolyte.

FIG. 19E illustrates the CNT comparison plot of resultant hypochlorite reduction charge vs. its solution concentration using different electrode surfaces such as diamond, glassy carbon (GC) and gold. The R² values were found to be CNT: 0.9997, Au: 0.9996, GC: 0.9853 and conducting diamond: 0.9263. It was found that the sensitivities were highest for CNTs followed in order by Au, GC and diamond.

FIG. 19F illustrates an example of the repeatability of the response of the free chlorine reduction reaction on CNTs. Here, the plot of trial number (n) versus the resultant charge for the same concentration of hypochlorite (100 ppb ClO— in 0.05 M phosphate buffer) is shown.

The Coefficient of Variation (%) of a set of values is calculated as:

100*(Standard Deviation)/(mean value of set)

In this case the coefficient of variation was found to be 5.25% which is in an acceptable range.

CNT based sensors for free chlorine have been demonstrated in these examples to provide superior sensitivity as compared to conventionally used electrode materials such as diamond, gold and glassy carbon. The response is precise and the linear dynamic range spans 4-5 orders of magnitude. Assays without the addition of supporting electrolyte are also analytically useful.

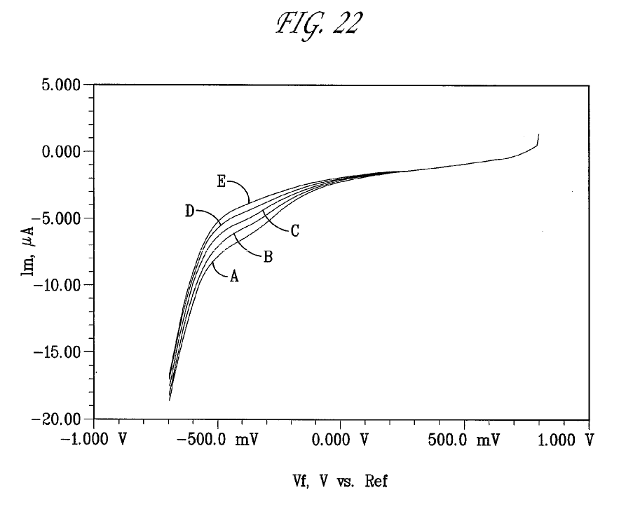

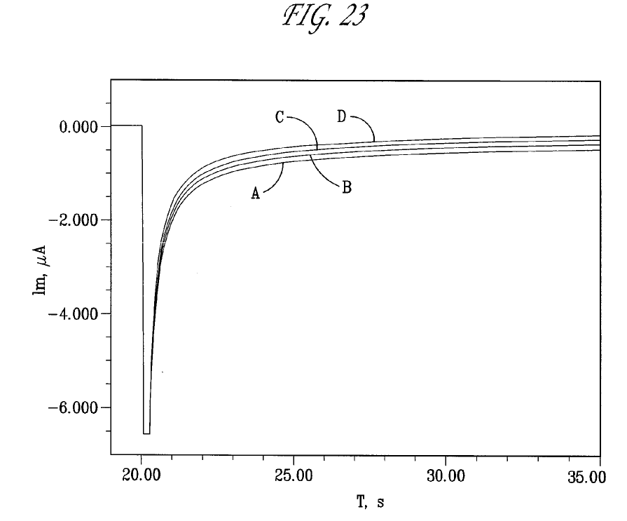

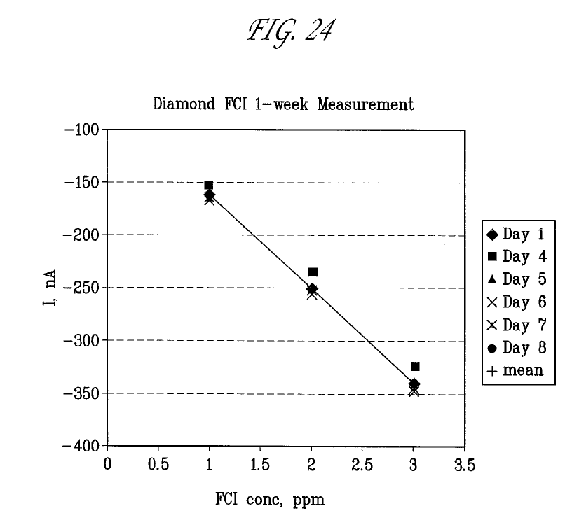

When exposed to solutions with various residual chlorine concentrations, a diamond electrode exhibits reduction peak response at about −0.1V on the linear potential sweep from about 1V to about −1V, which is assigned to the reduction of residual chlorine as shown in FIG. 22. Therefore, the applied potential across the diamond working electrode and Ag/AgCl reference electrode can be determined by the potential at which the residual chlorine reduction peak occurs.

FIG. 23 illustrates the amperometric response of the diamond electrode where the potential is stepped from a resting potential (about +0.6V versus Ag/AgCl) at which no Faradaic current occurs to the applied potential (about −0.1V versus Ag/AgCl) at which chlorine reduction occurs. Current as a function of time shows typical diffusion-controlled reduction. The reduction current decays rapidly as the electrochemistry proceeds. When the current values is plotted against the residual chlorine concentration, the diamond electrode is calibrated. FIG. 24 illustrates a typical calibration curve over a period of one week.

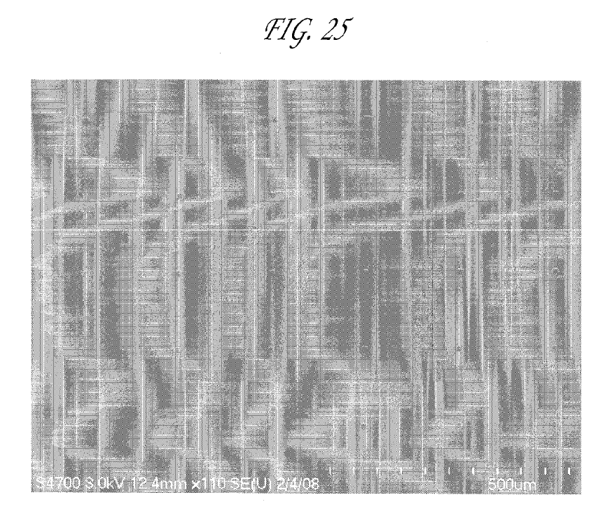

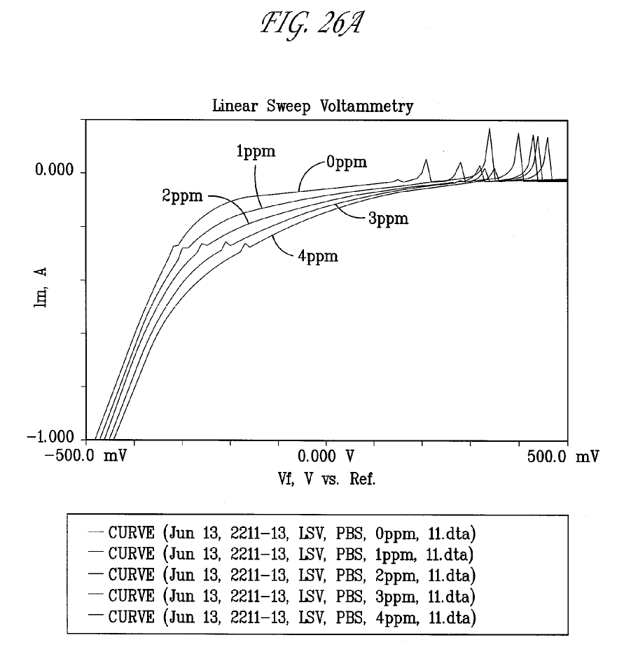

Amperometric Reduction of Free Chlorine at Carbon Nanotube Films. Using methods described previously herein, CNTs were used as working electrodes for the analysis of free chlorine in aqueous solutions using the reduction of free chlorine. In a first series of tests, an n-alkylphosphonic acid post-growth treatment of the electrode was used. The reduction voltage was −0.15V, and the time of reduction was 5 minutes. The total active sensor area was 0.000448 cm². The test conditions were: pH of 7.0; sodium hypochlorite as the free chlorine source; deionized water used for dilution; 0.1M phosphate buffer solution used for pH control. An exemplary device used for the first series of tests is depicted in FIG. 25.

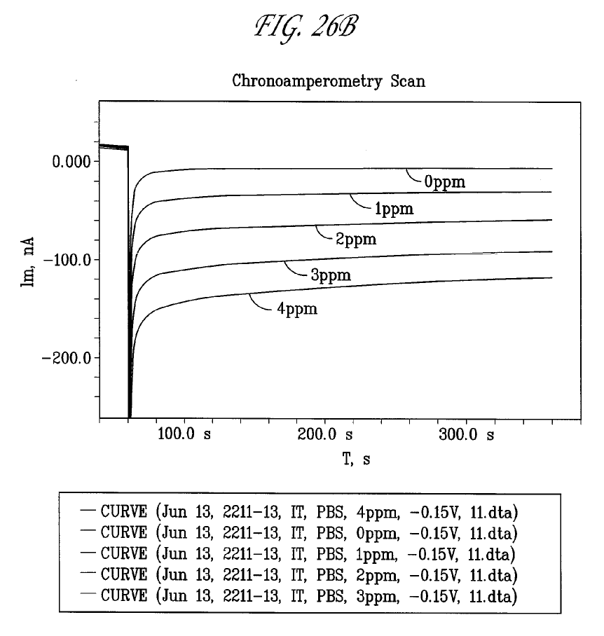

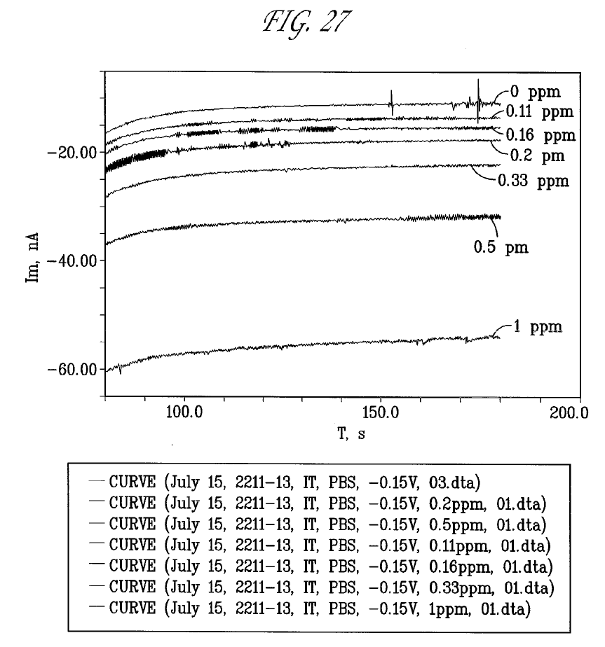

The results of the first series of tests are depicted in FIG. 26(a), showing linear sweep voltammatry for 0, 1, 2, 3, and 4 ppm of free chlorine. In the region of −0.5V to 0V, The lowest concentration of chlorine is the highest line in FIG. 26(a), and the height (corresponding to current) of the line decreases as the concentration of chlorine increases. In FIG. 26(b), the chronoamperometry scan over 5 minutes is depicted, in this case with the highest concentration of chlorine corresponding to the lowest line, and with the concentration of chlorine decreasing with increasing current.

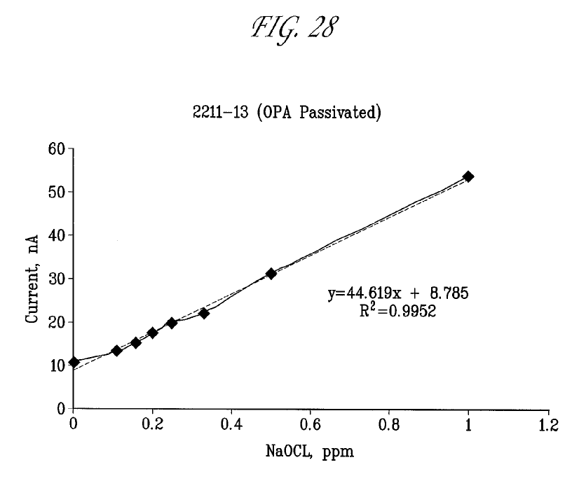

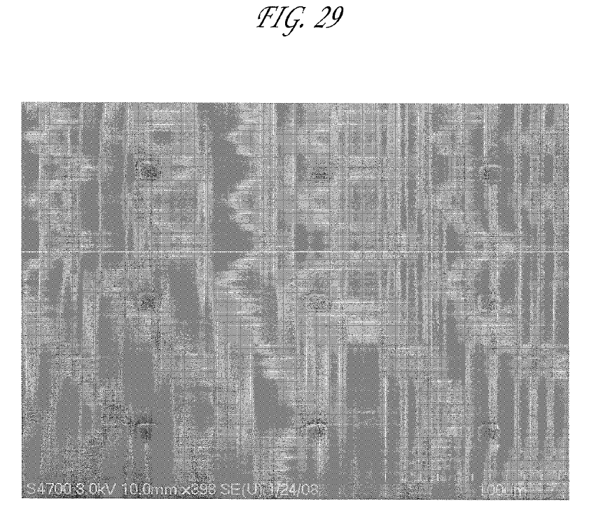

FIG. 27 depicts a similar chronoamperometry scan, this time over concentrations of chlorine ranging from 0 to 1 ppm. The results indicate that as the concentration of chlorine increases, the current decreases. These results are plotted in the form of a calibration curve in FIG. 28.

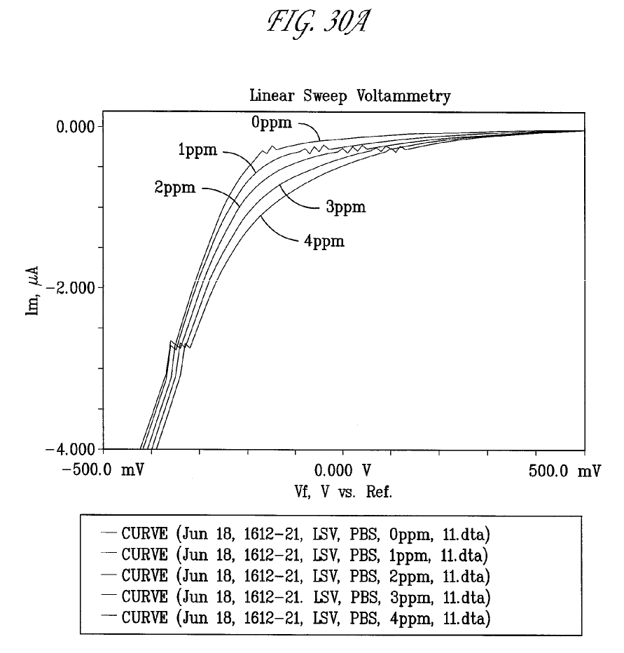

In a second series of tests, the n-alkylphosphonic post-growth treatment of the electrodes was used. The reduction voltage was −0.15V, and the time of reduction was 5 minutes. The total active sensor area was 0.001523 cm². The test conditions were: pH of 7.0; sodium hypochlorite as the free chlorine source; deionized water used for dilution; 0.1M phosphate buffer solution used for pH control. An exemplary device used for the second series of tests is depicted in FIG. 29.

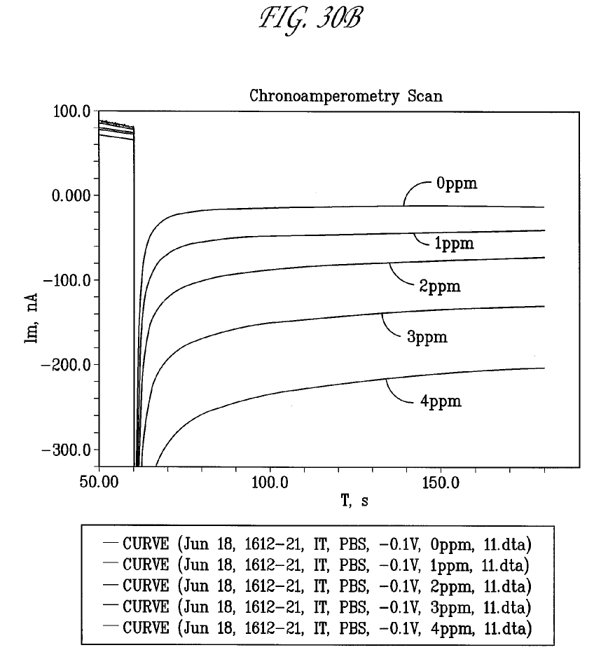

The results of the second series of tests are depicted in FIG. 30(a), showing linear sweep voltammatry for 0, 1, 2, 3, and 4 ppm of free chlorine. In the region of −0.5V to 0V, The lowest concentration of chlorine is the highest line in FIG. 30(a), and the height (corresponding to current) of the line decreases as the concentration of chlorine increases. In FIG. 30(b), the chronoamperometry scan over 5 minutes is depicted, in this case with the highest concentration of chlorine corresponding to the lowest line, and with the concentration of chlorine decreasing with increasing current.

1-219. (canceled)

220. A method of measuring the concentration of free chlorine in solution comprising:
applying a voltage in the range from about +0.5 V to about −1.0V between a working electrode and a reference electrode and measuring the current on the working electrode corresponding to the concentration of free chlorine in solution, wherein the working electrode comprises electrically conductive diamond.

221. The method of claim 220, wherein the reference electrode comprises silver/silver chloride.

222. The method of claim 220, wherein the working electrode comprises a diamond coated electrode.

223. The method of claim 220, wherein the surface of the working electrode is hydrogen-terminated.

224. The method of claim 220, wherein the electrically conductive diamond further comprises boron, nitrogen, phosphorus, or any combination thereof.

225. A method of measuring free chlorine in solution comprising:
applying a voltage between a working electrode and a reference electrode, and measuring the current on the working electrode corresponding to the concentration of free chlorine in solution, wherein the working electrode comprises carbon nanostructures.

226. The method of claim 225, wherein the carbon nanostructures comprise single wall carbon nanotubes, multi-wall carbon nanotubes, amorphous carbon, 2D-3D graphene structures, fullerites, fullerene molecules, buckyballs, carbon nano wires, carbon nano whiskers, carbon nano horns, carbon nano cones, carbon nano fibers, carbon nano ribbons, carbon nano spheres, carbon nano rods, carbon nano bowls, carbon nano onions, carbon nanotori, carbon nano buds, carbon peapod structures, or any combination thereof.

227. The method of claim 225, wherein a counter electrode is further contacted with the solution in the electrochemical cell to minimize electric current being transmitted through the reference electrode.

228. The method of claim 225, wherein the reference electrode comprises silver/silver chloride.

229. The method of claim 225, wherein the voltage is in the range from about +1.5V to about −1V.

230. The method of claim 225, wherein the voltage is in the range from about 0V to about −0.15V.

231. The method of claim 225, wherein the concentration of free chlorine is in the range from about 0 ppm to about 10 ppm.

232. The method of claim 225, wherein the working electrode comprises a surface area between that of a single carbon nanotube to about 10 cm².

233. The method of claim 225, wherein the working electrode comprises non-aligned CNTs antenna assembly electrodes, comprising: an electrically conductive layer at least partially surmounting a substrate; and an assembly of undoped antennae not vertically oriented with respect to the electrically conductive layer, wherein each of the undoped antennae comprises an undoped CNTs comprising: a base end attached to the electrically conductive layer, a mid-section comprising an outer surface surrounding a lumen, wherein at least a portion of the outer surface of the mid-section is capable of being in fluidic contact with an environment in contact with the antennae; a top end disposed opposite to the base end.

234. The method of claim 225, wherein the working electrode comprises aligned CNTs antenna assembly electrodes, comprising: an electrically conductive layer at least partially surmounting a substrate; and an assembly of undoped antennae vertically oriented with respect to the electrically conductive layer, wherein each of the undoped antennae comprises undoped CNTs comprising: a base end attached to the electrically conductive layer, a mid-section comprising an outer surface surrounding a lumen, wherein at least a portion of the outer surface of the mid-section is capable of being in fluidic contact with an environment in contact with the antennae; a top end disposed opposite to the base end.

235. The method of claim 225, wherein the working electrode comprises CNTs that are grown by thermal chemical vapor deposition, arc discharge process, laser-ablation process, natural, incidental and controlled flame environments, plasma enhanced chemical vapor deposition, a capacitively coupled microwave plasma process, a capacitively coupled electron cyclotron resonance process, a capacitively coupled radiofrequency process, an inductively coupled plasma process, a dc plasma assisted hot filament process, template synthesis, or any combination thereof.

236. The method of claim 225, wherein the working electrode comprises CNTs grown on a metal catalyst.

237. The method of claim 225, wherein the metal catalyst substance comprises Ni, Fe, Co, or any combination thereof.

238. The method of claim 237, wherein the thickness of the metal catalyst is in the range of from less than about 1 nm nanometer up to about 300 nanometers.

239. The method of claim 225, wherein the working electrode comprising CNTs of selected patterns.

240. The method of claim 239, wherein the selected patterns comprise CNTs bundle together in a shape comprising a rectangle, square, circle, or any combination or array thereof.

241. A method of measuring electrochemically-active species in solution comprising:
applying a voltage between a working electrode and a reference electrode, and measuring the current on the working electrode corresponding to the concentration of electrochemically-active species in solution, wherein the working electrode comprises carbon nanostructures.

242. An electrochemical device for measuring free chlorine concentration in an aqueous solution, comprising:
a working electrode comprising carbon nanostructures, and
a reference electrode,
wherein each one of said electrodes is capable of contacting an aqueous solution comprising residual chlorine, said electrodes capable of being in ionic communication with the aqueous solution; and
wherein the working and reference electrodes are operatively coupled to give rise to a measurable current at the working electrode upon application of a voltage between the working electrode and the reference electrode.

243. The device of claim 242, wherein the working electrode comprises aligned CNTs antenna assembly electrodes, comprising: an electrically conductive layer at least partially surmounting a substrate; and an assembly of undoped antennae vertically oriented with respect to the electrically conductive layer, wherein each of the undoped antennae comprises undoped CNTs comprising: a base end attached to the electrically conductive layer, a mid-section comprising an outer surface surrounding a lumen, wherein at least a portion of the outer surface of the mid-section is capable of being in fluidic contact with an environment in contact with the antennae; a top end disposed opposite to the base end.

244. The device of claim 242, wherein the working electrode comprises CNTs that are grown by thermal chemical vapor deposition, arc discharge process, laser-ablation process, natural, incidental and controlled flame environments, plasma enhanced chemical vapor deposition, a capacitively coupled microwave plasma process, a capacitively coupled electron cyclotron resonance process, a capacitively coupled radiofrequency process, an inductively coupled plasma process, a dc plasma assisted hot filament process, template synthesis, or any combination thereof.

245. The device of claim 242, wherein the working electrode comprises CNTs grown on a metal catalyst.

246. The device of claim 242, wherein the metal catalyst substance comprises Ni, Fe, Co, or any combination thereof.

247. The device of claim 246, wherein the thickness of the metal catalyst is in the range of from less than about 1 nm nanometer up to about 300 nanometers.

248. The device of claim 242, wherein the working electrode comprising CNTs of selected patterns.

249. The device of claim 248, wherein the selected patterns comprise CNTs bundle together in a shape comprising a rectangle, square, circle, or any combination or array thereof.

250. An electrochemical device, comprising:
a working electrode comprising electrically conductive diamond; and
a reference electrode;
wherein the electrochemical device is capable of measuring a current on the working electrode, the current arising from the presence of an analyte in an aqueous solution upon the application of a voltage in the range of from about +0.5 V to about −1.0V between the working electrode and a the reference electrode, wherein said electrodes are capable of being in ionic communication with the aqueous solution.

251. The electrochemical device of claim 250, further comprising a counter electrode capable of being operatively coupled with the working and reference electrodes to minimize electrical communication between the reference electrode and the working electrode.

252. The electrochemical device of claim 242, further comprising a counter electrode capable of being operatively coupled with the working and reference electrodes to minimize electrical communication between the reference electrode and the working electrode.

253. The electrochemical device of claim 250, wherein the working electrode comprises an electrically conductive substrate and the electrically conductive diamond is disposed as a thin film on the electrically conductive substrate.

254. The method of claim 241, wherein the electrochemically-active species in solution comprises potassium iodide, I−, N,N-diethyl-p-phenylenediamine, potassium ferrocyanide, ruthenium (II) bipyridyl complex, ferrocene, or any combination thereof.
